(19) United States
(12) Patent Application Publication
(10) Pub. No.: US 2024/0284778 A1
(43) Pub. Date: Aug. 22, 2024

(54) ORGANIC ELECTROLUMINESCENT MATERIALS AND DEVICES

(71) Applicant: Universal Display Corporation, Ewing, NJ (US)

(72) Inventors: Alexey Borisovich DYATKIN, Ambler, PA (US); Wei-Chun SHIH, Lawrenceville, NJ (US); Jui-Yi TSAI, Newtown, PA (US)

(73) Assignee: Universal Display Corporation, Ewing, NJ (US)

(21) Appl. No.: 18/414,610

(22) Filed: Jan. 17, 2024

Related U.S. Application Data
(60) Provisional application No. 63/482,344, filed on Jan. 31, 2023.
(60) Provisional application No. 63/459,415, filed on Apr. 14, 2023.
(60) Provisional application No. 63/484,004, filed on Feb. 9, 2023.
(60) Provisional application No. 63/459,773, filed on Apr. 17, 2023.
(60) Provisional application No. 63/488,719, filed on Mar. 6, 2023.
(60) Provisional application No. 63/497,148, filed on Apr. 19, 2023.

(51) Int. Cl. H10K 85/30; C07F 15/00; C09K 11/06

(52) U.S. Cl. CPC H10K 85/342; C07F 15/004; C07F 15/0093; C09K 11/06; H10K 85/346; C09K 2211/1007; C09K 2211/1029; C09K 2211/1033; C09K 2211/1088; C09K 2211/185

(57) ABSTRACT

A compound including a first ligand L_{A} of Formula I,

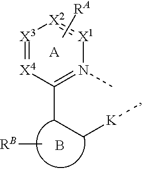

is provided. In Formula I, moiety B is a fused polycyclic ring system; X¹ to X⁴ are each C or N; K is a direct bond or a linker; L_{A} is coordinated to a metal. Formulations, OLEDs, and consumer products containing such compounds are also provided.

### CROSS-REFERENCE TO RELATED APPLICATIONS

This application claims priority under 35 U.S.C. § 119(e) to U.S. Provisional Applications No. 63/497,148, filed on Apr. 19, 2023, No. 63/459,773, filed on Apr. 17, 2023, No. 63/459,415, filed on Apr. 14, 2023, No. 63/488,719, filed on Mar. 6, 2023, No. 63/484,004, filed on Feb. 9, 2023, and No. 63/482,344, filed on Jan. 31, 2023, the entire contents of which are incorporated herein by reference.

### FIELD

The present disclosure generally relates to organometallic compounds and formulations and their various uses including as emitters in devices such as organic light emitting diodes and related electronic devices.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as flat panel displays, illumination, and backlighting.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound comprising a first ligand L_{A} of Formula I,

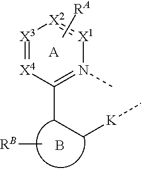

### In Formula I:

moiety B is a fused polycyclic ring system, wherein each ring of the fused polycyclic ring system is a 5-membered or 6-membered carbocyclic or heterocyclic ring;

X¹ to X⁴ are each independently C or N;

K is selected from the group consisting of a direct bond, O, S, N(R^{α}), P(R^{α}), B(R^{α}), C(R^{α})(R^{β}), and Si(R^{α})(R^{β});

L_{A} is coordinated to a metal M;

M may be coordinated to other ligands;

L_{A} may be joined with other ligands to comprise a tridentate, tetradentate, pentadentate, or hexadentate ligand;

wherein each of R^{A} and R^{B} independently represents mono to the maximum allowable substitutions, or no substitutions;

each R^{A}, R^{B}, R^{α}, and R^{β} is independently hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and

any two R^{A}, R^{B}, R^{α}, and R^{β} may be joined or fused to form a ring.

In another aspect, the present disclosure provides a formulation comprising a compound comprising a first ligand L_{A} of Formula I as described herein.

In yet another aspect, the present disclosure provides an OLED having an organic layer comprising a compound comprising a first ligand L_{A} of Formula I as described herein.

In yet another aspect, the present disclosure provides a consumer product comprising an OLED with an organic layer comprising a compound comprising a first ligand L_{A} of Formula I as described herein.

### BRIEF DESCRIPTION OF THE DRAWINGS

FIG. 1 shows an organic light emitting device.

FIG. 2 shows an inverted organic light emitting device that does not have a separate electron transport layer.

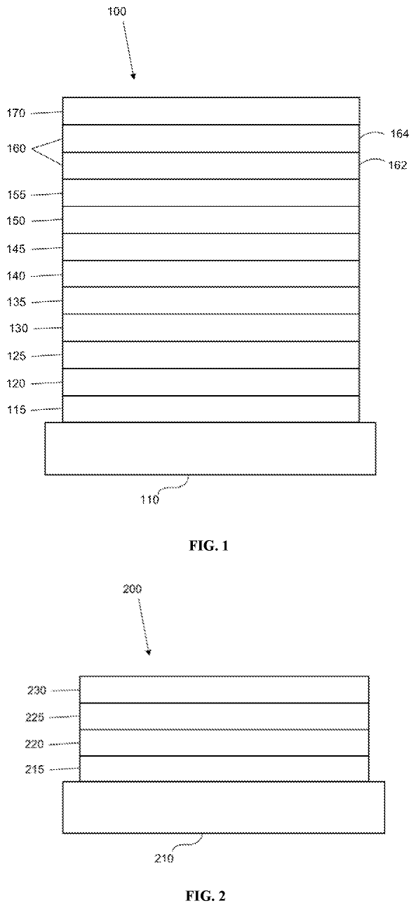

### DETAILED DESCRIPTION

### A. Terminology

Unless otherwise specified, the below terms used herein are defined as follows:

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine. bromine, and iodine.

The term “acyl” refers to a substituted carbonyl radical (C(O)—Rₛ).

The term “ester” refers to a substituted oxycarbonyl (—O—C(O)—Rₛ or —C(O)—O—Rₛ) radical.

The term “ether” refers to an —ORₛ radical.

The terms “sulfanyl” or “thio-ether” are used interchangeably and refer to a —SRₛ radical.

The term “selenyl” refers to a —SeRₛ radical.

The term “sulfinyl” refers to a —S(O)—Rₛ radical.

The term “sulfonyl” refers to a —SO₂—Rₛ radical.

The term “phosphino” refers to a —P(Rₛ)₂ radical, wherein each Rₛ can be same or different.

The term “silyl” refers to a —Si(Rₛ)₃ radical, wherein each Rₛ can be same or different.

The term “germyl” refers to a —Ge(Rₛ)₃ radical, wherein each Rs can be same or different.

The term “boryl” refers to a —B(Rₛ)₂ radical or its Lewis adduct —B(Rₛ)₃ radical, wherein Rₛ can be same or different.

In each of the above, Rₛ can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. Preferred Rₛ is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1, 1-dimethylpropyl, 1,2-dimethylpropyl, 2,2-dimethylpropyl, and the like. Additionally, the alkyl group may be optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1 ]heptyl, spiro[4.5]decyl, spiro[5.5]undecyl, adamantyl, and the like. Additionally, the cycloalkyl group may be optionally substituted.

The terms “heteroalkyl” or “heterocycloalkyl” refer to an alkyl or a cycloalkyl radical, respectively. having at least one carbon atom replaced by a heteroatom. Optionally the at least one heteroatom is selected from O, S, N, P, B, Si and Se, preferably, O, S or N. Additionally, the heteroalkyl or heterocycloalkyl group may be optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group may be optionally substituted.

The term “alkynyl” refers to and includes both straight and branched chain alkyne radicals. Alkynyl groups are essentially alkyl groups that include at least one carbon-carbon triple bond in the alkyl chain. Preferred alkynyl groups are those containing two to fifteen carbon atoms. Additionally, the alkynyl group may be optionally substituted.

The terms “aralkyl” or “arylalkyl” are used interchangeably and refer to an alkyl group that is substituted with an aryl group. Additionally, the aralkyl group may be optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group may be optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more General Substituents.

In many instances, the General Substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the Preferred General Substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the More Preferred General Substituents are selected from the group consisting of deuterium, fluorine, alkyl, cycloalkyl, alkoxy, aryloxy, amino, silyl, aryl, heteroaryl, sulfanyl, and combinations thereof.

In yet other instances, the Most Preferred General Substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution, R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein. “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein. “adjacent” means that the two substituents involved can be on the same ring next to each other, or on two neighboring rings having the two closest available substitutable positions, such as 2,2′ positions in a biphenyl, or 1,8 position in a naphthalene. as long as they can form a stable fused ring system.

### B. The Compounds of the Present Disclosure

New metal complexes comprising a silyl group on the emitting ligand are disclosed. Such complexes exhibit a narrower line shape of electroluminescent (EL) spectrum than conventional emissive complexes. Emitter compounds having a narrower emission line shape is beneficial for obtaining higher efficiency in an OLED device.

In one aspect, the present disclosure provides a compound comprising a first ligand L_{A} of Formula I,

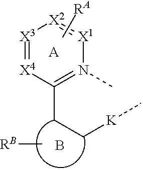

### In Formula I:

moiety B is a fused polycyclic ring system, wherein each ring of the fused polycyclic ring system is a 5-membered or 6-membered carbocyclic or heterocyclic ring;

X¹ to X⁴ are each independently C or N;

K is selected from the group consisting of a direct bond, O, S, N(R^{α}), P(R^{α}), B(R^{α}), C(R^{α})(R^{β}), and Si(R^{α})(R^{β});

L_{A} is coordinated to a metal M;

M may be coordinated to other ligands;

L_{A} may be joined with other ligands to comprise a tridentate, tetradentate, pentadentate, or hexadentate ligand;

wherein each of R^{A} and R^{B} independently represents mono to the maximum allowable substitutions, or no substitutions;

each R^{A}, R^{B}, R^{α}, and R^{β} is independently hydrogen or a substituent selected from the group consisting of the General Substituents defined herein; and

any two R^{A}, R^{B}, R^{α}, and R^{β} may be joined or fused to form a ring.

In some embodiments, at least one of R^{A} or R^{B} comprises a silyl group, and moiety B comprises four or more fused rings.

In some embodiments, at least one R^{A} has a structure of Formula II,

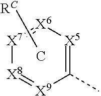

wherein R^{C} represents mono to the maximum allowable substitutions, or no substitutions; each R^{C} is independently hydrogen or a substituent selected from the group consisting of the General Substituents defined herein; and at least one of R^{A} or R^{B} comprises a silyl group, wherein if the at least one of R^{A} that is Formula II is joined to X³ and K is a direct bond, then at least one R^{C} is not H. When at least one R^{A} has a structure of Formula II, any two R^{A}, R^{B}, R^{C}, R^{α}, and R^{β} may be joined or fused to form a ring.

In some embodiments, at least one R^{B} comprises a silyl group and at least one R^{A} comprises a cyclic group or a silyl group.

In some embodiments, at least one of R^{A} or R^{B} comprises a silyl group, and moiety B comprises four or more fused rings, and at least one R^{A} has a structure of Formula II,

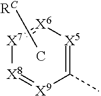

wherein R^{C} represents mono to the maximum allowable substitutions, or no substitutions; each R^{C} is independently hydrogen or a substituent selected from the group consisting of the General Substituents defined herein; and if the at least one of R^{A} that is Formula II is joined to X³ and K is a direct bond, then at least one R^{C} is not H.

In some embodiments, at least one of R^{A} or R^{B} comprises a silyl group, and moiety B comprises four or more fused rings, and at least one R^{A} comprises a cyclic group.

In some embodiments, at least one R^{A} has a structure of Formula II,

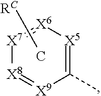

wherein R^{C} represents mono to the maximum allowable substitutions, or no substitutions; each R^{C} is independently hydrogen or a substituent selected from the group consisting of the General Substituents defined herein, and if the at least one of R^{A} that is Formula II is joined to X³ and K is a direct bond, then at least one R^{C} is not H, and at least one R^{B} comprises a silyl group and at least one R^{A} comprises a cyclic group or a silyl group.

In some embodiments, at least one of R^{A} or R^{B} comprises a silyl group, and moiety B comprises four or more fused rings, and at least one R^{A} has a structure of Formula II,

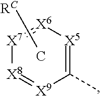

wherein R^{C} represents mono to the maximum allowable substitutions, or no substitutions; each R^{C} is independently hydrogen or a substituent selected from the group consisting of the General Substituents defined herein, and if the at least one of R^{A} that is Formula II is joined to X³ and K is a direct bond, then at least one R^{C} is not H, and at least one R^{B} comprises a silyl group and at least one R^{A} comprises a cyclic group or a silyl group.

In some embodiments, at least one of the substituents adjacent to the substituent comprising a silyl group is a General Substituent defined herein. In some embodiments, both of the substituents adjacent to the substituent comprising a silyl group are independently General Substituents defined herein.

In some embodiments, at least one of the substituents adjacent to the substituent comprising a silyl group is a Preferred General Substituent defined herein. In some embodiments, both of the substituents adjacent to the substituent comprising a silyl group are independently Preferred General Substituents defined herein.

In some embodiments, each R^{A}, R^{B}, R^{C}, R^{α}, and R^{β} is independently hydrogen or a substituent selected from the group consisting of the Preferred General Substituent defined herein. In some embodiments, each R^{A}, R^{B}, R^{C}, R^{α}, and R^{β} is independently hydrogen or a substituent selected from the group consisting of the More Preferred General Substituent defined herein. In some embodiments, each R^{A}, R^{B}, R^{C}, R^{α}, and R^{β} is independently hydrogen or a substituent selected from the group consisting of the Most Preferred General Substituent defined herein.

In some embodiments, moiety B comprises at least three fused rings. In some embodiments, moiety B comprises at least three fused aromatic rings.

In some embodiments, moiety B comprises at least four fused rings. In some embodiments, moiety B comprises at least four fused aromatic rings.

In some embodiments, moiety B comprises at least five fused rings. In some embodiments, moiety B comprises at least five fused aromatic rings.

In some embodiments, moiety B comprises at least one 5-membered ring. In some embodiments, moiety B includes exactly one 5-membered ring. In some embodiments, moiety B includes exactly one 5-membered ring, which is fused to the ring that is coordinated to metal M.

In some embodiments, moiety B is selected from the group consisting of naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene.

In some embodiments, moiety B is independently a polycyclic fused ring structure. In some embodiments, moiety B is independently a polycyclic fused ring structure comprising at least three fused rings. In some embodiments, the polycyclic fused ring structure has two 6-membered rings and one 5-membered ring. In some such embodiments, the 5-membered ring is fused to the ring coordinated to metal M and the second 6-membered ring is fused to the 5-membered ring. In some embodiments, moiety B is independently selected from the group consisting of dibenzofuran, dibenzothiophene, dibenzoselenophene, and aza-variants thereof. In some such embodiments, moiety B can independently be further substituted at the ortho- or meta-position of the O, S, or Se atom by a substituent selected from the group consisting of deuterium, fluorine, nitrile, alkyl, cycloalkyl, aryl, heteroaryl, and combinations thereof. In some such embodiments, the aza-variants contain exactly one N atom at the 6-position (ortho to the O, S, or Se) with a substituent at the 7-position (meta to the O, S, or Se).

In some embodiments, moiety B is independently a polycyclic fused ring structure comprising at least four fused rings. In some embodiments, the polycyclic fused ring structure comprises three 6-membered rings and one 5-membered ring. In some such embodiments, the 5-membered ring is fused to the ring coordinated to metal M, the second 6-membered ring is fused to the 5-membered ring, and the third 6-membered ring is fused to the second 6-membered ring. In some such embodiments, the third 6-membered ring is further substituted by a substituent selected from the group consisting of deuterium, fluorine, nitrile, alkyl, cycloalkyl, aryl, heteroaryl, and combinations thereof.

In some embodiments, moiety B is independently a polycyclic fused ring structure comprising at least five fused rings. In some embodiments, the polycyclic fused ring structure comprises four 6-membered rings and one 5-membered ring or three 6-membered rings and two 5-membered rings. In some embodiments comprising two 5-membered rings, the 5-membered rings are fused together. In some embodiments comprising two 5-membered rings, the 5-membered rings are separated by at least one 6-membered ring. In some embodiments with one 5-membered ring, the 5-membered ring is fused to the ring coordinated to metal M, the second 6-membered ring is fused to the 5-membered ring, the third 6-membered ring is fused to the second 6-membered ring, and the fourth 6-membered ring is fused to the third 6-membered ring.

In some embodiments, moiety B is independently an aza version of the polycyclic fused rings described above. In some such embodiments, moiety B independently contains exactly one aza N atom. In some such embodiments, moiety B contains exactly two aza N atoms, which can be in one ring, or in two different rings. In some such embodiments, the ring having aza N atom is separated by at least two other rings from the metal M atom. In some such embodiments, the ring having aza N atom is separated by at least three other rings from the metal M atom. In some such embodiments, each of the ortho position of the aza N atom is substituted.

In some embodiments, each of X¹ to X⁴ is C.

In some embodiments, at least one of X¹ to X⁴ is N. In some embodiments, exactly one of X¹ to X⁴ is N.

In some embodiments, K is a direct bond.

In some embodiments, K is O. In some embodiments, K is S.

In some embodiments, K is selected from the group consisting of N(R^{α}), P(R^{α}), and B(R^{β}).

In some embodiments, K is selected from the group consisting of C(R^{α})(R^{β}) and Si(R^{α})(R^{β}).

In some embodiments, the metal M has an atomic mass of at least 40. In some embodiments, the metal M is selected from the group consisting of Ir, Rh, Re, Ru, Os, Pt, Pd, Ag, Au, and Cu.

In some embodiments, the metal M is Ir. In some embodiments, the metal M is Pt.

In some embodiments, two adjacent ones of X¹ to X⁴ are C and the adjacent R^{A} are joined or fused to form a ring.

In some embodiments, at least one R^{A} is not hydrogen.

In some embodiments, at least one R^{A} comprises a silyl group. In some embodiments, at least one R^{A} comprises is trimethylsilyl or triphenylsilyl.

In some embodiments, at least one R^{A} is a silyl group. In some embodiments, at least one R^{A} is trimethylsilyl or triphenylsilyl.

In some embodiments, at least one R^{B} is not hydrogen.

In some embodiments, at least one R^{B} comprises a silyl group. In some embodiments, at least one R^{B} comprises is trimethylsilyl or triphenylsilyl.

In some embodiments, at least one R^{B} is a silyl group. In some embodiments, at least one R^{B} is trimethylsilyl or triphenylsilyl.

In some embodiments, moiety B comprises four or more fused rings.

In some embodiments, at least one R^{A} has a structure of Formula II,

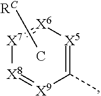

wherein R^{C} represents mono to the maximum allowable substitutions, or no substitutions; each R^{C} is independently hydrogen or a substituent selected from the group consisting of the General Substituents defined herein. In some of such embodiments, the R^{A} bonded to X³ has a structure of Formula II, K is a direct bond, and at least one R^{C} is not H.

In some embodiments where at least one R^{A} has a structure of Formula II, at least one R^{C} is not H.

In some embodiments where at least one R^{A} has a structure of Formula II, at least one R^{C} comprises a silyl group. In some embodiments, at least one R^{C} comprises trimethylsilyl.

In some embodiments where at least one R^{A} has a structure of Formula II, the R^{C} bonded to at least one of X⁵ or X⁹ is not H. In some embodiments where at least one R^{A} has a structure of Formula II, the R^{C} bonded to each of X⁵ and X⁹ is not H.

In some embodiments where at least one R^{A} has a structure of Formula II, the R^{C} bonded to at least one of X⁵ or X⁹ is independently selected from the group consisting of alkyl, cycloalkyl, aryl, heteroaryl, and combinations thereof.

In some embodiments where at least one R^{A} has a structure of Formula II, the R^{C} bonded to each of X⁵ and X⁹ is independently selected from the group consisting of alkyl, cycloalkyl, aryl, heteroaryl, and combinations thereof.

In some embodiments where at least one R^{A} has a structure of Formula II, the R^{C} bonded to X⁷ is not H.

In some embodiments where at least one R^{A} has a structure of Formula II, the R^{C} bonded to X⁷ is independently selected from the group consisting of alkyl, cycloalkyl, aryl, heteroaryl, and combinations thereof.

In some embodiments where at least one R^{A} has a structure of Formula II, two adjacent ones of X⁵ to X⁹ are C and the adjacent R^{C} are joined or fused to form a ring.

In some embodiments where at least one R^{A} has a structure of Formula II, at least one additional R^{A} is not H. In some embodiments where at least one R^{A} has a structure of Formula II, at least one additional R^{A} comprises a moiety selected from the group consisting of alkyl, cycloalkyl, aryl, heteroaryl, partially or fully deuterated variants thereof, F, and silyl.

In some embodiments, the silyl group of R^{A}, R^{B}, or R^{C} has a structure of —SiR^{Sa}R^{Sb}R^{Sc}, where each of R^{Sa}, R^{Sb}, and R^{Sc} is independently alkyl, cycloalkyl, heteroalkyl, heterocycloalkyl, boryl, arylalkyl, alkoxy, aryloxy, alkenyl, cycloalkenyl, heteroalkenyl, alkynyl, aryl, heteroaryl, or combinations thereof; and any two substituents may be joined or fused to form a ring.

In some embodiments, the silyl group of R^{A}, R^{B}, or R^{C} is selected from the group consisting of the structures of the following Silyl List: SiEt₃, Si(ⁱPr)₃, Si(ⁱBu)₃, SiPh₃, Si(CD₃)₃,

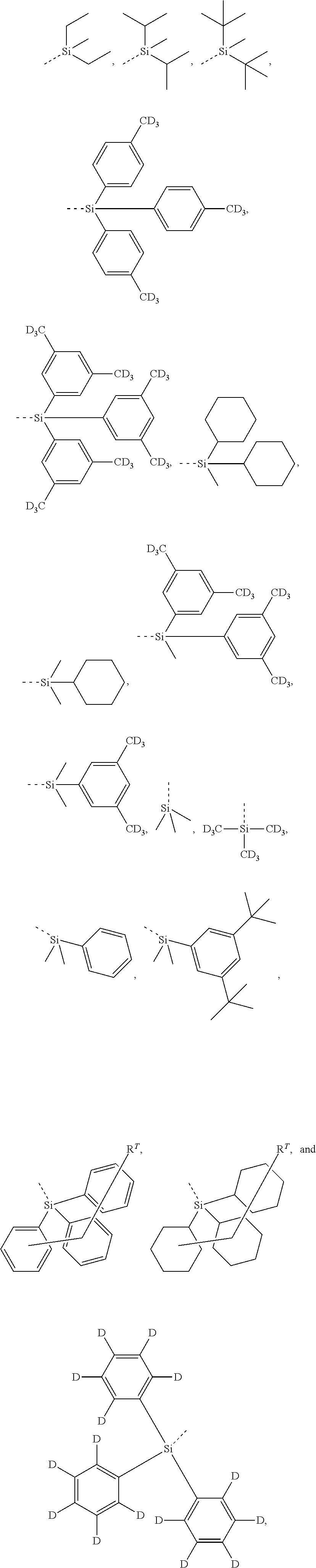

wherein each R^{T} independently represents mono to the maximum allowable substitutions, or no substitution;

each R^{T} is independently hydrogen or a substituent selected from the group consisting of the General Substituents defined herein; and

any two substituents may be joined or fused to form a ring.

In some embodiments, at least one R^{A} comprises a cyclic group or a silyl group. In some embodiments, at least one R^{B} comprises a silyl group. In some embodiments, at least one R^{B} comprises a silyl group and at least one R^{A} comprises a cyclic group or a silyl group.

In some embodiments of the compound, at least one of R^{A} or R^{B} is an electron-withdrawing group from LIST EWG 1 as defined herein. In some embodiments of the compound, at least one of R^{A} or R^{B} is an electron-withdrawing group from LIST EWG 2 as defined herein. In some embodiments of the compound, at least one of R^{A} or R^{B} is an electron-withdrawing group from LIST EWG 3 as defined herein. In some embodiments of the compound, at least one of R^{A} or R^{B} is an electron-withdrawing group from LIST EWG 4 as defined herein. In some embodiments of the compound, at least one of R^{A} or R^{B} is an electron-withdrawing group from LIST Pi-EWG as defined herein.

In some embodiments of the compound, one R^{A} is an electron-withdrawing group from LIST EWG 1 as defined herein. In some embodiments of the compound, one of R^{A} is an electron-withdrawing group from LIST EWG 2 as defined herein. In some embodiments of the compound, one of R^{A} is an electron-withdrawing group from LIST EWG 3 as defined herein. In some embodiments of the compound, one of R^{A} is an electron-withdrawing group from LIST EWG 4 as defined herein. In some embodiments of the compound, one of R^{A} is an electron-withdrawing group from LIST Pi-EWG as defined herein.

In some embodiments of the compound, one R^{B} is an electron-withdrawing group from LIST EWG 1 as defined herein. In some embodiments of the compound, one of R^{B} is an electron-withdrawing group from LIST EWG 2 as defined herein. In some embodiments of the compound, one of R^{B} is an electron-withdrawing group from LIST EWG 3 as defined herein. In some embodiments of the compound, one of R^{B} is an electron-withdrawing group from LIST EWG 4 as defined herein. In some embodiments of the compound, one of R^{B} is an electron-withdrawing group from LIST Pi-EWG as defined herein.

In some embodiments of the compound, the ligand L_{A} comprises an electron-withdrawing group from LIST EWG 1 as defined herein. In some embodiments of the compound, the ligand L_{A} comprises an electron-withdrawing group from LIST EWG 2 as defined herein. In some embodiments of the compound, the ligand L_{A} comprises an electron-withdrawing group from LIST EWG 3 as defined herein. In some embodiments of the compound, the ligand L_{A} comprises an electron-withdrawing group from LIST EWG 4 as defined herein. In some embodiments of the compound, the ligand L_{A} comprises an electron-withdrawing group from LIST Pi-EWG as defined herein.

In some embodiments of the compound, the compound comprises an electron-withdrawing group from LIST EWG 1 as defined herein. In some embodiments of the compound, the compound comprises an electron-withdrawing group from LIST EWG 2 as defined herein. In some embodiments of the compound, the compound comprises an electron-withdrawing group from LIST EWG 3 as defined herein. In some embodiments of the compound, the compound comprises an electron-withdrawing group from LIST EWG 4 as defined herein. In some embodiments of the compound, the compound comprises an electron-withdrawing group from LIST Pi-EWG as defined herein.

In some embodiments, the electron-withdrawing groups commonly comprise one or more highly electronegative elements including but not limited to fluorine, oxygen, sulfur, nitrogen, chlorine, and bromine.

In some embodiments of the compound, the electron-withdrawing group has a Hammett constant larger than 0. In some embodiments, the electron-withdrawing group has a Hammett constant equal or larger than 0.1, 0.2, 0.3, 0.4, 0.5, 0.6, 0.7, 0.8, 0.9, 1.0, or 1.1.

In some embodiments, the electron-withdrawn group is selected from the group consisting of the following structures (LIST EWG 1): F, CF₃, CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, (R^{k2})₂CCN, (R^{k2})₂CCF₃, CNC(CF₃)₂, BR^{k3}R^{k2}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridoxine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl, isocyanate,

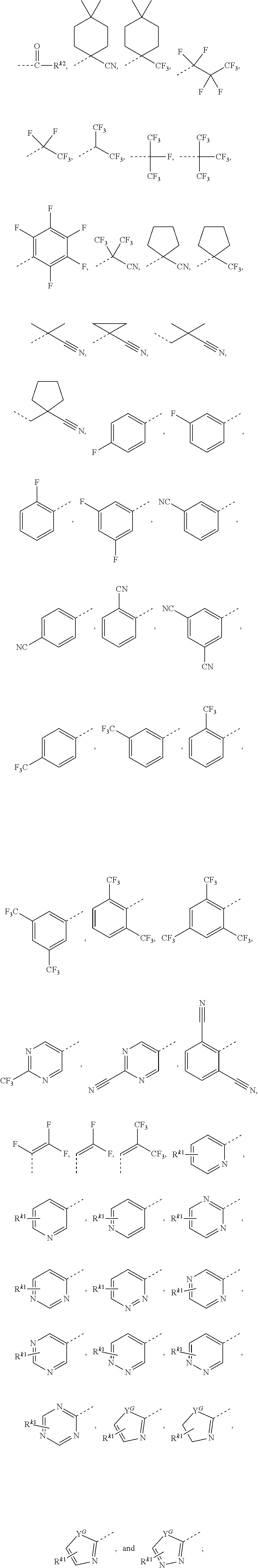

wherein each R^{k1} represents mono to the maximum allowable substitution, or no substitutions;

wherein Y^{G} is selected from the group consisting of BRₑ, NRₑ, PRₑ, O, S, Se, C═O, S═O, SO₂, CRₑR_{f}, SiRₑR_{f}, and GeRₑR_{f}; and

wherein each of R^{k1}, R^{k2}, R^{k3}, Rₑ, and R_{f} is independently a hydrogen or a substituent selected from the group consisting of the General Substituents defined herein.

In some embodiments, the electron-withdrawing group is selected from the group consisting of the following structures (LIST EWG 2):

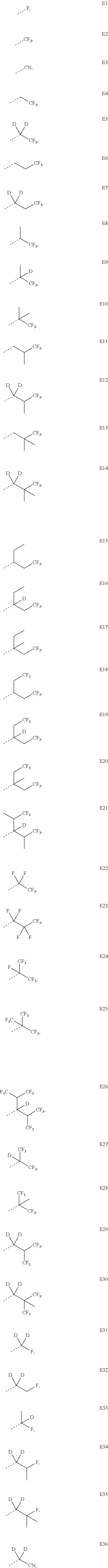

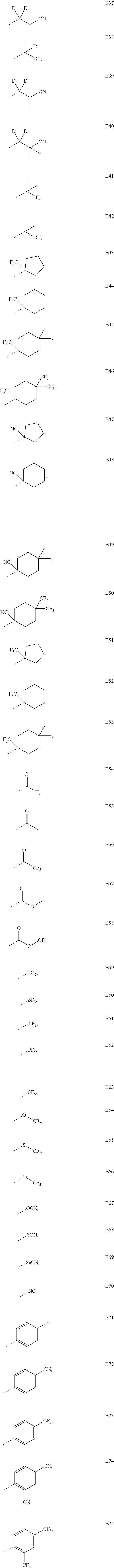

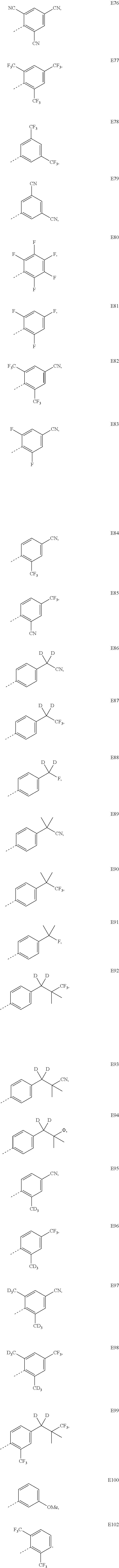

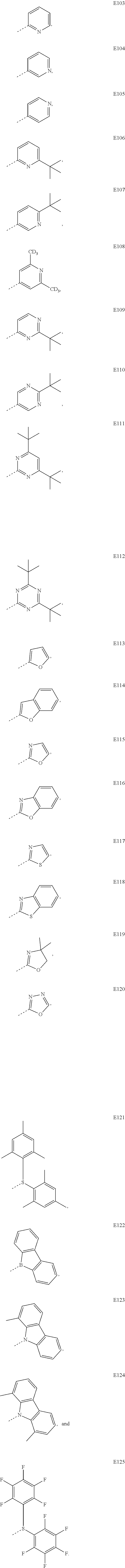

In some embodiments, the electron-withdrawing group is selected from the group consisting of the following structures (LIST EWG 3):

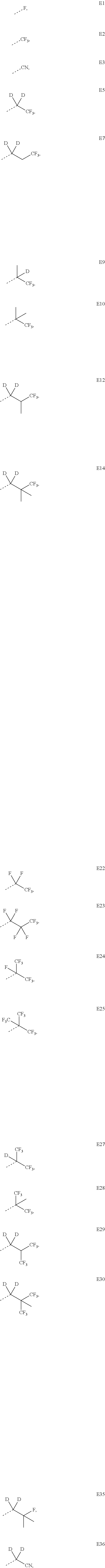

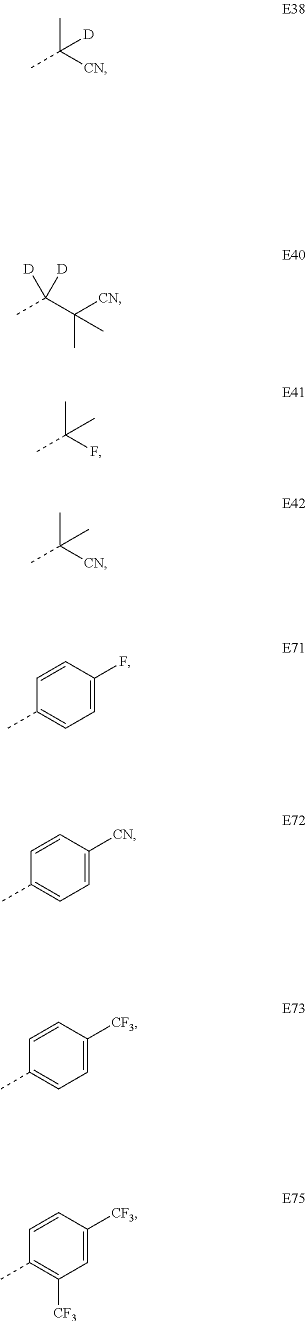

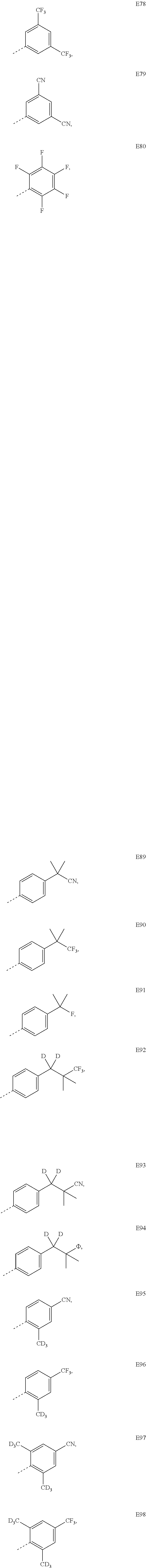

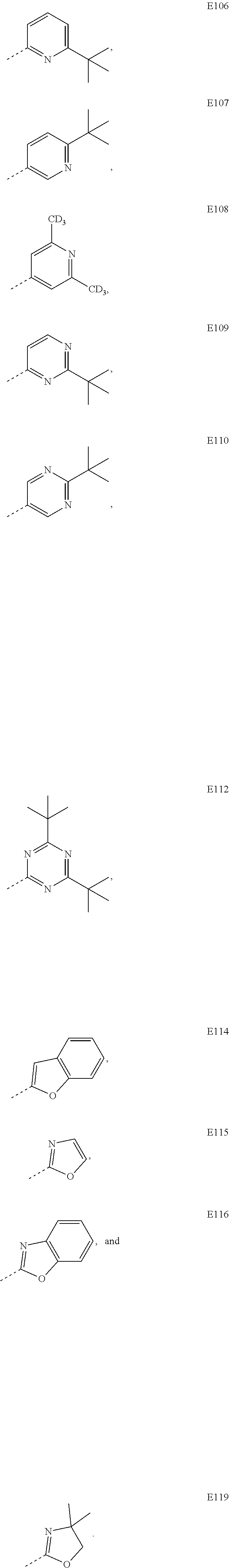

In some embodiments, the electron-withdrawing group is selected from the group consisting of the following structures (LIST EWG 4):

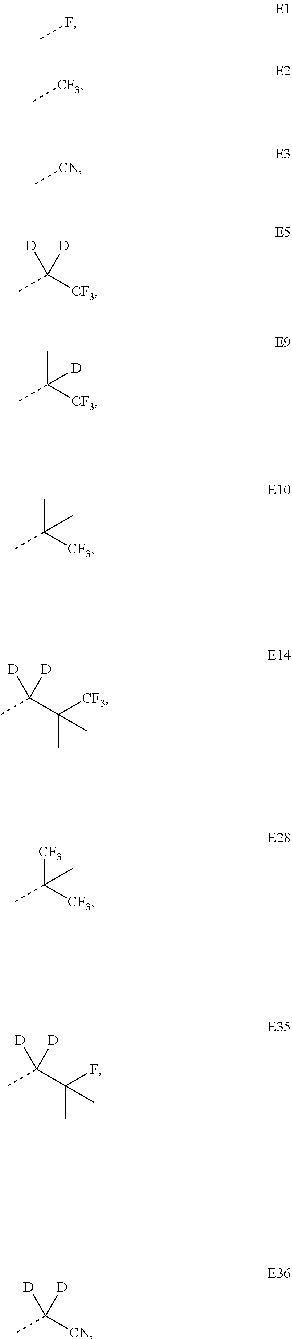

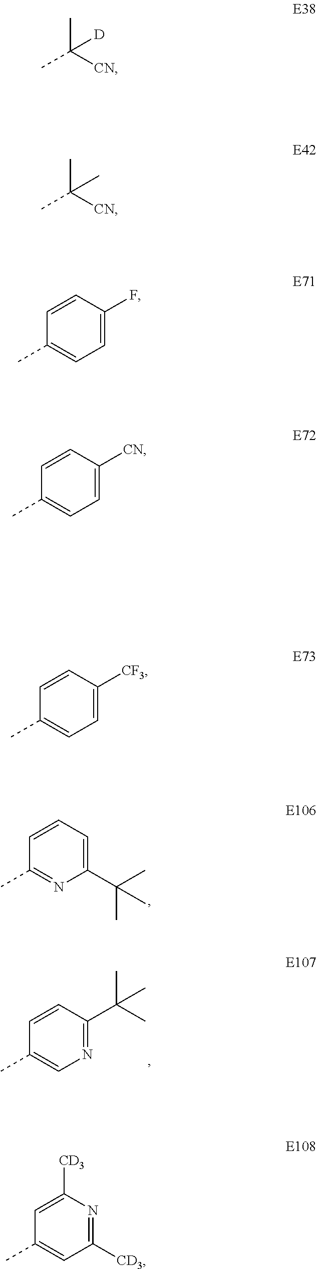

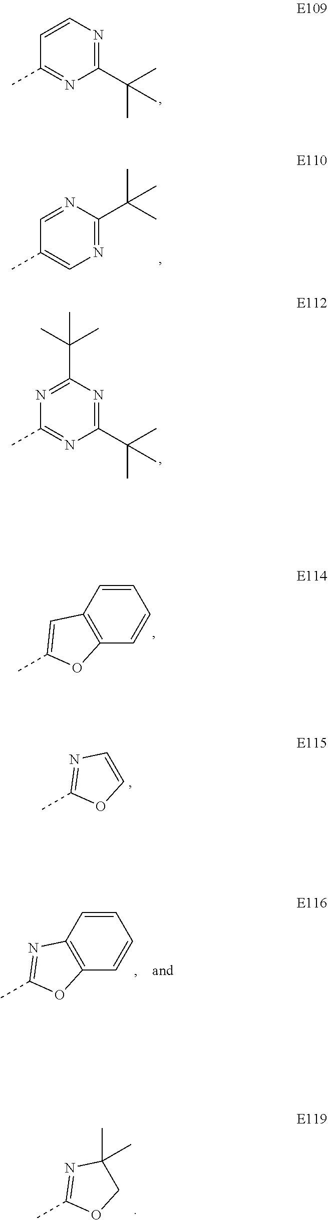

In some embodiments, the electron-withdrawing group is a π-electron deficient electron-withdrawing group. In some embodiments, the π-electron deficient electron-withdrawing group is selected from the group consisting of the following structures (LIST Pi-EWG): CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, BR^{k2}R^{k3}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated aryl, partially and fully fluorinated heteroaryl, cyano-containing aryl, cyano-containing heteroaryl, isocyanate,

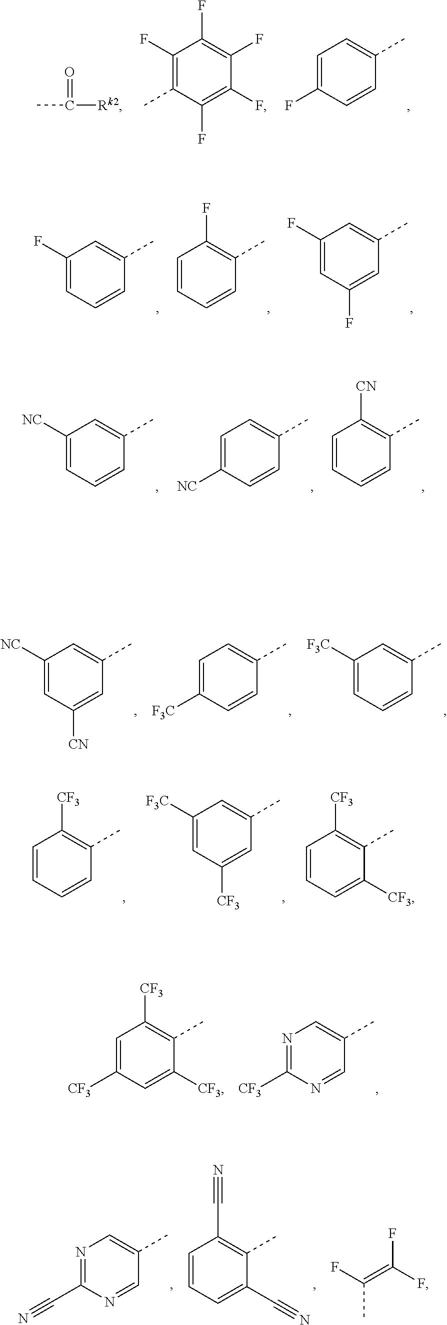

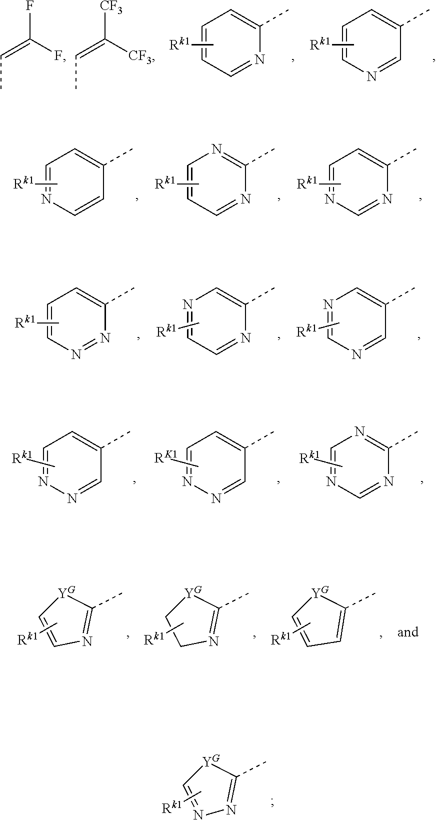

wherein the variables are the same as previously defined.
In some embodiments, L_{A} is partially deuterated.

In some embodiments, ligand L_{A} is selected from the group consisting of the structures of the following LIST 1:

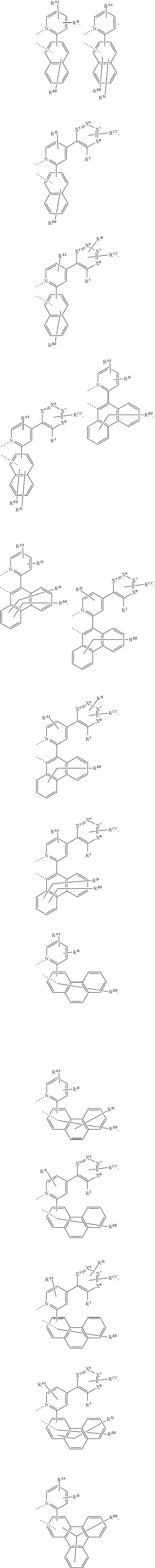

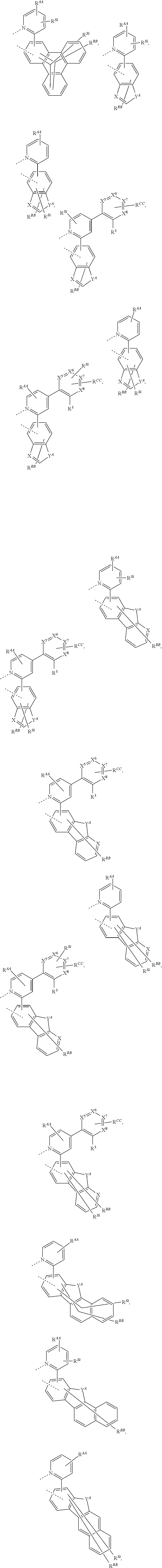

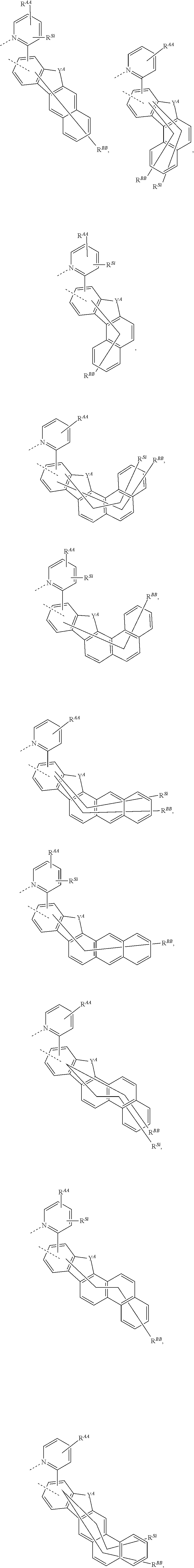

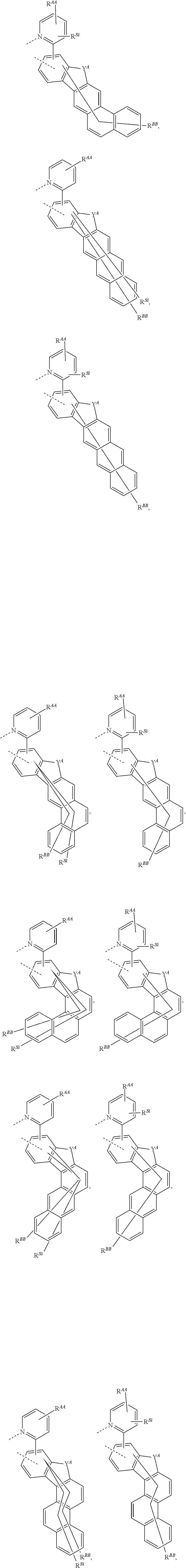

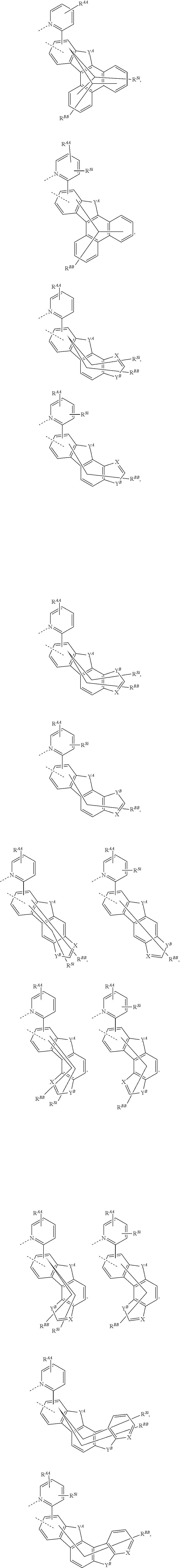

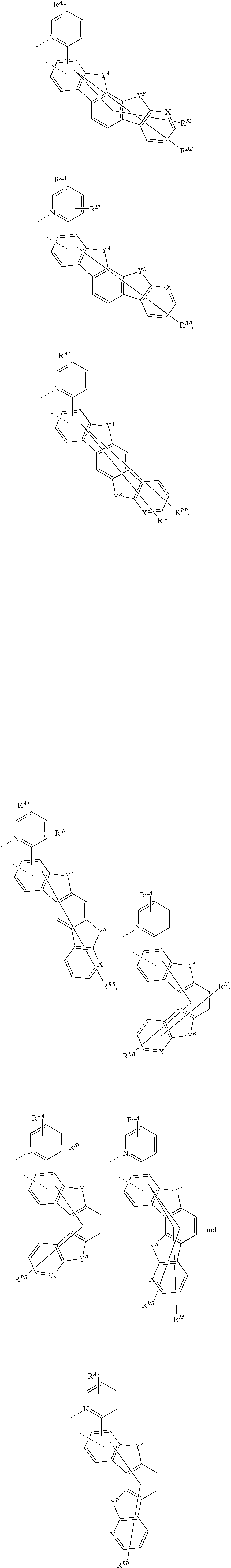

wherein:

X is C or N;

each of Y^{A} and Y^{B} is independently selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};

each of R^{AA}, R^{BB}, and R^{CC} independently represents mono to the maximum allowable substitutions, or no substitutions;

each Rₑ, R_{f}, R^{AA}, R^{BB}, R^{CC}, and R^{Si} is independently hydrogen or a substituent selected from the group consisting of the General Substituents defined herein; and

R³ is a substituent selected from the group consisting of the General Substituents defined herein;

with the proviso that R^{Si} comprises a silyl moiety; and

any two R^{A}, R^{B}, R^{C}, R^{α}, and R^{β} may be joined or fused to form a ring.

In some embodiments with a ligand L_{A} of LIST 1, each of Y^{A} and Y^{B} is independently selected from the group consisting of O, S, Se, NRₑ, CRₑR_{f}, and SiRₑR_{f}. In some embodiments with a ligand L_{A} of LIST 1, each of Y^{A} and Y^{B} is independently S or O.

In some embodiments with a ligand L_{A} of LIST 1, R^{Si} is a silyl group having a structure of —SiR^{Sa}R^{Sb}R^{Sc}. In some embodiments with a ligand L_{A} of LIST 1, R^{Si} is a silyl group selected from the Silyl List defined herein.

In some embodiments with a ligand L_{A} of LIST 1, R^{Si} comprises a silyl group having a structure of —SiR^{Sa}R^{Sb}R^{Sc}. In some embodiments with a ligand L_{A} of LIST 1, R^{Si} comprises a silyl group selected from the Silyl List defined herein.

In some embodiments with a ligand L_{A} of LIST 1, at least one substituent adjacent to the bond with the silyl moiety is not H. In some embodiments with a ligand L_{A} of LIST 1, each substituent adjacent to the bond with the silyl moiety is not H.

In some embodiments where ligand L_{A} is selected from LIST 1, at least one of R^{AA}, R^{BB}, or R^{CC} is partially or fully deuterated. In some embodiments, at least one R^{AA} is partially or fully deuterated. In some embodiments, at least one R^{BB} is partially or fully deuterated. In some embodiments, at least one R^{CC} is partially or fully deuterated. In some embodiments, at least one Rₑ or R_{f} is partially or fully deuterated.

In some embodiments where ligand L_{A} is selected from LIST 1, at least one R^{AA} is or comprises an electron-withdrawing group from the LIST EWG 1 as defined herein. In some embodiments, at least one R^{AA} is or comprises an electron-withdrawing group from the LIST EWG 2 as defined herein. In some embodiments, at least one R^{AA} is or comprises an electron-withdrawing group from the LIST EWG 3 as defined herein. In some embodiments, at least one R^{AA} is or comprises an electron-withdrawing group from the LIST EWG 4 as defined herein. In some embodiments, at least one R^{AA} is or comprises an electron-withdrawing group from the LIST Pi-EWG as defined herein.

In some embodiments where ligand L_{A} is selected from LIST 1, at least one R^{BB} is or comprises an electron-withdrawing group from the LIST EWG 1 as defined herein. In some embodiments, at least one R^{BB} is or comprises an electron-withdrawing group from the LIST EWG 2 as defined herein. In some embodiments, at least one R^{BB} is or comprises an electron-withdrawing group from the LIST EWG 3 as defined herein. In some embodiments, at least one R^{BB} is or comprises an electron-withdrawing group from the LIST EWG 4 as defined herein. In some embodiments, at least one R^{BB} is or comprises an electron-withdrawing group from the LIST Pi-EWG as defined herein.

In some embodiments where ligand L_{A} is selected from LIST 1, at least one R^{CC} is or comprises an electron-withdrawing group from the LIST EWG 1 as defined herein. In some embodiments, at least one R^{CC} is or comprises an electron-withdrawing group from the LIST EWG 2 as defined herein. In some embodiments, at least one R^{CC} is or comprises an electron-withdrawing group from the LIST EWG 3 as defined herein. In some embodiments, at least one R^{CC} is or comprises an electron-withdrawing group from the LIST EWG 4 as defined herein. In some embodiments, at least one R^{CC} is or comprises an electron-withdrawing group from the LIST Pi-EWG as defined herein.

In some embodiments, the ligand L_{A} is selected from the group consisting of the structures of the following LIST 2:

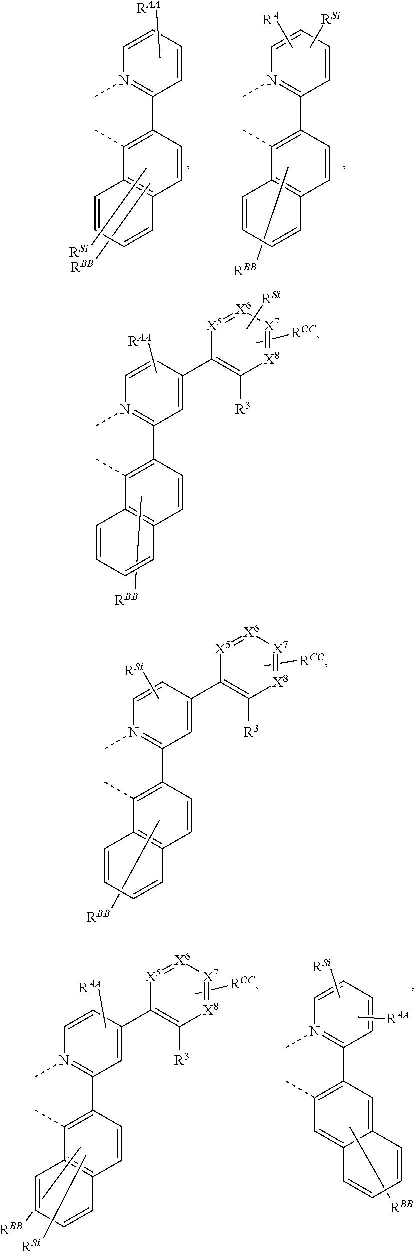

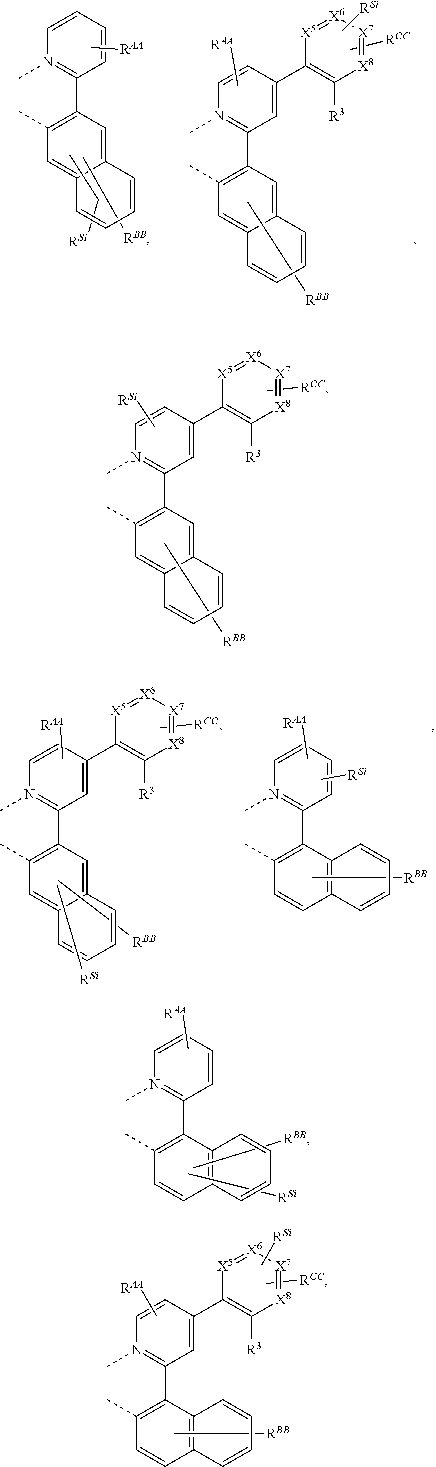

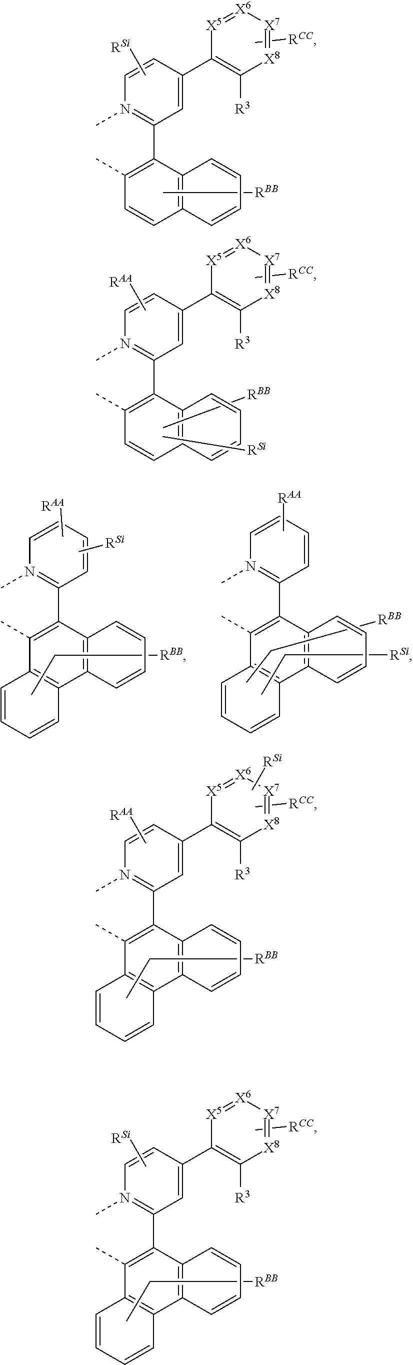

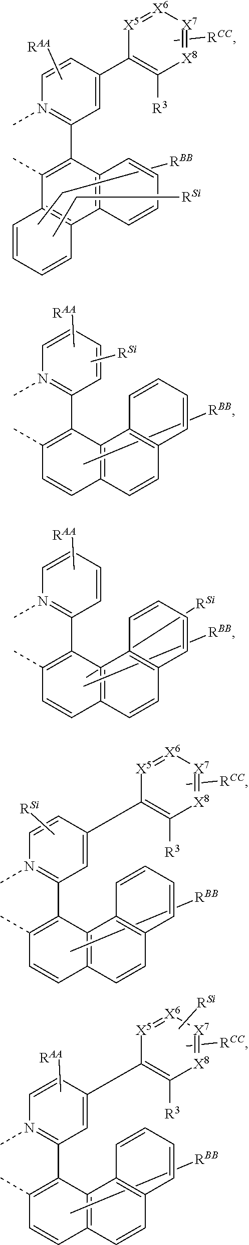

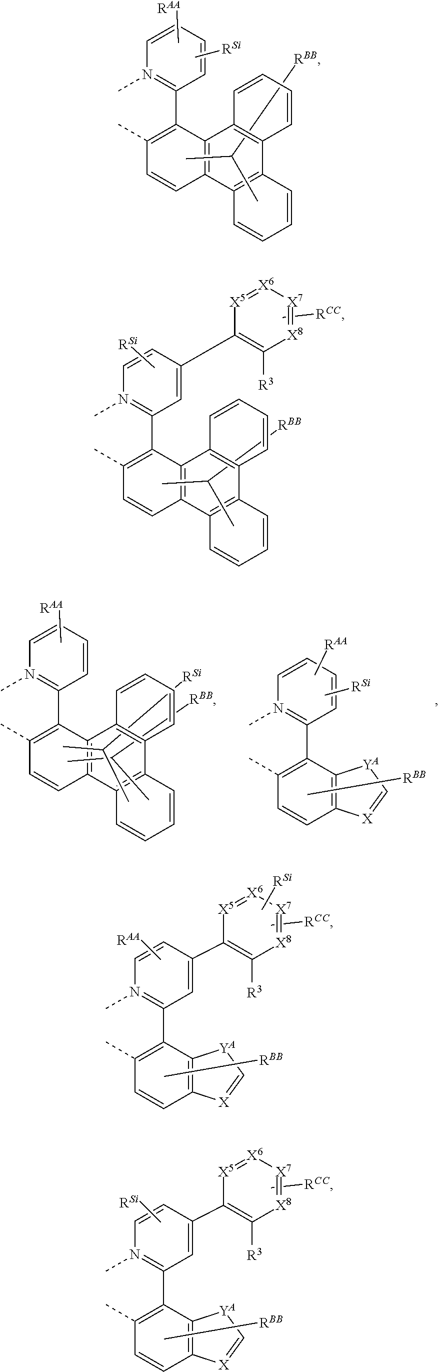

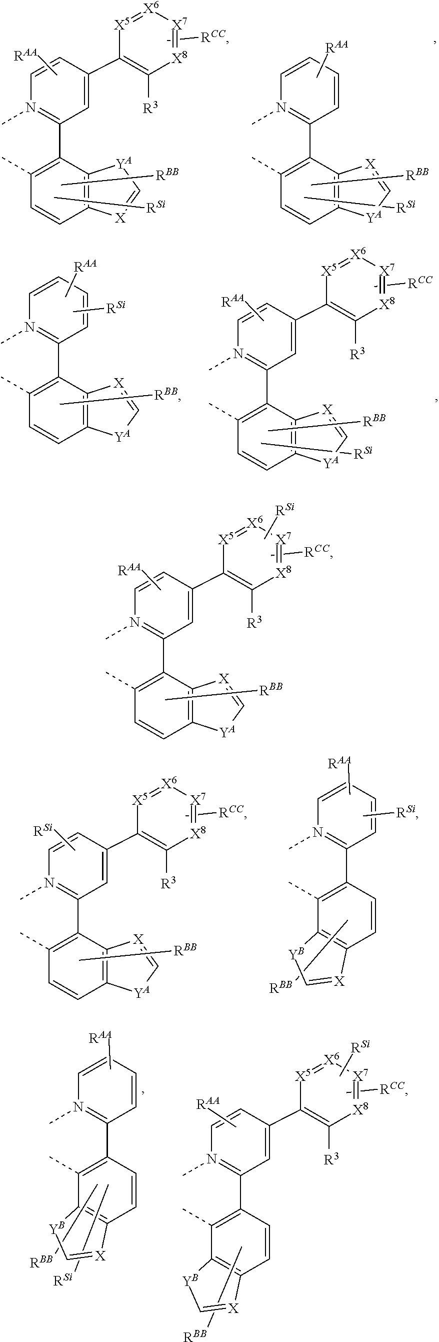

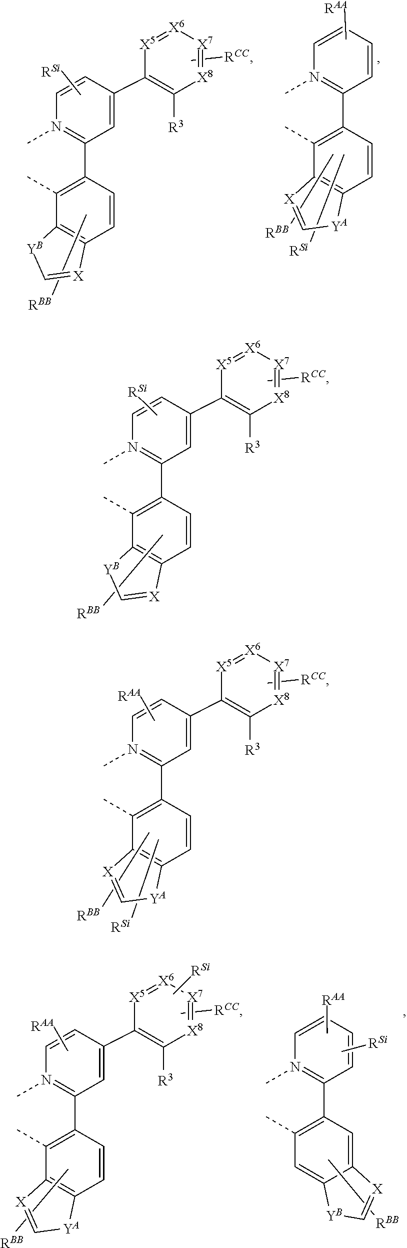

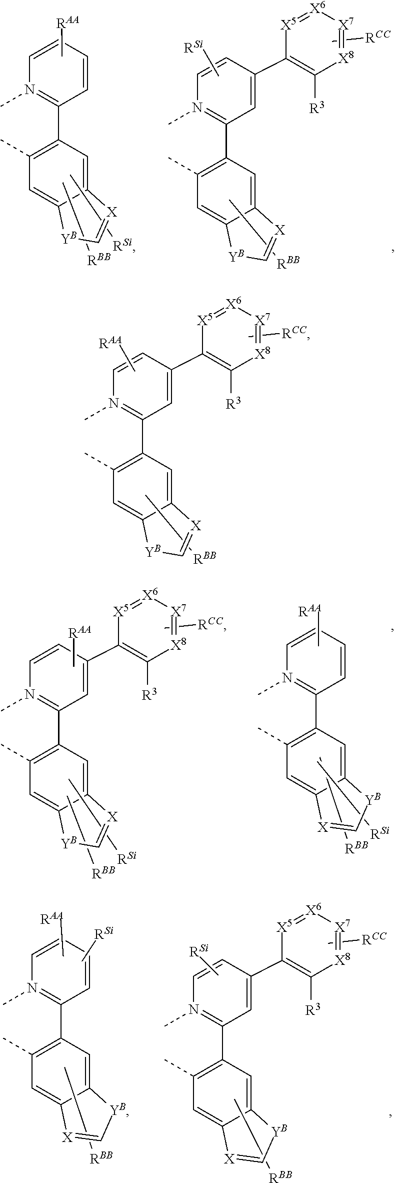

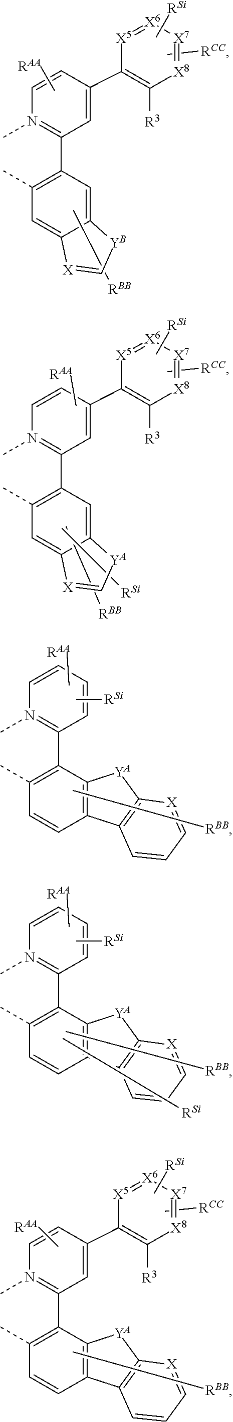

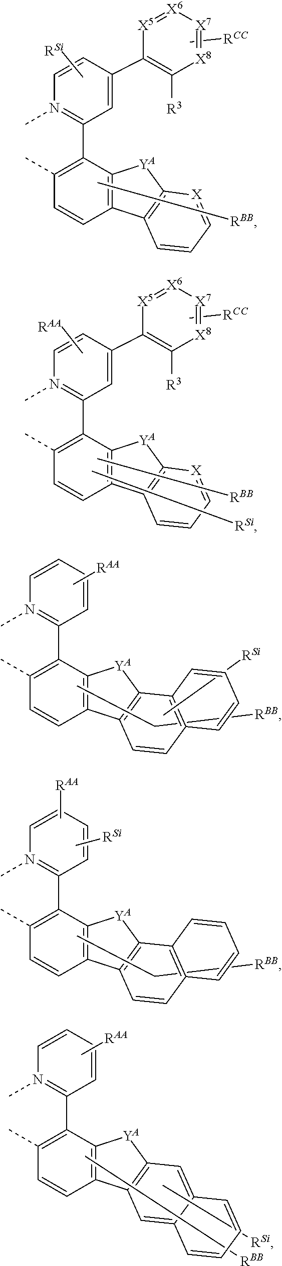

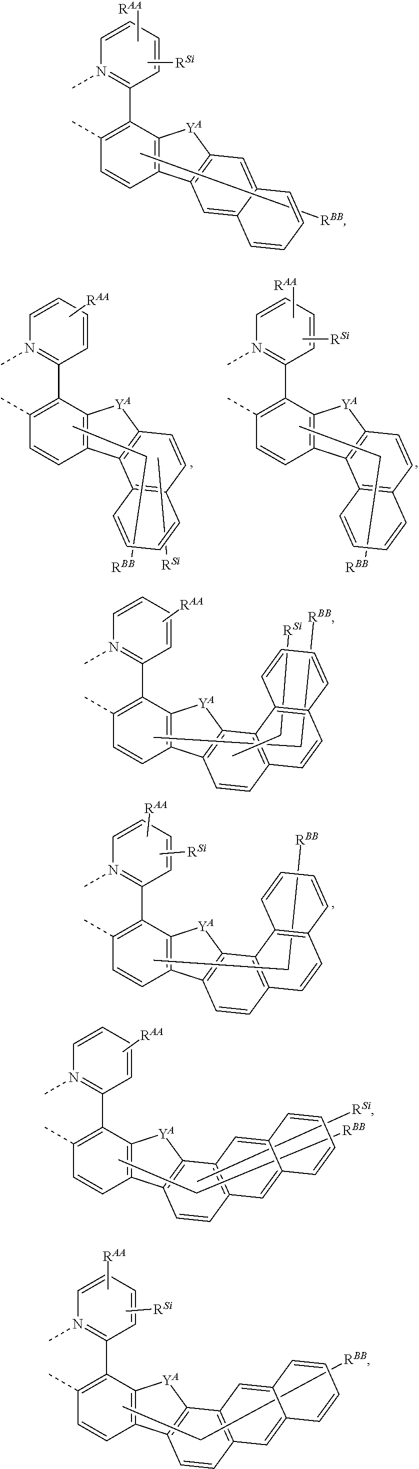

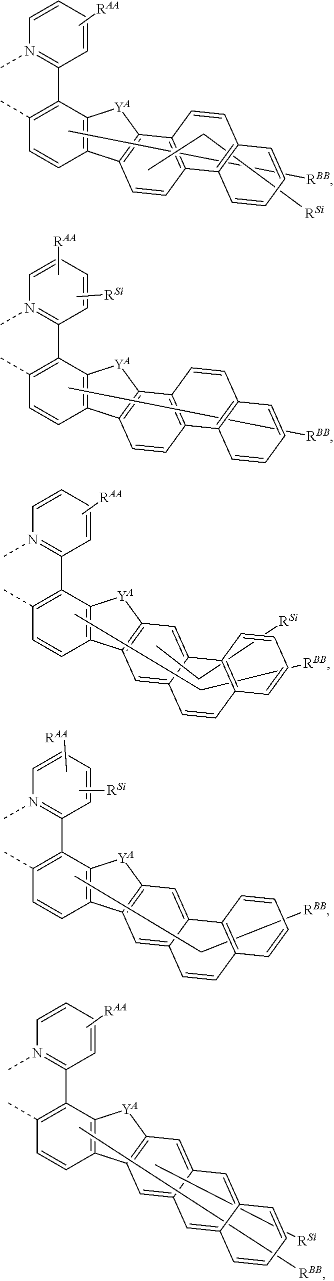

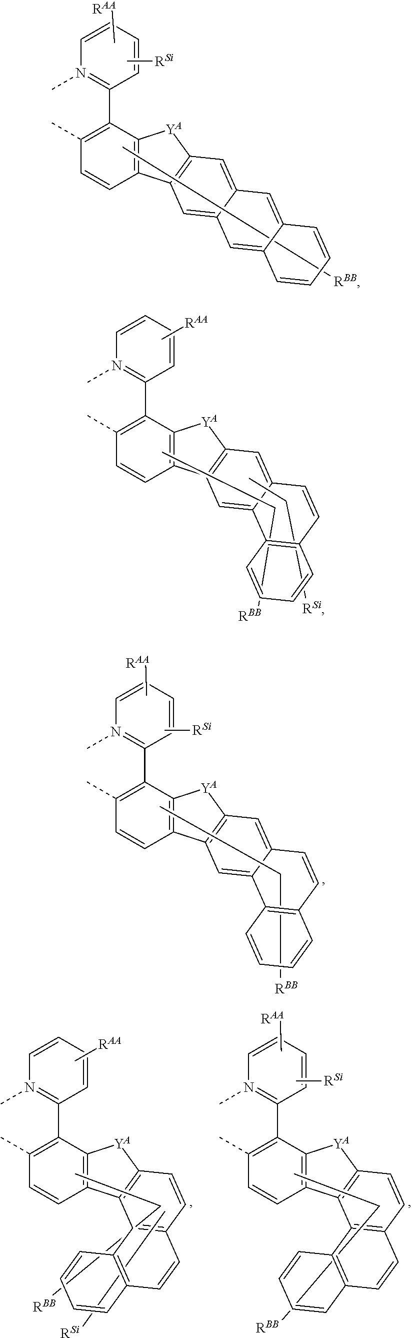

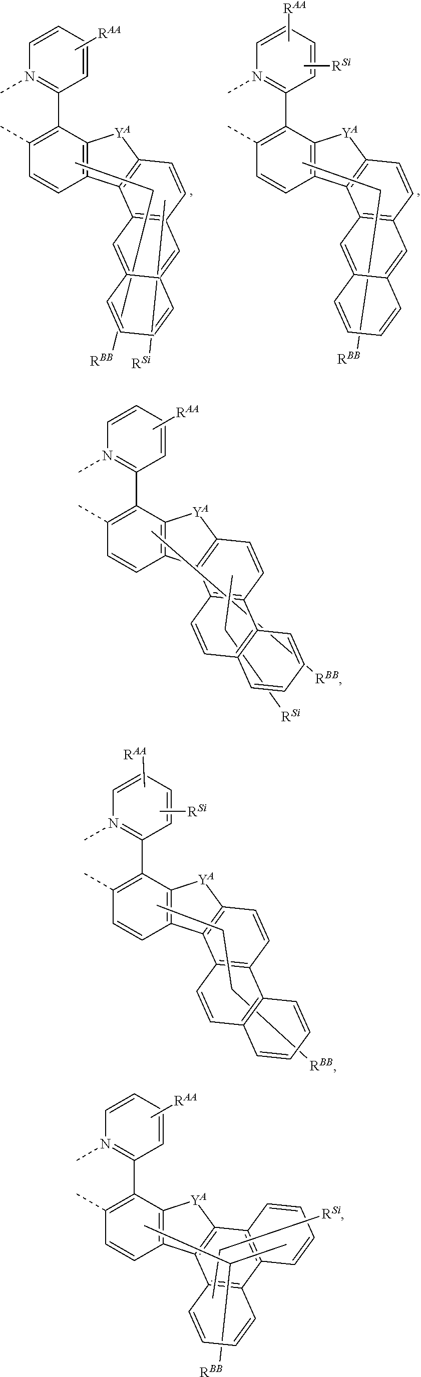

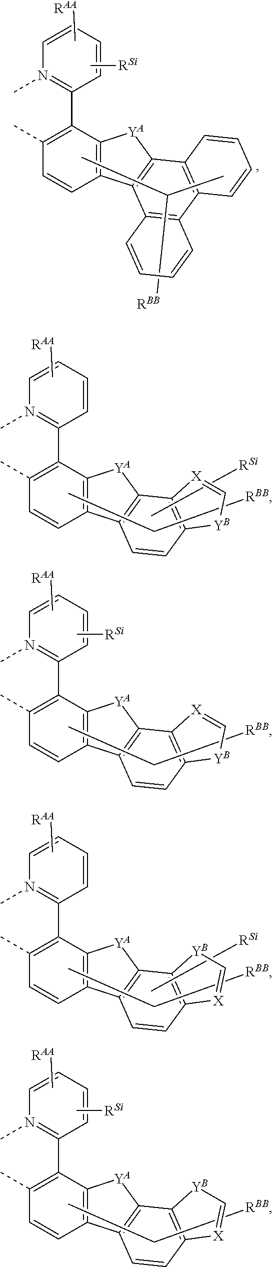

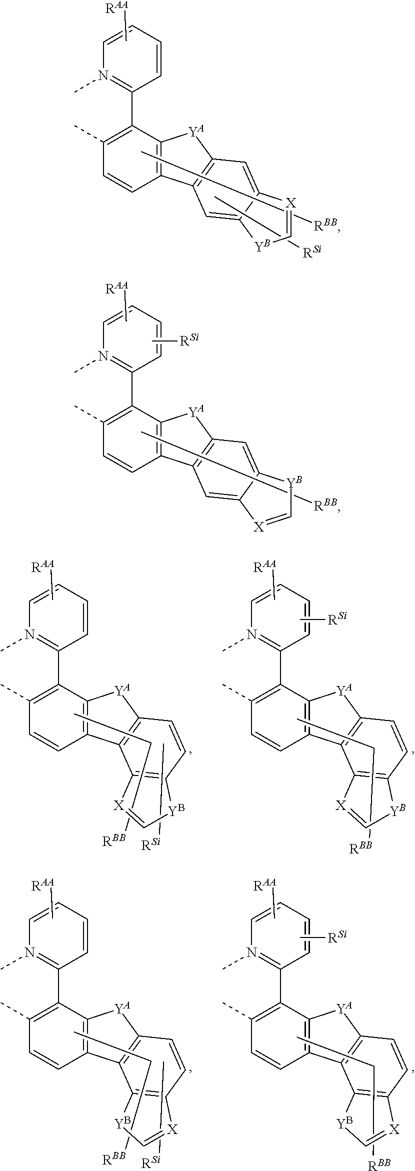

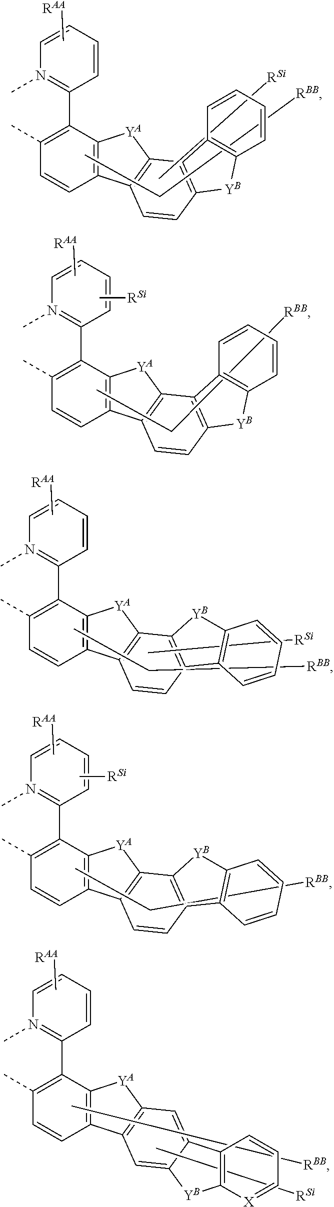

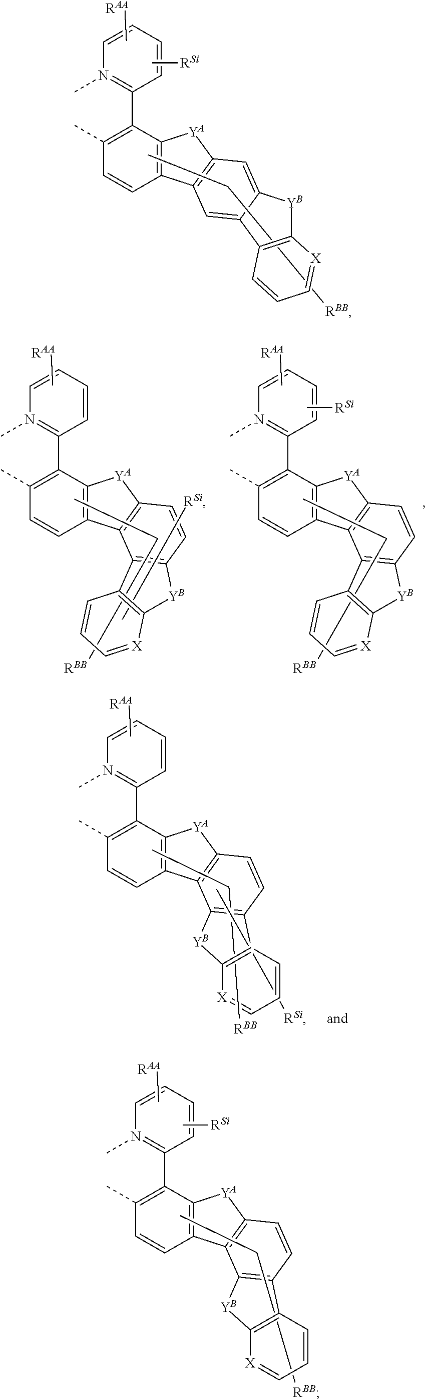

wherein:

X is C or N;

each of Y^{A} and Y^{B} is independently selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};

each of R^{AA}, R^{BB}, and R^{CC} independently represents mono to the maximum allowable substitutions, or no substitutions;

each Rₑ, R_{f}, R^{AA}, R^{BB}, R^{CC,} and R^{Si} is independently hydrogen or a substituent selected from the group consisting of the General Substituents defined herein; and

R³ is a substituent selected from the group consisting of the General Substituents defined herein;

with the proviso that R^{Si} comprises a silyl moiety; and

any two R^{A}, R^{B}, R^{C}, R^{α}, and R^{β} may be joined or fused to form a ring.

In some embodiments with a ligand L_{A} of LIST 2, each of Y^{A} and Y^{B} is independently selected from the group consisting of O, S, Se, NRₑ, CRₑR_{f}, and SiRₑR_{f}. In some embodiments with a ligand L_{A} of LIST 2, each of Y^{A} and Y^{B} is independently S or O. In some embodiments with a ligand L_{A} of LIST 2, R^{Si} comprises a silyl group having a structure of —SiR^{Sa}R^{Sb}R^{Sc}. In some embodiments with a ligand L_{A} of LIST 2, R^{Si} comprises a silyl group selected from the group consisting of the structures of Silyl List defined herein.

In some embodiments with a ligand L_{A} of LIST 2, R^{Si} is a silyl group having a structure of —SiR^{Sa}R^{Sb}R_{Sc}. In some embodiments with a ligand L_{A} of LIST 2, R^{Si} is a silyl group selected from the group consisting of the structures of Silyl List defined herein.

In some embodiments with a ligand L_{A} of LIST 2, at least one substituent adjacent to the bond with the silyl moiety is not H. In some embodiments with a ligand L_{A} of LIST 2, each substituent adjacent to the bond with the silyl moiety is not H.

In some embodiments where ligand L_{A} is selected from LIST 2, at least one of R^{AA}, R^{BB}, or R^{CC} is partially or fully deuterated. In some embodiments, at least one R^{AA} is partially or fully deuterated. In some embodiments, at least one R^{BB} is partially or fully deuterated. In some embodiments, at least one R^{CC} is partially or fully deuterated. In some embodiments, at least one Rₑ or R_{f} is partially or fully deuterated.

In some embodiments where ligand L_{A} is selected from LIST 2, at least one R^{AA} is or comprises an electron-withdrawing group from the LIST EWG 1 as defined herein. In some embodiments, at least one R^{AA} is or comprises an electron-withdrawing group from the LIST EWG 2 as defined herein. In some embodiments, at least one R^{AA} is or comprises an electron-withdrawing group from the LIST EWG 3 as defined herein. In some embodiments, at least one R^{AA} is or comprises an electron-withdrawing group from the LIST EWG 4 as defined herein. In some embodiments, at least one R^{AA} is or comprises an electron-withdrawing group from the LIST Pi-EWG as defined herein.

In some embodiments where ligand L_{A} is selected from LIST 2, at least one R^{BB} is or comprises an electron-withdrawing group from the LIST EWG 1 as defined herein. In some embodiments, at least one R^{BB} is or comprises an electron-withdrawing group from the LIST EWG 2 as defined herein. In some embodiments, at least one R^{BB} is or comprises an electron-withdrawing group from the LIST EWG 3 as defined herein. In some embodiments, at least one RBB is or comprises an electron-withdrawing group from the LIST EWG 4 as defined herein. In some embodiments, at least one R^{BB} is or comprises an electron-withdrawing group from the LIST Pi-EWG as defined herein.

In some embodiments where ligand L_{A} is selected from LIST 2, at least one R^{CC} is or comprises an electron-withdrawing group from the LIST EWG 1 as defined herein. In some embodiments, at least one R^{CC} is or comprises an electron-withdrawing group from the LIST EWG 2 as defined herein. In some embodiments, at least one R^{CC} is or comprises an electron-withdrawing group from the LIST EWG 3 as defined herein. In some embodiments, at least one R^{CC} is or comprises an electron-withdrawing group from the LIST EWG 4 as defined herein. In some embodiments, at least one R^{CC} is or comprises an electron-withdrawing group from the LIST Pi-EWG as defined herein.

In some embodiments, the ligand L_{A} is selected from L_{Aw}R^{m})(Rⁿ)(R^{o})(R^{p})(T), wherein w is an integer from 1 to 62, and each R^{m}, Rⁿ, R^{o}, and R^{p} is independently selected from the group consisting of R1 to R115; each T is selected from T1 to T20; wherein each of L_{A1}(R1)(R1)(R1)(R1)(T1) to L_{A2}(R115)(R115)(R115)(R115)(T20) is defined in LIST 3a below:

| Compound | Structure of compound | Compound | Structure of compound |
|---|---|---|---|
| L_{A1}(R^{m})(Rⁿ) (R^{o})(R^{p})(T), wherein L_{A1}(R1)(R1) (R1)(R1)(T1) to L_{A1}(R115) (R115)(R115) (R115)T(20), have the structure | 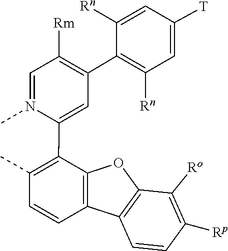 | L_{A2}(R^{m})(Rⁿ) (R^{o})(R^{p})(T), wherein L_{A2}(R1)(R1) (R1)(R1)(T1) to L_{A2}(R115) (R115)(R115) (R115)T(20), have the structure | 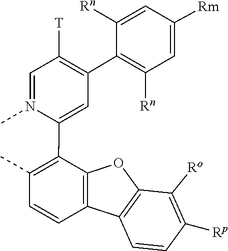 |
| L_{A3}(R^{m})(Rⁿ) (R^{o})(R^{p})(T), wherein L_{A3}(R1)(R1) (R1)(R1)(T1) to L_{A3}(R115) (R115)(R115) (R115)T(20), have the structure | 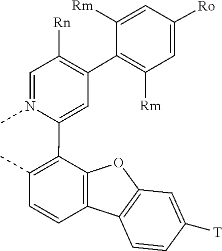 | L_{A4}(R^{m})(Rⁿ) (R^{o})(R^{p})(T), wherein L_{A4}(R1)(R1) (R1)(R1)(T1) to L_{A4}(R115) (R115)(R115) (R115)T(20), have the structure | 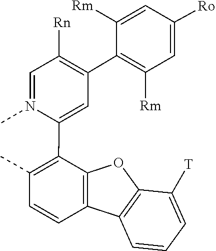 |
| L_{A5}(R^{m})(Rⁿ) (R^{o})(R^{p})(T), wherein L_{A5}(R1)(R1) (R1)(R1)(T1) to L_{A5}(R115) (R115)(R115) (R115)T(20), have the structure | 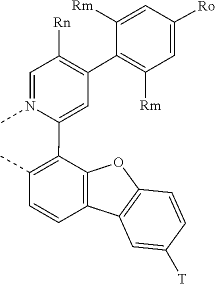 | L_{A6}(R^{m})(Rⁿ) (R^{o})(R^{p})(T), wherein L_{A6}(R1)(R1) (R1)(R1)(T1) to L_{A6}(R115) (R115)(R115) (R115)T(20), have the structure | 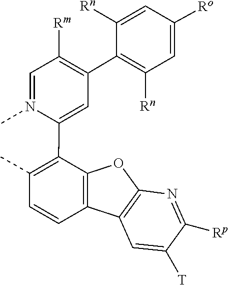 |
| L_{A7}(R^{m})(Rⁿ) (R^{o})(R^{p})(T), wherein L_{A7}(R1)(R1) (R1)(R1)(T1) to L_{A7}(R115) (R115)(R115) (R115)T(20), have the structure | 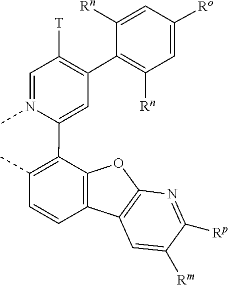 | L_{A8}(R^{m})(Rⁿ) (R^{o})(R^{p})(T), wherein L_{A8}(R1)(R1) (R1)(R1)(T1) to L_{A8}(R115) (R115)(R115) (R115)T(20), have the structure | 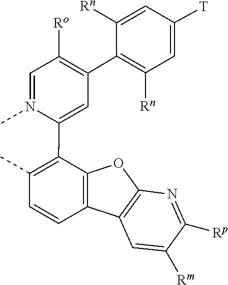 |
| L_{A9}(R^{m})(Rⁿ) (R^{o})(R^{p})(T), wherein L_{A9}(R1)(R1) (R1)(R1)(T1) to L_{A9}(R115) (R115)(R115) (R115)T(20), have the structure | 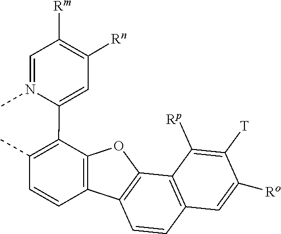 | L_{A10}(R^{m})(Rⁿ) (R^{o})(R^{p})(T), wherein L_{A10}(R1)(R1) (R1)(R1)(T1) to L_{A10}(R115) (R115)(R115) (R115)T(20), have the structure | 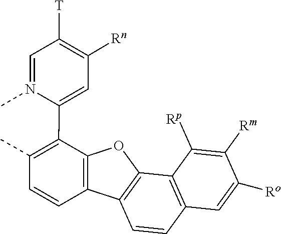 |
| L_{A11}(R^{m})(Rⁿ) (R^{o})(R^{p})(T), wherein L_{A11}(R1)(R1) (R1)(R1)(T1) to L_{A11}(R115) (R115)(R115) (R115)T(20), have the structure | 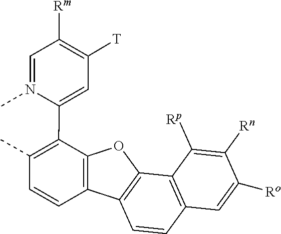 | L_{A12}(R^{m})(Rⁿ) (R^{o})(R^{p})(T), wherein L_{A12}(R1)(R1) (R1)(R1)(T1) to L_{A12}(R115) (R115)(R115) (R115)T(20), have the structure | 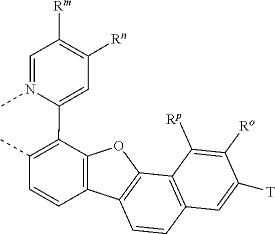 |
| L_{A13}(R^{m})(Rⁿ) (R^{o})(R^{p})(T), wherein L_{A13}(R1)(R1) (R1)(R1)(T1) to L_{A13}(R115) (R115)(R115) (R115)T(20), have the structure | 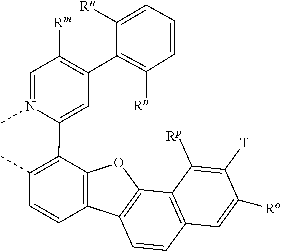 | L_{A14}(R^{m})(Rⁿ) (R^{o})(R^{p})(T), wherein L_{A14}(R1)(R1) (R1)(R1)(T1) to L_{A14}(R115) (R115)(R115) (R115)T(20), have the structure | 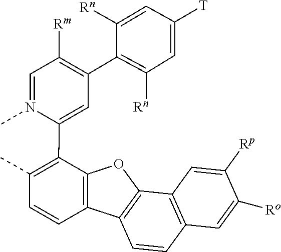 |
| L_{A15}(R^{m})(Rⁿ) (R^{o})(R^{p})(T), wherein L_{A15}(R1)(R1) (R1)(R1)(T1) to L_{A15}(R115) (R115)(R115) (R115)T(20), have the structure | 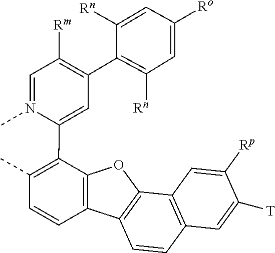 | L_{A16}(R^{m})(Rⁿ) (R^{o})(R^{p})(T), wherein L_{A16}(R1)(R1) (R1)(R1)(T1) to L_{A16}(R115) (R115)(R115) (R115)T(20), have the structure | 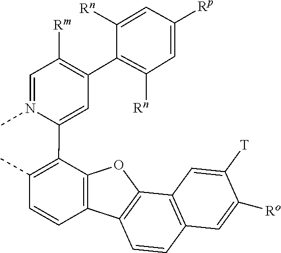 |
| L_{A17}(R^{m})(Rⁿ) (R^{o})(R^{p})(T), wherein L_{A17}(R1)(R1) (R1)(R1)(T1) to L_{A17}(R115) (R115)(R115) (R115)T(20), have the structure | 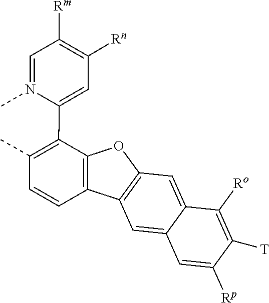 | L_{A18}(R^{m})(Rⁿ) (R^{o})(R^{p})(T), wherein L_{A18}(R1)(R1) (R1)(R1)(T1) to L_{A18}(R115) (R115)(R115) (R115)T(20), have the structure | 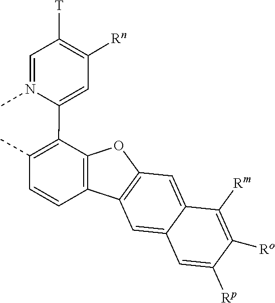 |
| L_{A19}(R^{m})(Rⁿ) (R^{o})(R^{p})(T), wherein L_{A19}(R1)(R1) (R1)(R1)(T1) to L_{A19}(R115) (R115)(R115) (R115)T(20), have the structure | 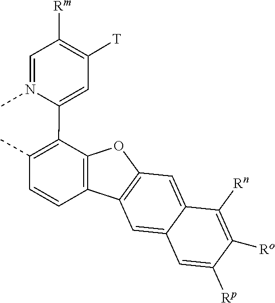 | L_{A20}(R^{m})(Rⁿ) (R^{o})(R^{p})(T), wherein L_{A20}(R1)(R1) (R1)(R1)(T1) to L_{A20}(R115) (R115)(R115) (R115)T(20), have the structure | 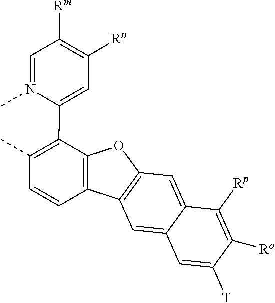 |
| L_{A21}(R^{m})(Rⁿ) (R^{o})(R^{p})(T), wherein L_{A21}(R1)(R1) (R1)(R1)(T1) to L_{A21}(R115) (R115)(R115) (R115)T(20), have the structure | 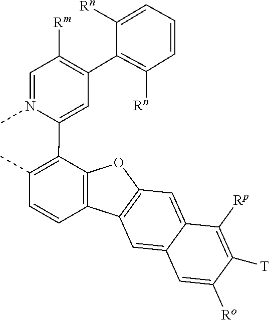 | L_{A22}(R^{m})(Rⁿ) (R^{o})(R^{p})(T), wherein L_{A22}(R1)(R1) (R1)(R1)(T1) to L_{A22}(R115) (R115)(R115) (R115)T(20), have the structure | 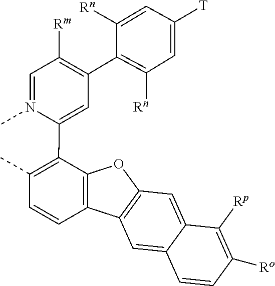 |
| L_{A23}(R^{m})(Rⁿ) (R^{o})(R^{p})(T), wherein L_{A23}(R1)(R1) (R1)(R1)(T1) to L_{A23}(R115) (R115)(R115) (R115)T(20), have the structure | 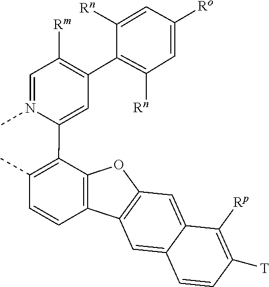 | L_{A24}(R^{m})(Rⁿ) (R^{o})(R^{p})(T), wherein L_{A24}(R1)(R1) (R1)(R1)(T1) to L_{A24}(R115) (R115)(R115) (R115)T(20), have the structure | 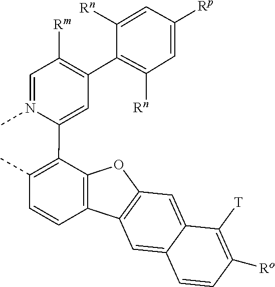 |
| L_{A25}(R^{m})(Rⁿ) (R^{o})(R^{p})(T), wherein L_{A25}(R1)(R1) (R1)(R1)(T1) to L_{A25}(R115) (R115)(R115) (R115)T(20), have the structure | 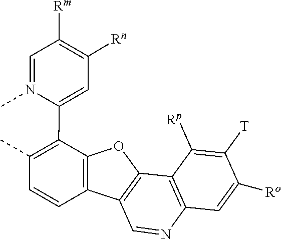 | L_{A26}(R^{m})(Rⁿ) (R^{o})(R^{p})(T), wherein L_{A26}(R1)(R1) (R1)(R1)(T1) to L_{A26}(R115) (R115)(R115) (R115)T(20), have the structure | 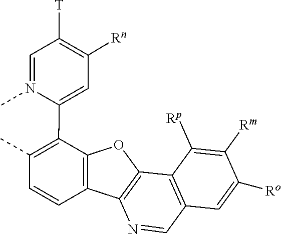 |
| L_{A27}(R^{m})(Rⁿ) (R^{o})(R^{p})(T), wherein L_{A27}(R1)(R1) (R1)(R1)(T1) to L_{A27}(R115) (R115)(R115) (R115)T(20), have the structure | 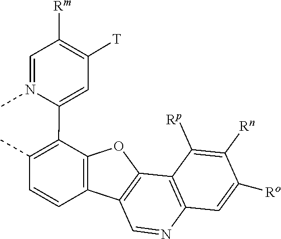 | L_{A28}(R^{m})(Rⁿ) (R^{o})(R^{p})(T), wherein L_{A28}(R1)(R1) (R1)(R1)(T1) to L_{A28}(R115) (R115)(R115) (R115)T(20), have the structure | 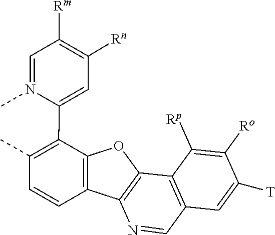 |
| L_{A29}(R^{m})(Rⁿ) (R^{o})(R^{p})(T), wherein L_{A29}(R1)(R1) (R1)(R1)(T1) to L_{A29}(R115) (R115)(R115) (R115)T(20), have the structure | 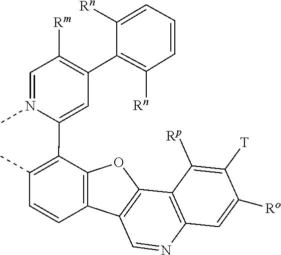 | L_{A30}(R^{m})(Rⁿ) (R^{o})(R^{p})(T), wherein L_{A30}(R1)(R1) (R1)(R1)(T1) to L_{A30}(R115) (R115)(R115) (R115)T(20), have the structure | 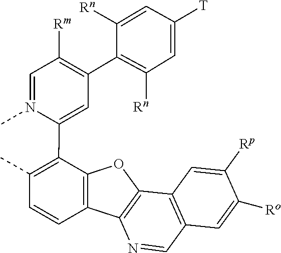 |
| L_{A31}(R^{m})(Rⁿ) (R^{o})(R^{p})(T), wherein L_{A31}(R1)(R1) (R1)(R1)(T1) to L_{A31}(R115) (R115)(R115) (R115)T(20), have the structure | 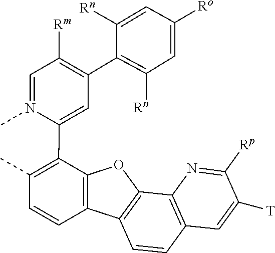 | L_{A32}(R^{m})(Rⁿ) (R^{o})(R^{p})(T), wherein L_{A32}(R1)(R1) (R1)(R1)(T1) to L_{A32}(R115) (R115)(R115) (R115)T(20), have the structure | 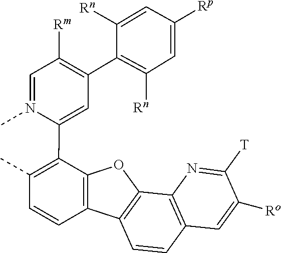 |
| L_{A33}(R^{m})(Rⁿ) (R^{o})(R^{p})(T), wherein L_{A33}(R1)(R1) (R1)(R1)(T1) to L_{A33}(R115) (R115)(R115) (R115)T(20), have the structure | 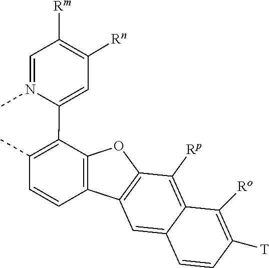 | L_{A34}(R^{m})(Rⁿ) (R^{o})(R^{p})(T), wherein L_{A34}(R1)(R1) (R1)(R1)(T1) to L_{A34}(R115) (R115)(R115) (R115)T(20), have the structure | 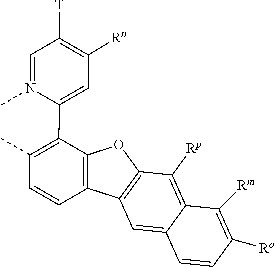 |
| L_{A35}(R^{m})(Rⁿ) (R^{o})(R^{p})(T), wherein L_{A35}(R1)(R1) (R1)(R1)(T1) to L_{A35}(R115) (R115)(R115) (R115)T(20), have the structure | 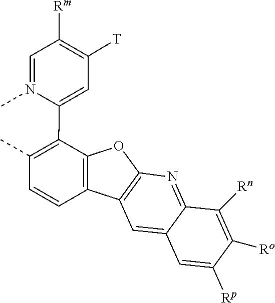 | L_{A36}(R^{m})(Rⁿ) (R^{o})(R^{p})(T), wherein L_{A36}(R1)(R1) (R1)(R1)(T1) to L_{A36}(R115) (R115)(R115) (R115)T(20), have the structure | 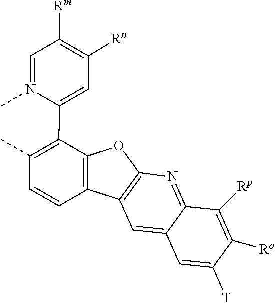 |
| L_{A37}(R^{m})(Rⁿ) (R^{o})(R^{p})(T), wherein L_{A37}(R1)(R1) (R1)(R1)(T1) to L_{A37}(R115) (R115)(R115) (R115)T(20), have the structure | 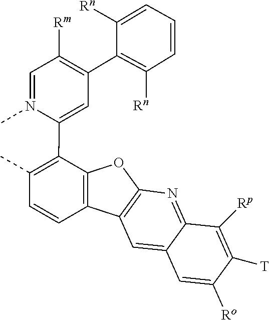 | L_{A38}(R^{m})(Rⁿ) (R^{o})(R^{p})(T), wherein L_{A38}(R1)(R1) (R1)(R1)(T1) to L_{A38}(R115) (R115)(R115) (R115)T(20), have the structure | 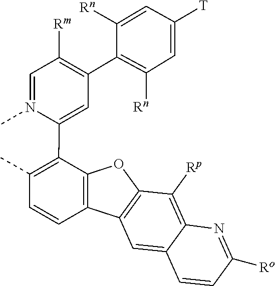 |
| L_{A39}(R^{m})(Rⁿ) (R^{o})(R^{p})(T), wherein L_{A39}(R1)(R1) (R1)(R1)(T1) to L_{A39}(R115) (R115)(R115) (R115)T(20), have the structure | 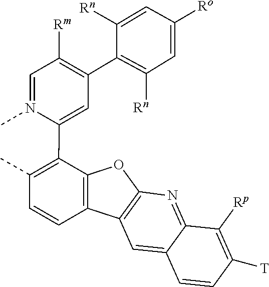 | L_{A40}(R^{m})(Rⁿ) (R^{o})(R^{p})(T), wherein L_{A40}(R1)(R1) (R1)(R1)(T1) to L_{A40}(R115) (R115)(R115) (R115)T(20), have the structure | 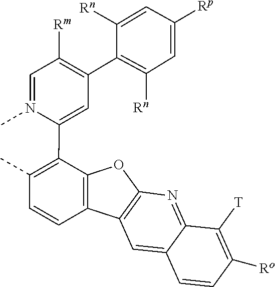 |
| L_{A41}(R^{m})(Rⁿ) (R^{o})(R^{p})(T), wherein L_{A41}(R1)(R1) (R1)(R1)(T1) to L_{A41}(R115) (R115)(R115) (R115)T(20), have the structure | 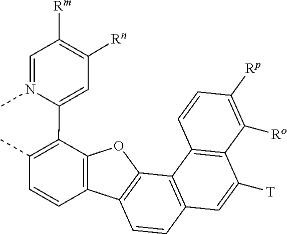 | L_{A42}(R^{m})(Rⁿ) (R^{o})(R^{p})(T), wherein L_{A42}(R1)(R1) (R1)(R1)(T1) to L_{A42}(R115) (R115)(R115) (R115)T(20), have the structure | 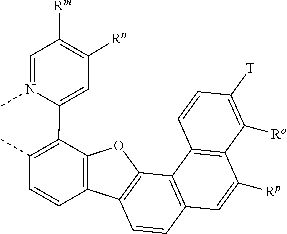 |
| L_{A43}(R^{m})(Rⁿ) (R^{o})(R^{p})(T), wherein L_{A43}(R1)(R1) (R1)(R1)(T1) to L_{A43}(R115) (R115)(R115) (R115)T(20), have the structure | 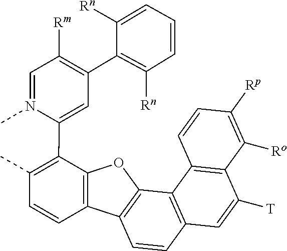 | L_{A44}(R^{m})(Rⁿ) (R^{o})(R^{p})(T), wherein L_{A44}(R1)(R1) (R1)(R1)(T1) to L_{A44}(R115) (R115)(R115) (R115)T(20), have the structure | 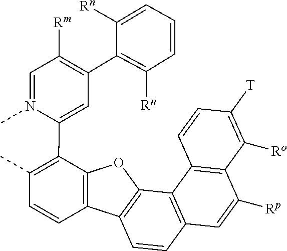 |
| L_{A45}(R^{m})(Rⁿ) (R^{o})(R^{p})(T), wherein L_{A45}(R1)(R1) (R1)(R1)(T1) to L_{A45}(R115) (R115)(R115) (R115)T(20), have the structure | 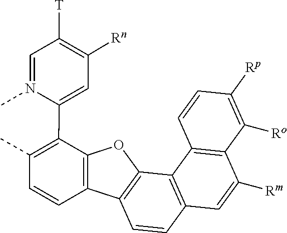 | L_{A46}(R^{m})(Rⁿ) (R^{o})(R^{p})(T), wherein L_{A46}(R1)(R1) (R1)(R1)(T1) to L_{A46}(R115) (R115)(R115) (R115)T(20), have the structure | 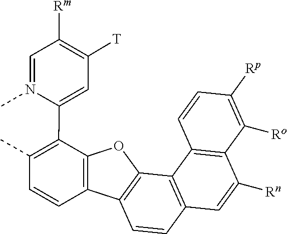 |
| L_{A47}(R^{m})(Rⁿ) (R^{o})(R^{p})(T), wherein L_{A47}(R1)(R1) (R1)(R1)(T1) to L_{A47}(R115) (R115)(R115) (R115)T(20), have the structure | 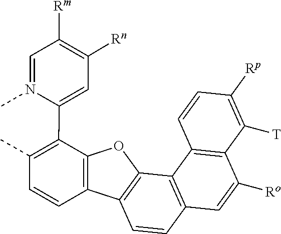 | L_{A48}(R^{m})(Rⁿ) (R^{o})(R^{p})(T), wherein L_{A48}(R1)(R1) (R1)(R1)(T1) to L_{A48}(R115) (R115)(R115) (R115)T(20), have the structure | 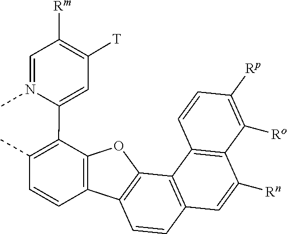 |
| L_{A49}(R^{m})(Rⁿ) (R^{o})(R^{p})(T), wherein L_{A49}(R1)(R1) (R1)(R1)(T1) to L_{A49}(R115) (R115)(R115) (R115)T(20), have the structure | 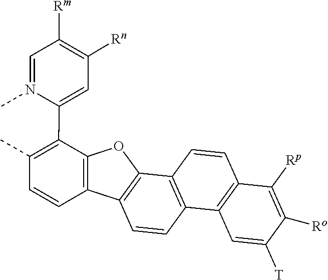 | L_{A50}(R^{m})(Rⁿ) (R^{o})(R^{p})(T), wherein L_{A50}(R1)(R1) (R1)(R1)(T1) to L_{A50}(R115) (R115)(R115) (R115)T(20), have the structure | 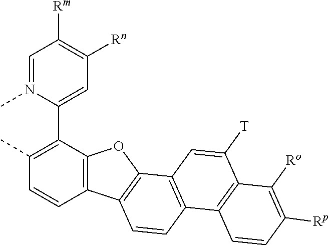 |
| L_{A51}(R^{m})(Rⁿ) (R^{o})(R^{p})(T), wherein L_{A51}(R1)(R1) (R1)(R1)(T1) to L_{A51}(R115) (R115)(R115) (R115)T(20), have the structure | 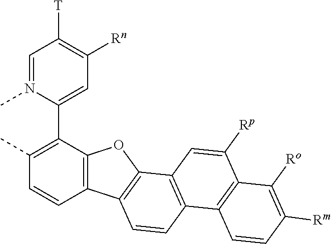 | L_{A52}(R^{m})(Rⁿ) (R^{o})(R^{p})(T), wherein L_{A52}(R1)(R1) (R1)(R1)(T1) to L_{A52}(R115) (R115)(R115) (R115)T(20), have the structure | 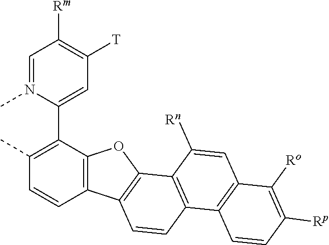 |
| L_{A53}(R^{m})(Rⁿ) (R^{o})(R^{p})(T), wherein L_{A53}(R1)(R1) (R1)(R1)(T1) to L_{A53}(R115) (R115)(R115) (R115)T(20), have the structure | 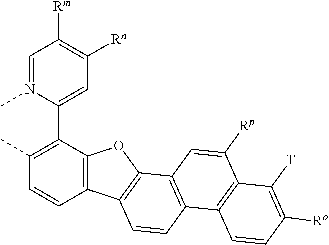 | L_{A54}(R^{m})(Rⁿ) (R^{o})(R^{p})(T), wherein L_{A54}(R1)(R1) (R1)(R1)(T1) to L_{A54}(R115) (R115)(R115) (R115)T(20), have the structure | 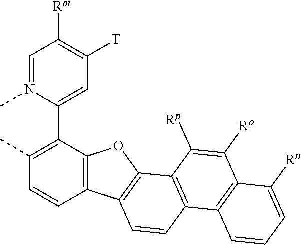 |
| L_{A55}(R^{m})(Rⁿ) (R^{o})(R^{p})(T), wherein L_{A55}(R1)(R1) (R1)(R1)(T1) to L_{A55}(R115) (R115)(R115) (R115)T(20), have the structure | 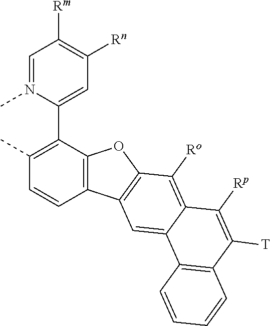 | L_{A56}(R^{m})(Rⁿ) (R^{o})(R^{p})(T), wherein L_{A56}(R1)(R1) (R1)(R1)(T1) to L_{A56}(R115) (R115)(R115) (R115)T(20), have the structure | 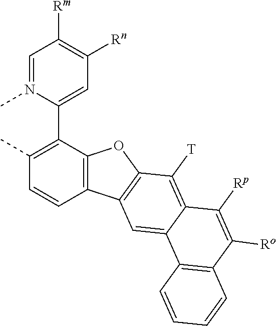 |
| L_{A57}(R^{m})(Rⁿ) (R^{o})(R^{p})(T), wherein L_{A57}(R1)(R1) (R1)(R1)(T1) to L_{A57}(R115) (R115)(R115) (R115)T(20), have the structure | 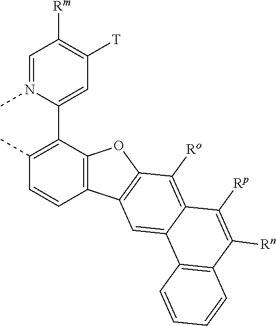 | L_{A58}(R^{m})(Rⁿ) (R^{o})(R^{p})(T), wherein L_{A58}(R1)(R1) (R1)(R1)(T1) to L_{A58}(R115) (R115)(R115) (R115)T(20), have the structure | 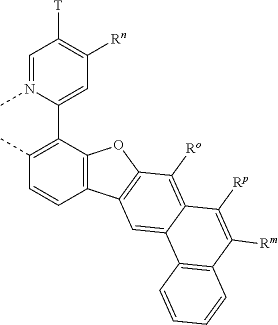 |
| L_{A59}(R^{m})(Rⁿ) (R^{o})(R^{p})(T), wherein L_{A59}(R1)(R1) (R1)(R1)(T1) to L_{A59}(R115) (R115)(R115) (R115)T(20), have the structure | 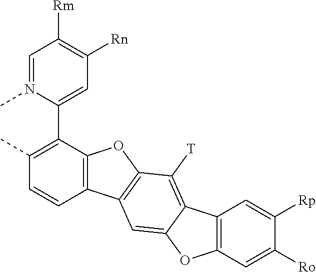 | L_{A60}(R^{m})(Rⁿ) (R^{o})(R^{p})(T), wherein L_{A60}(R1)(R1) (R1)(R1)(T1) to L_{A60}(R115) (R115)(R115) (R115)T(20), have the structure | 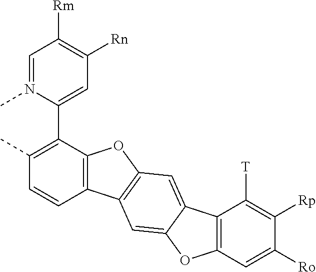 |
| L_{A61}(R^{m})(Rⁿ) (R^{o})(R^{p})(T), wherein L_{A61}(R1)(R1) (R1)(R1)(T1) to L_{A61}(R115) (R115)(R115) (R115)T(20), have the structure | 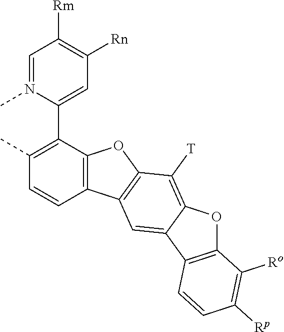 | L_{A62}(R^{m})(Rⁿ) (R^{o})(R^{p})(T), wherein L_{A62}(R1)(R1) (R1)(R1)(T1) to L_{A62}(R115) (R115)(R115) (R115)T(20), have the structure | 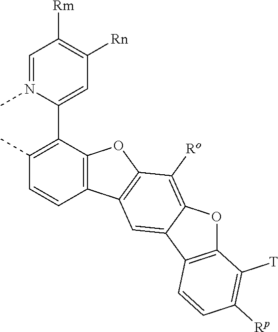 |

wherein R¹ to R¹⁴⁰ have the following structures:

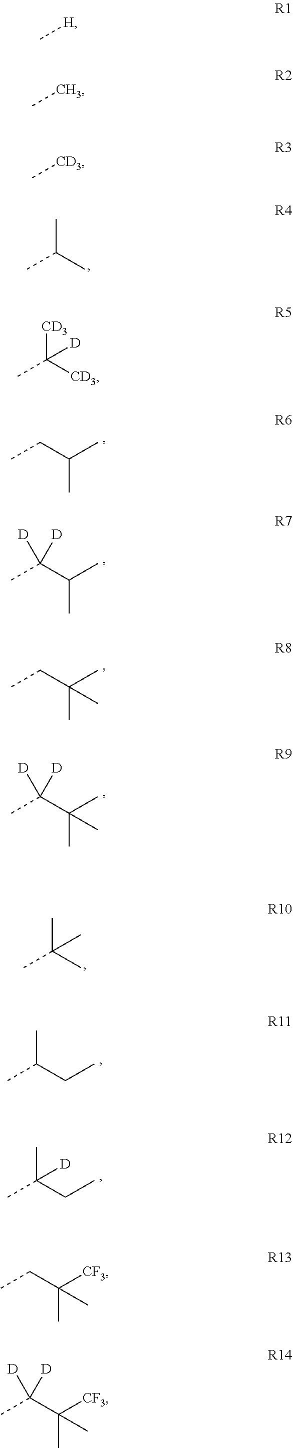

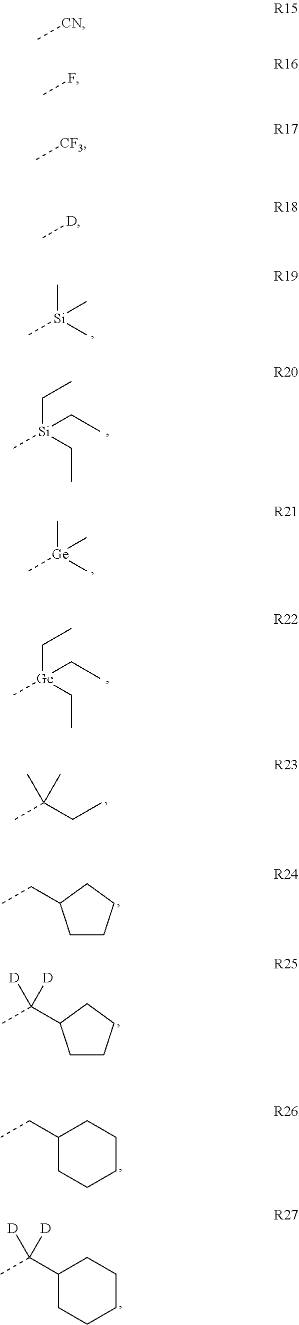

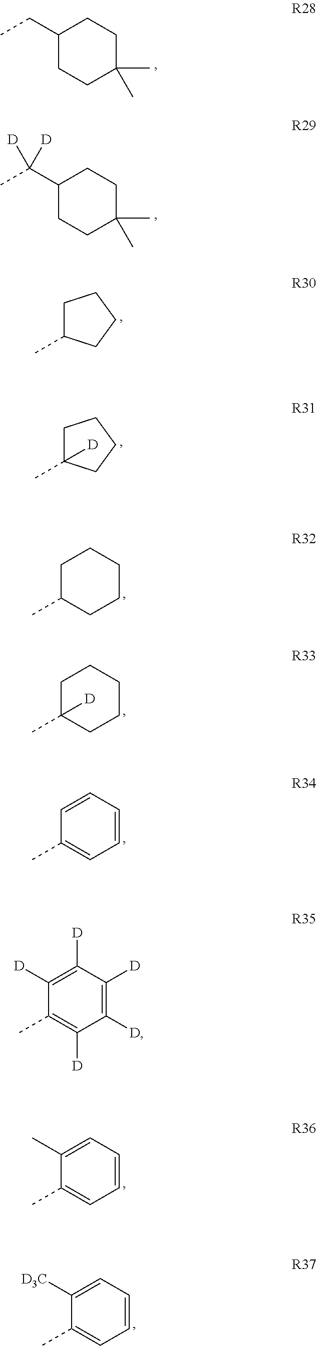

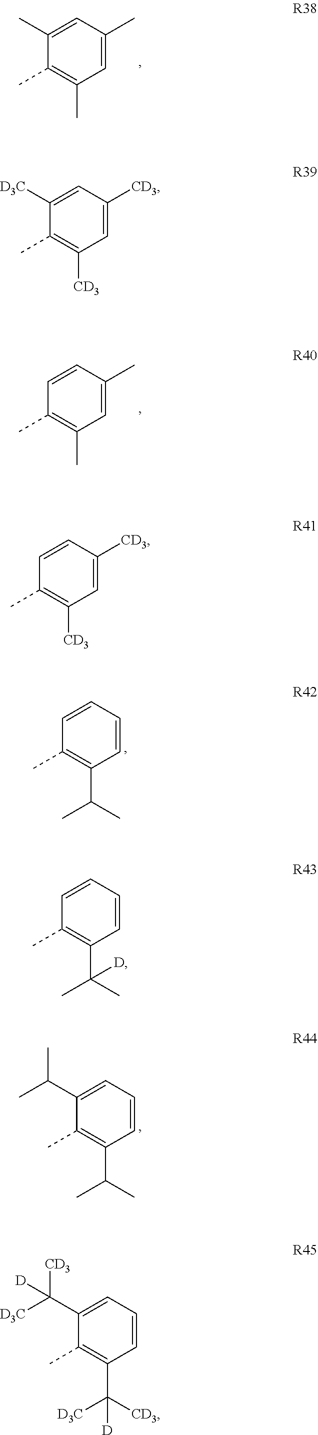

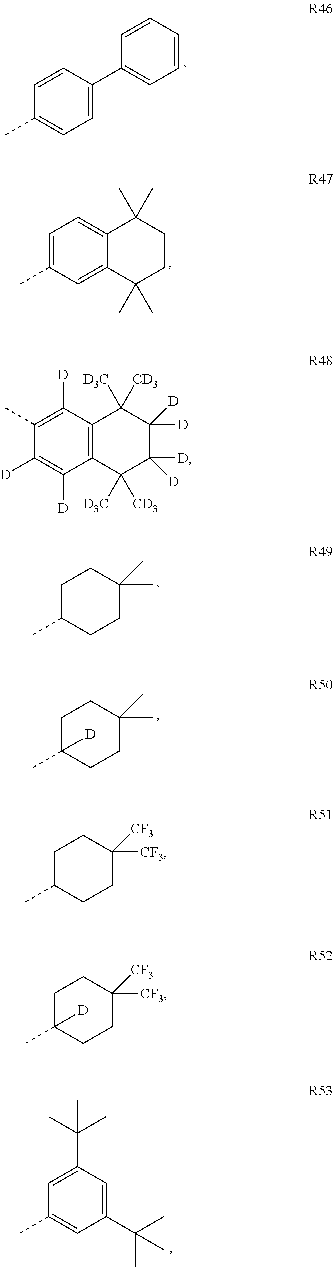

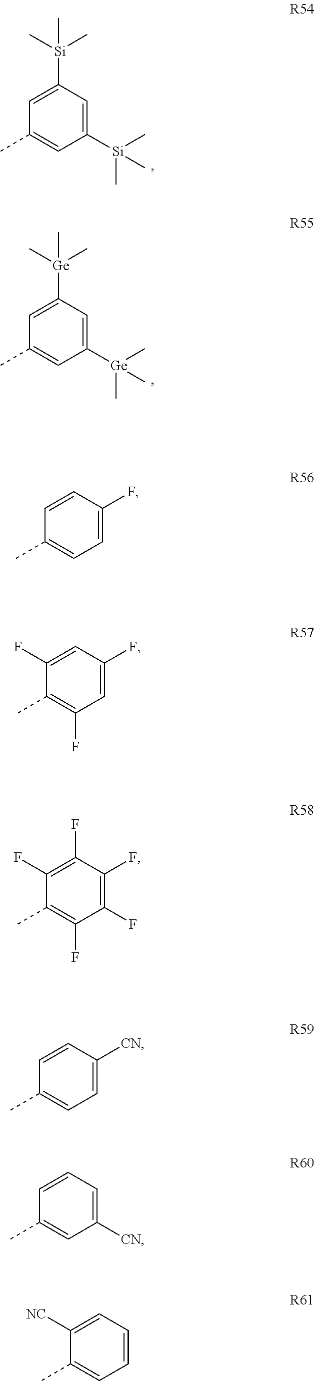

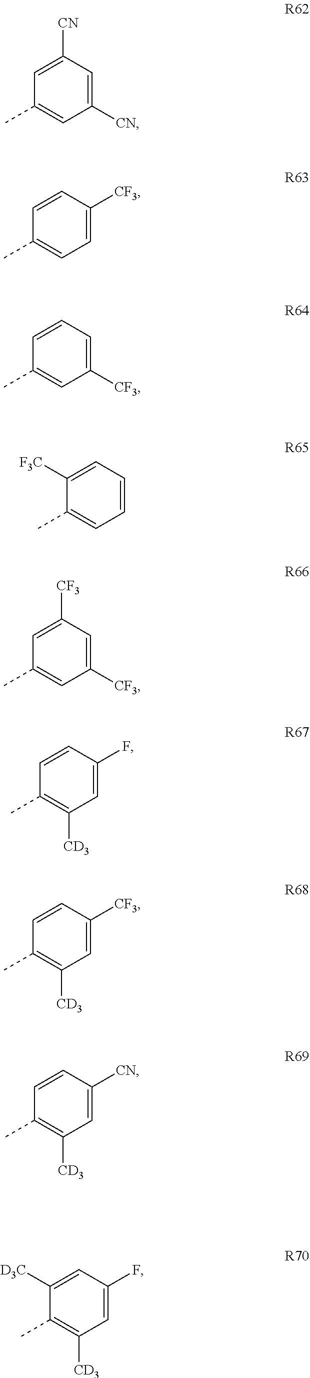

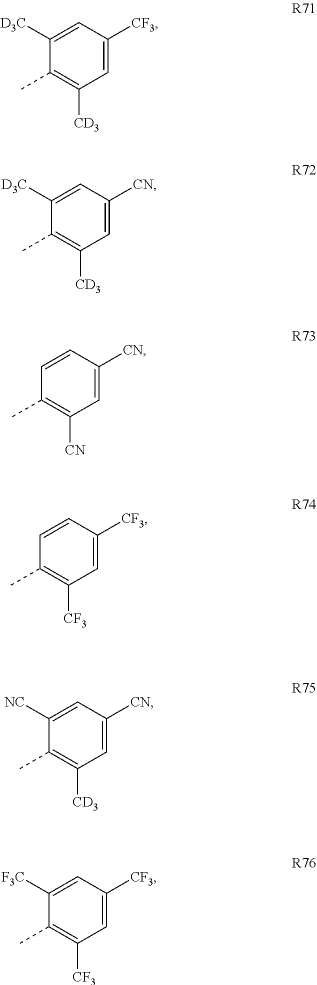

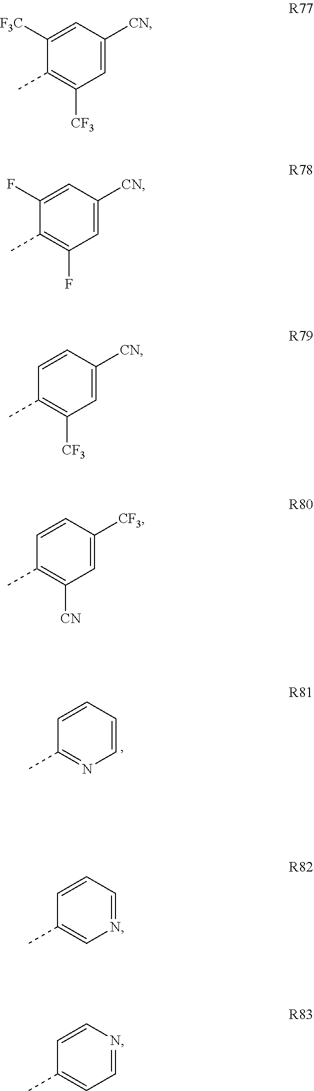

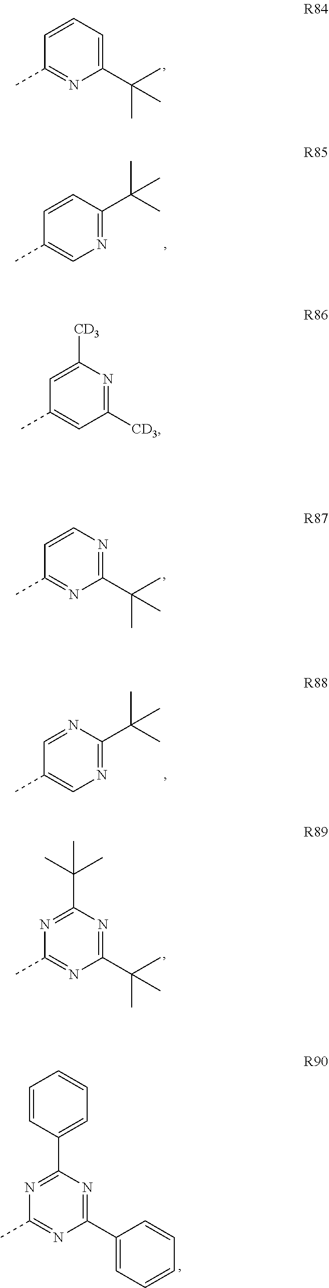

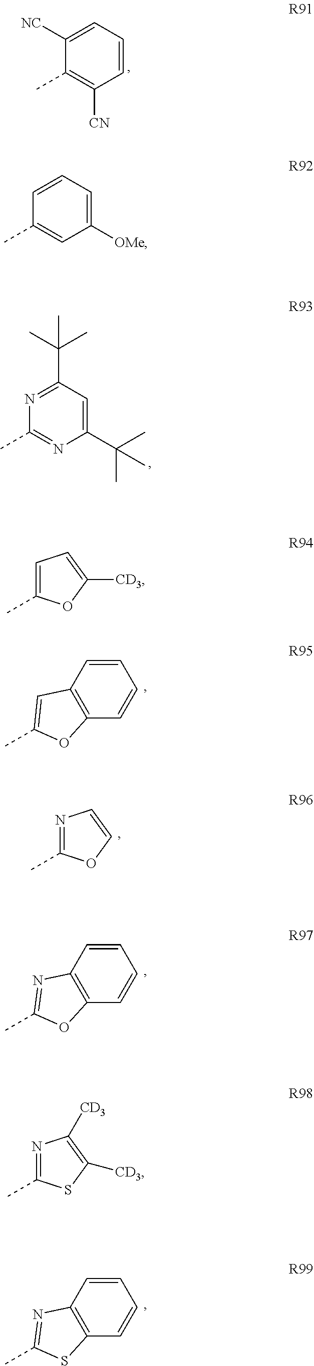

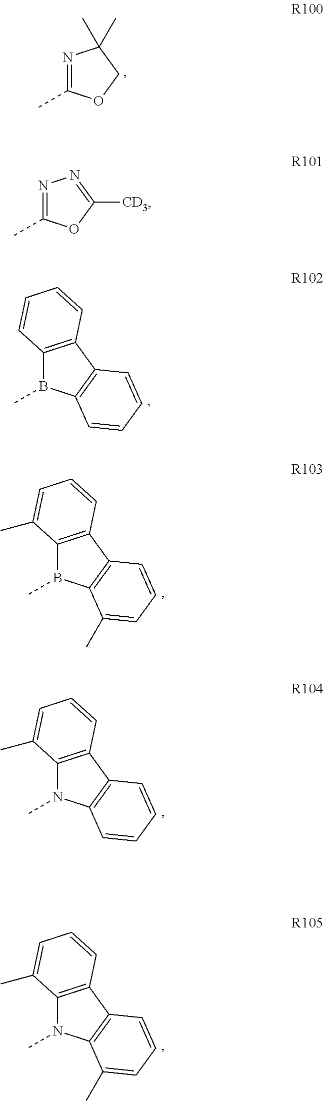

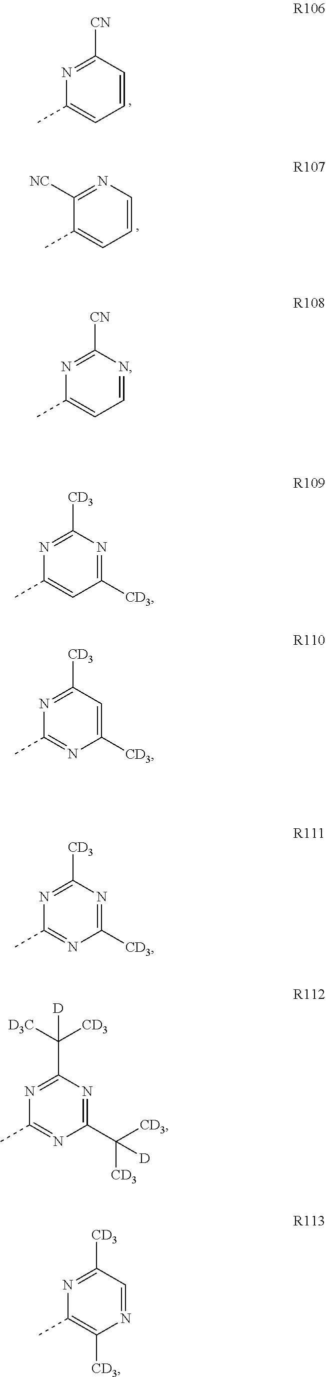

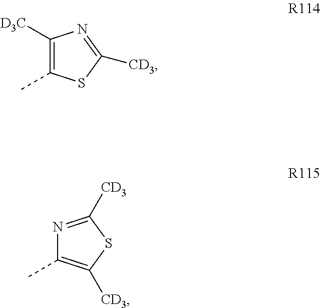

wherein T1 to T20 have the following structures:

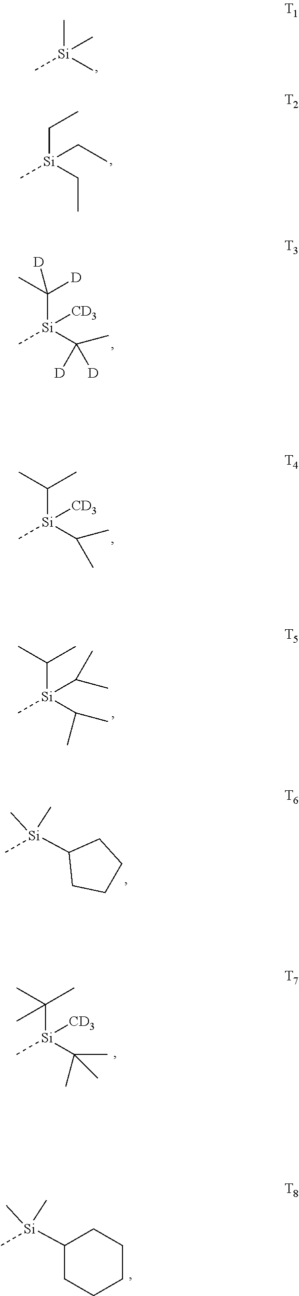

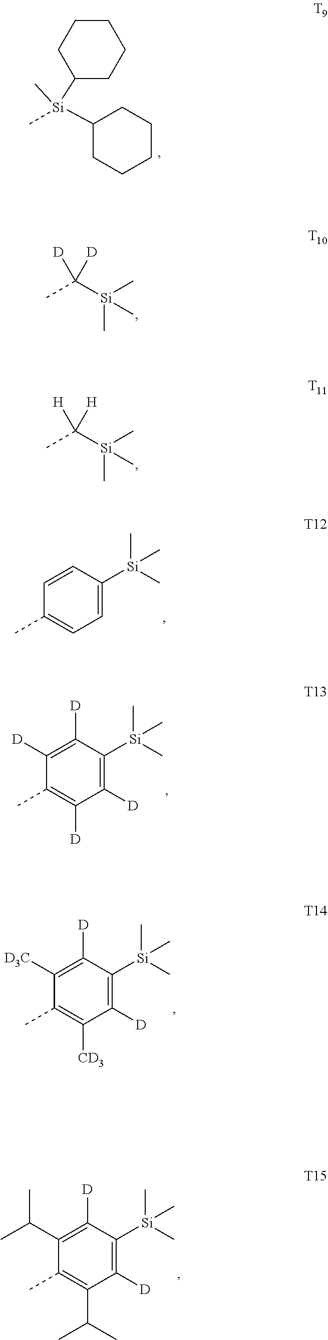

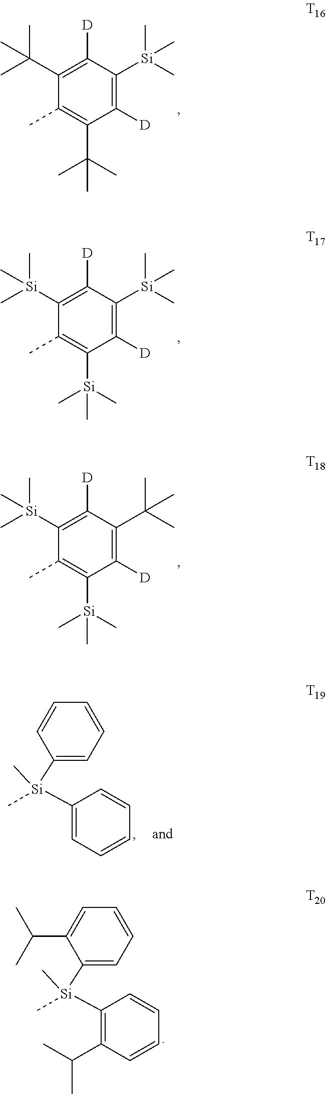

In some embodiments, the ligand L_{A} is selected from the group consisting of L_{Ai}, wherein i is an integer from 1 to 90, and each L_{Ai} is defined in the following LIST 3:

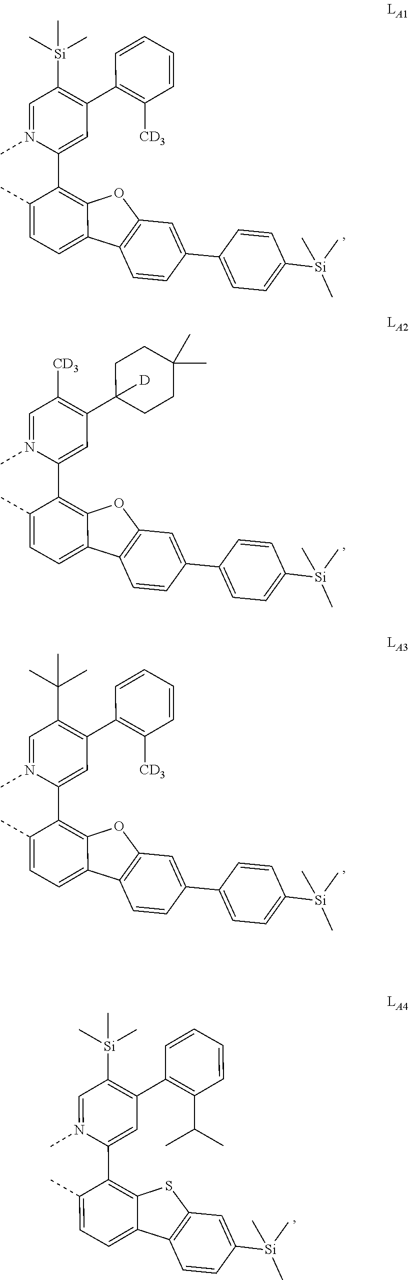

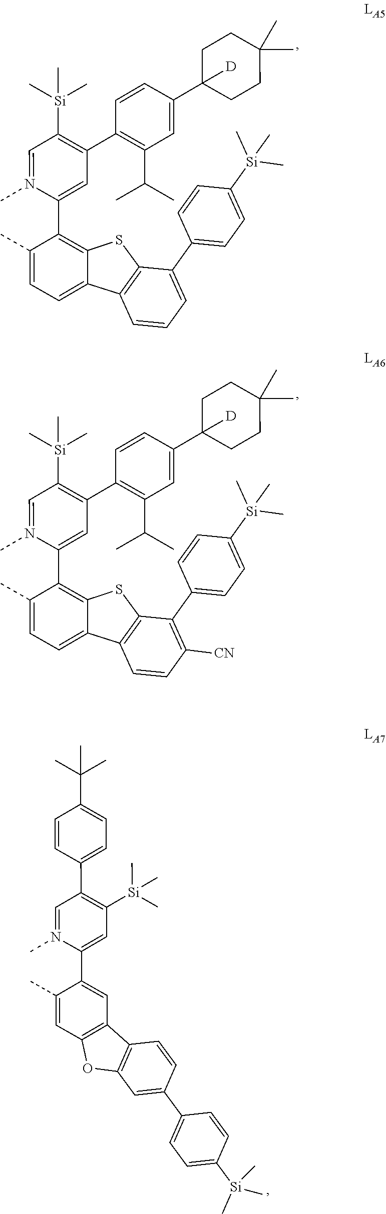

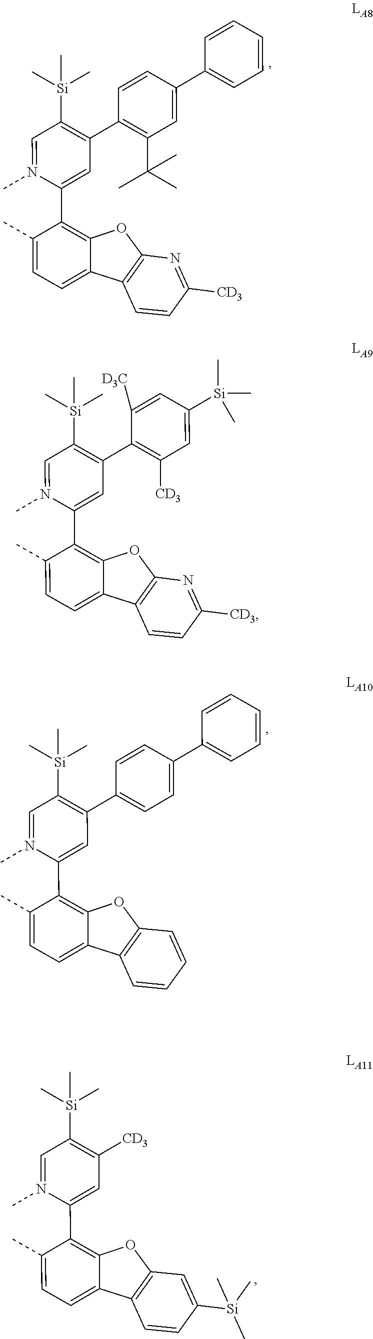

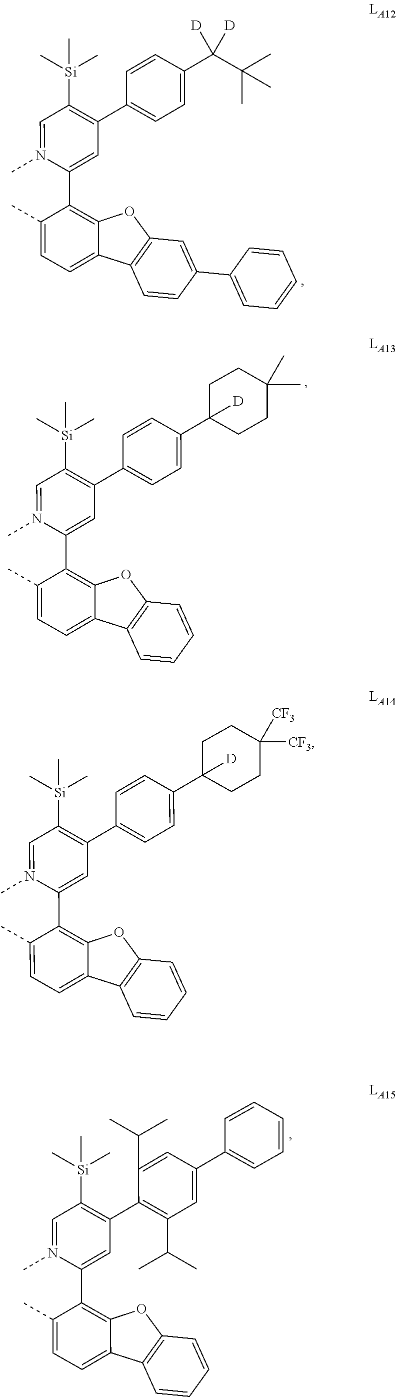

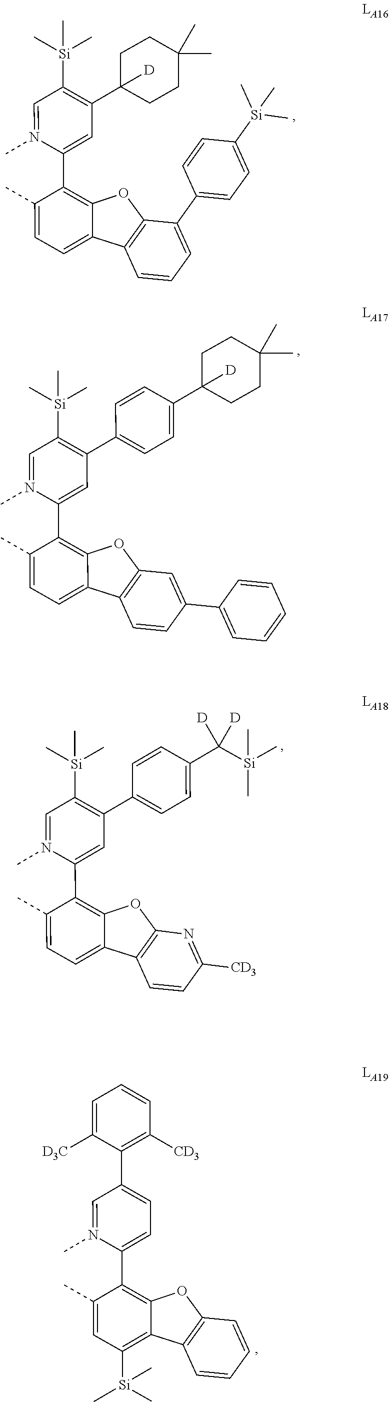

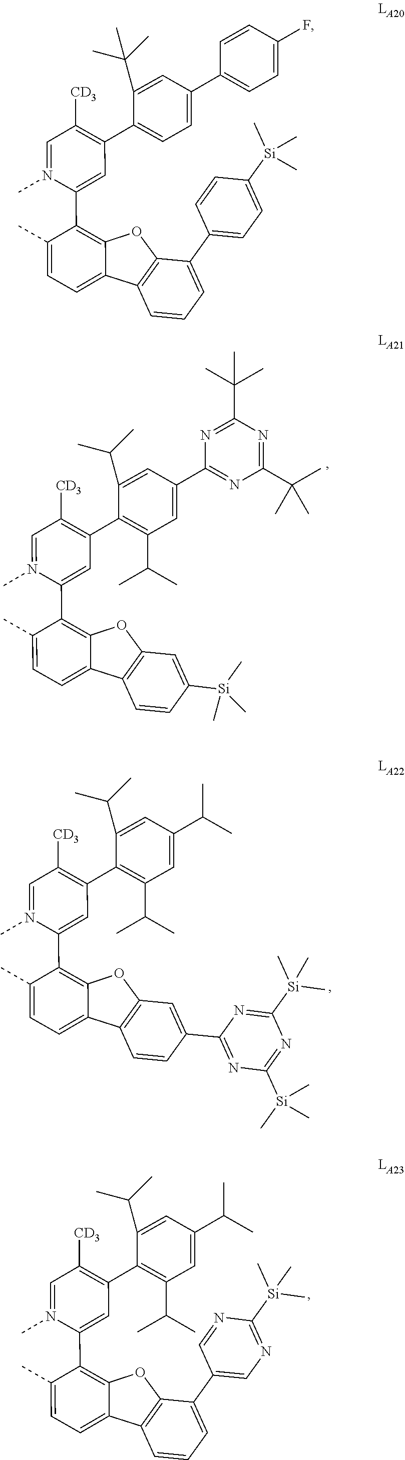

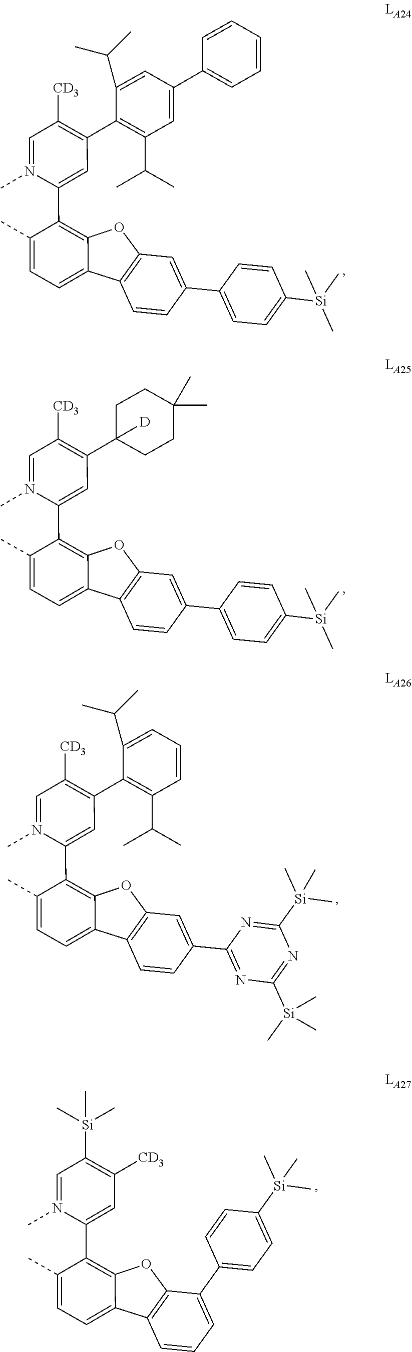

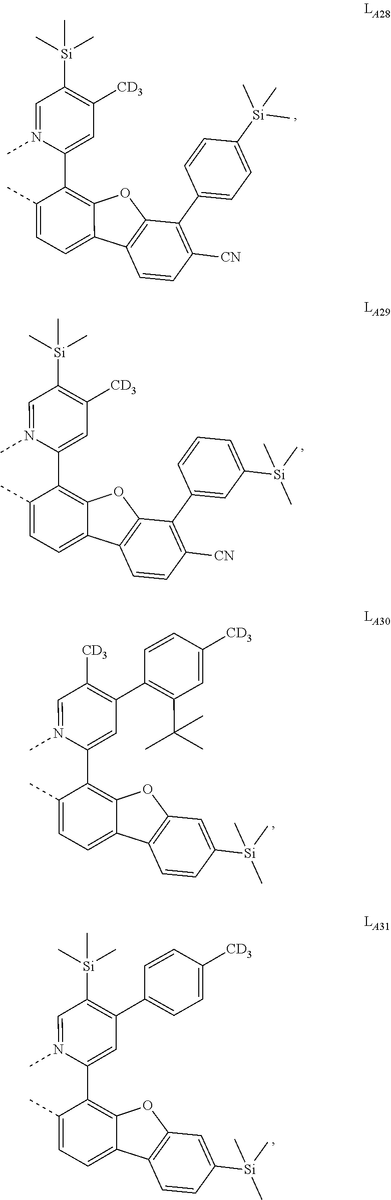

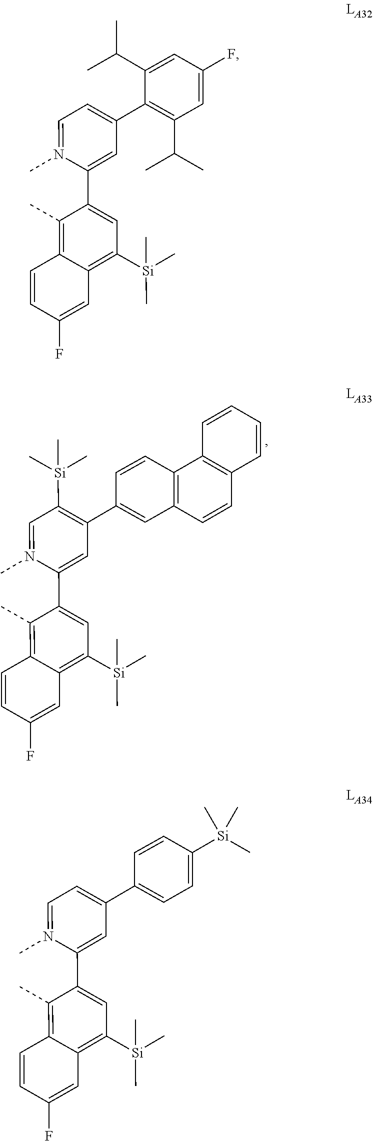

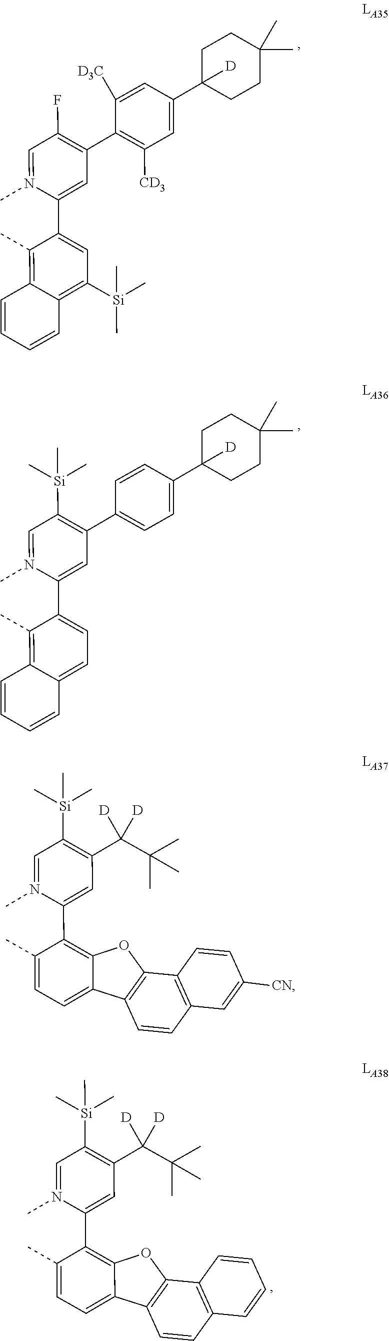

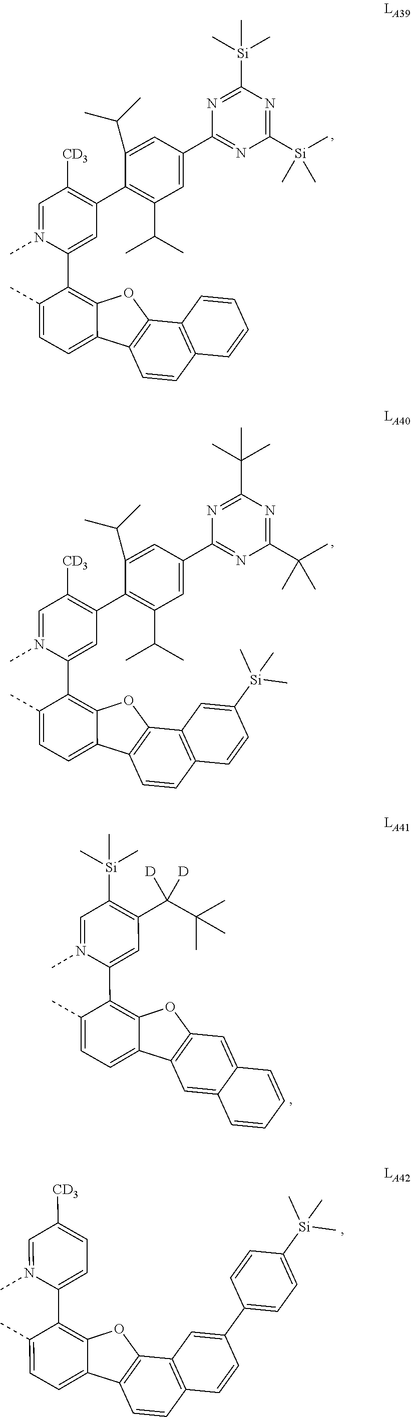

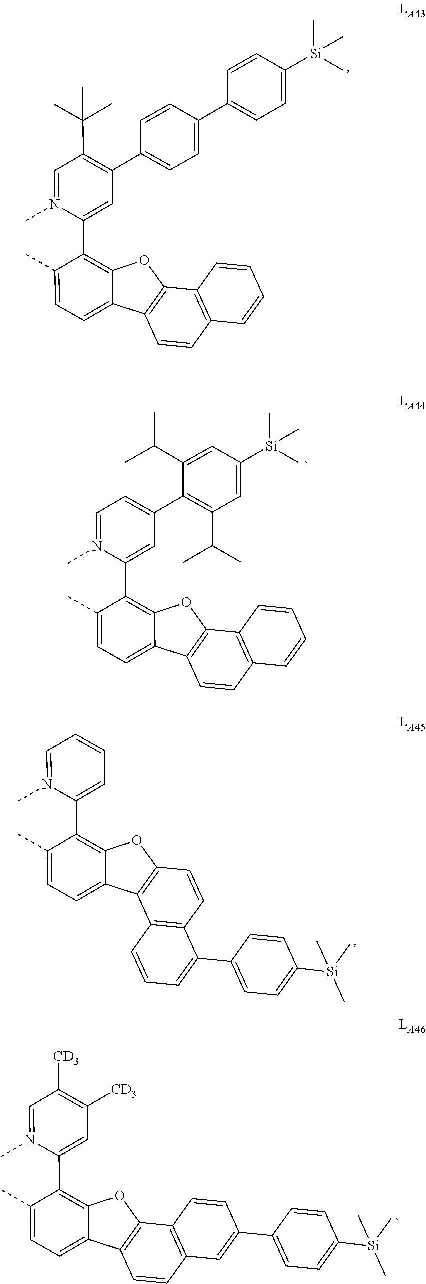

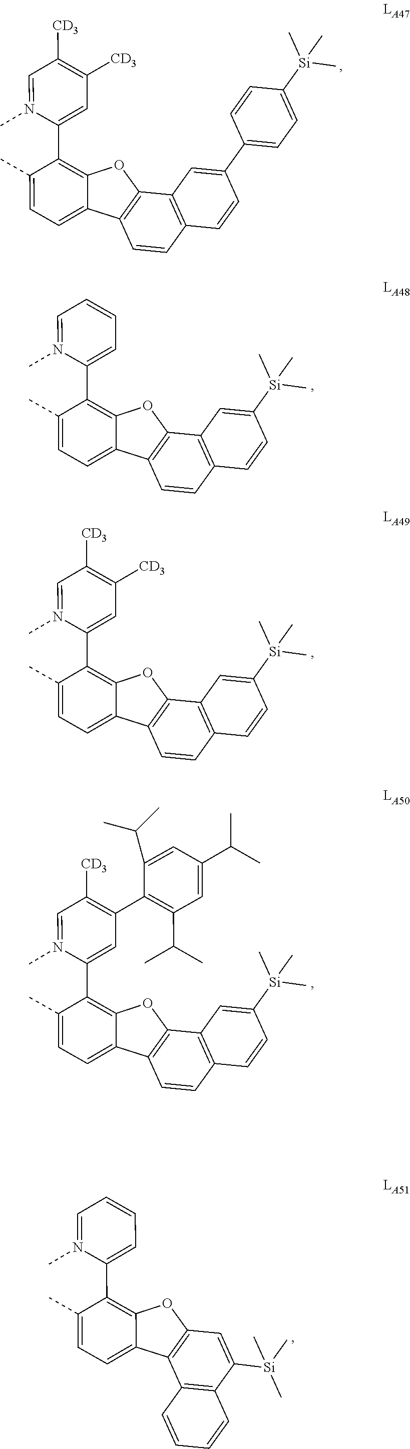

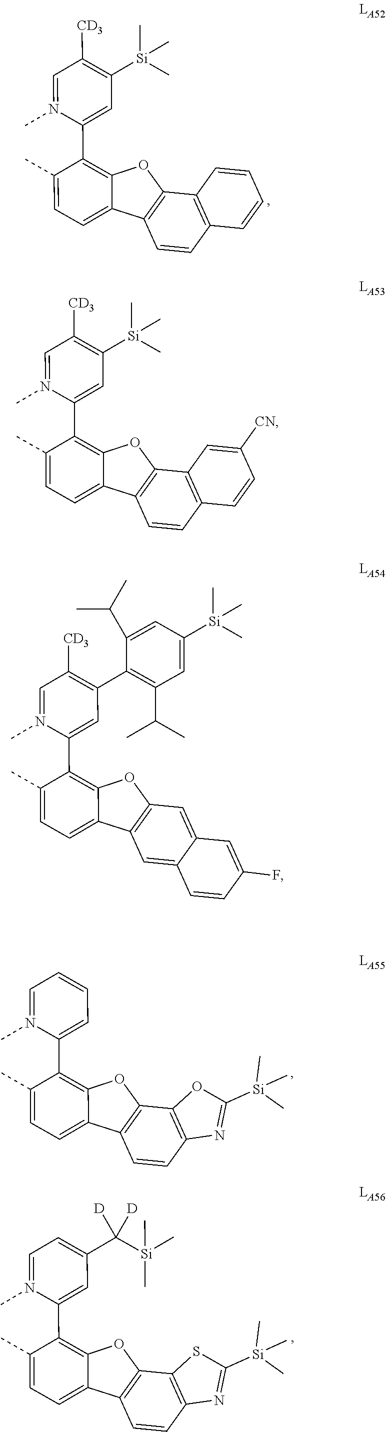

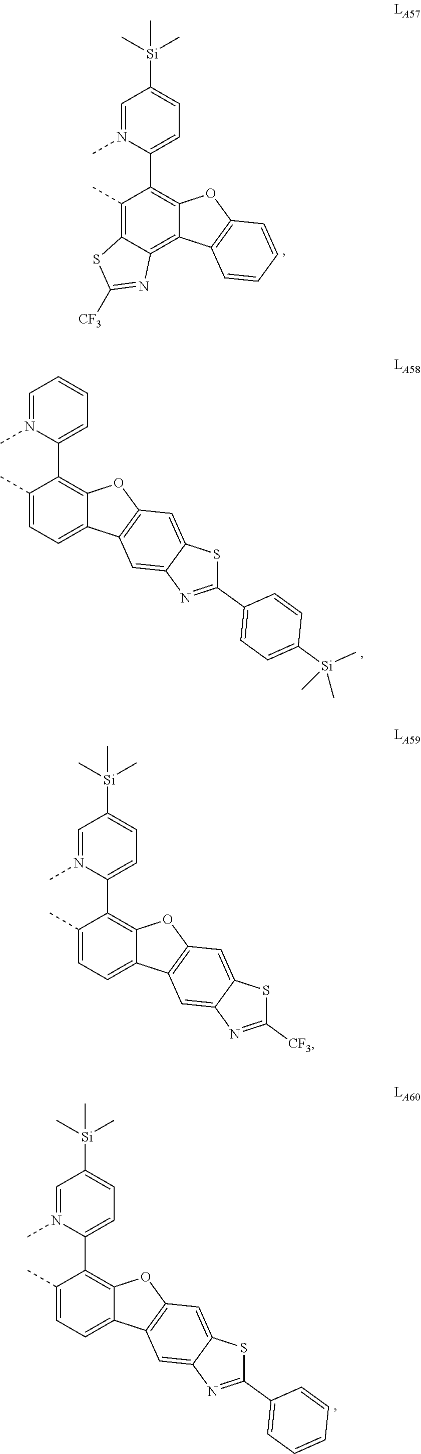

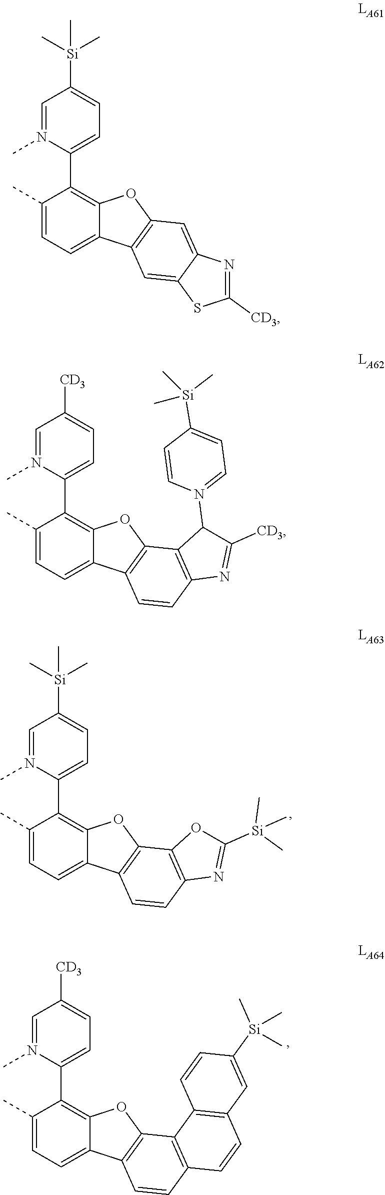

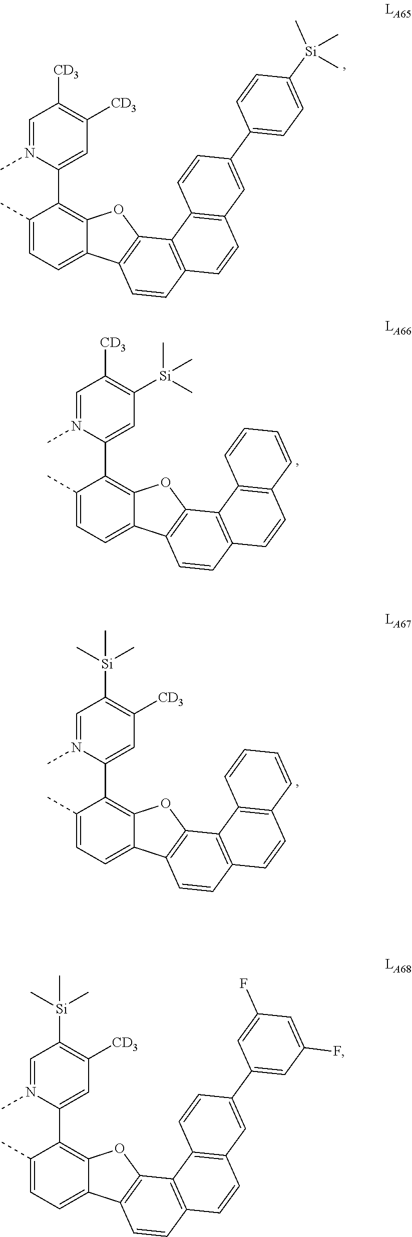

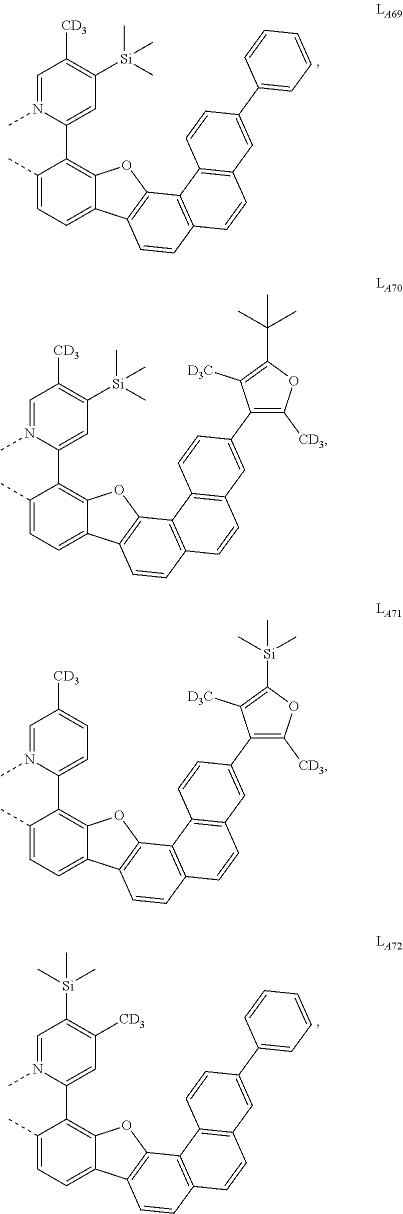

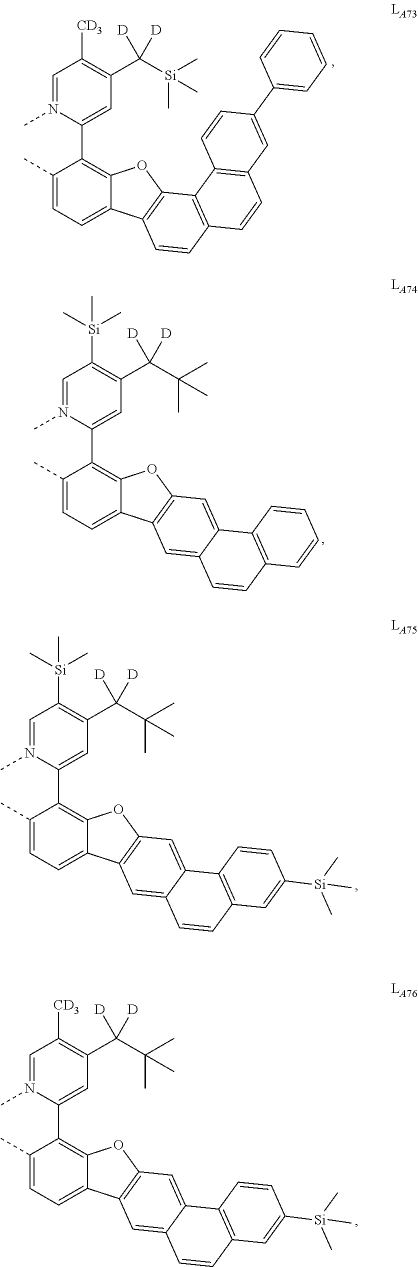

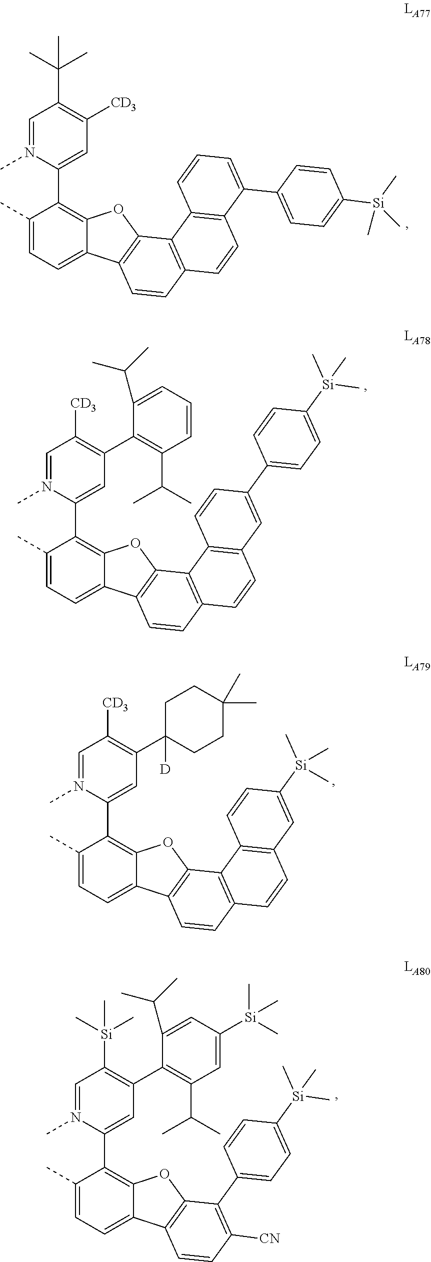

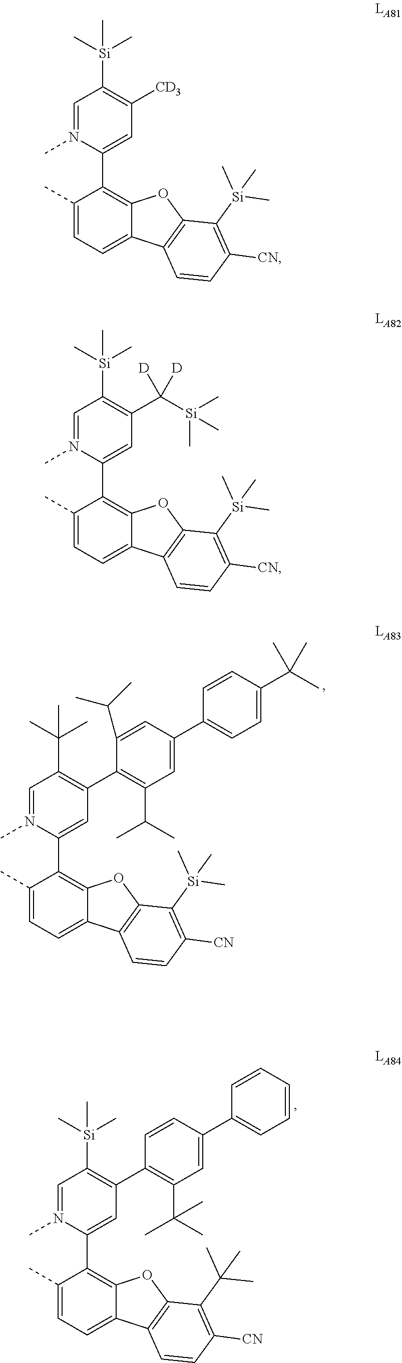

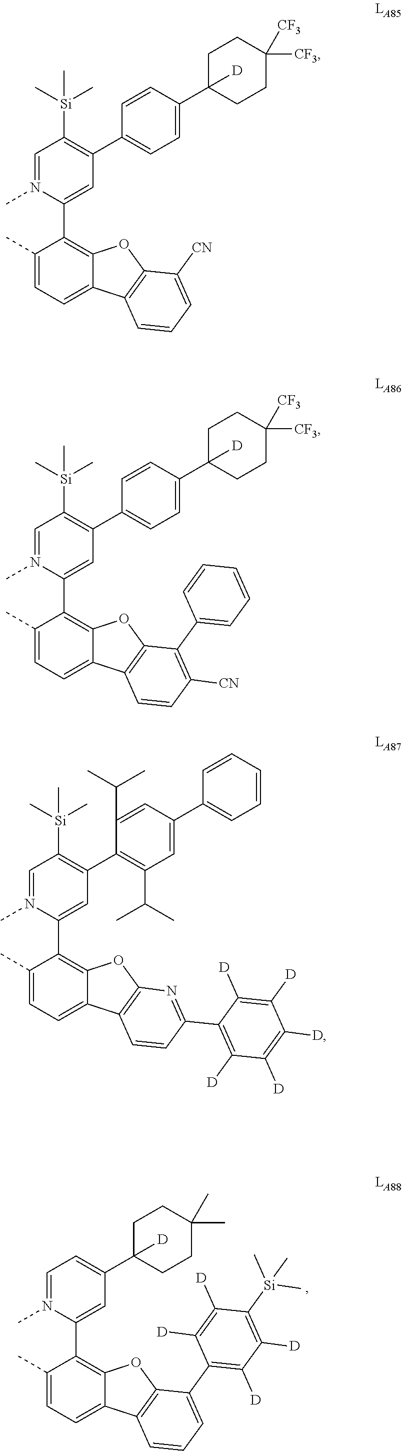

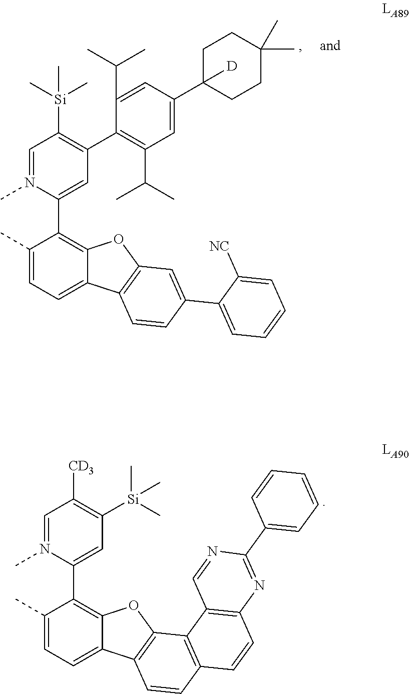

In some embodiments, the compound has a formula of M(L_{A})ₚ(L_{B}),(L_{C})ᵣ wherein L_{B} and L_{C} are each a bidentate ligand; and wherein p is 1, 2, or 3; q is 0, 1, or 2; r is 0, 1, or 2; and p+q+r is the oxidation state of the metal M.

In some embodiments, the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other.

In some embodiments, L_{B} is a substituted or unsubstituted phenylpyridine, and L_{C} is a substituted or unsubstituted acetylacetonate.

In some embodiments, the compound has a formula of Pt(L_{A})(L_{B}); and wherein L_{A} and L_{B} can be same or different. In some embodiments, L_{A} and L_{B} are connected to form a tetradentate ligand.

In some embodiments, L_{B} and L_{C} are each independently selected from the group consisting of the structures of the following LIST 4:

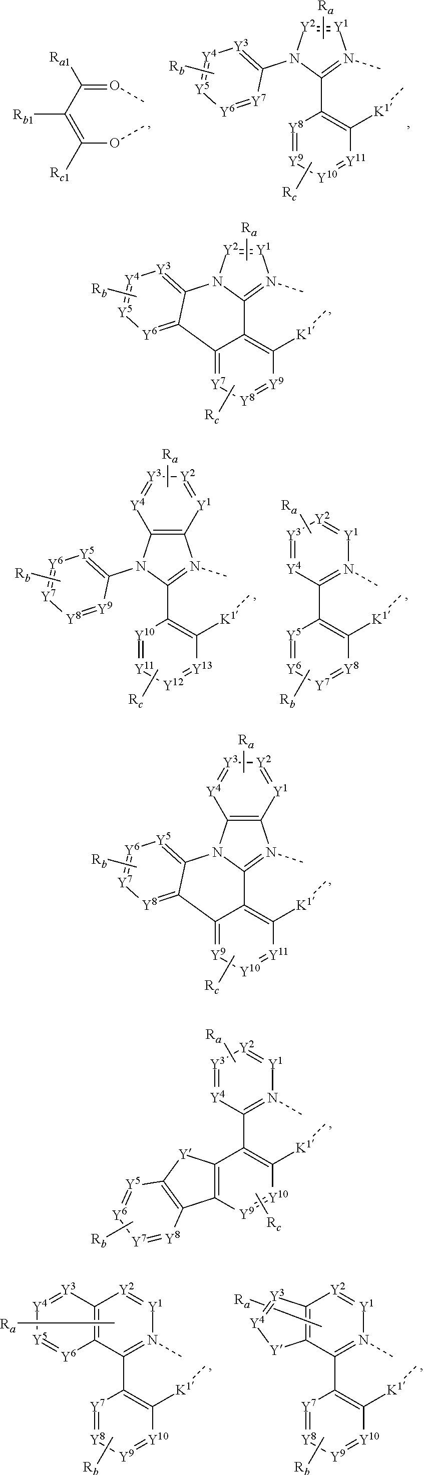

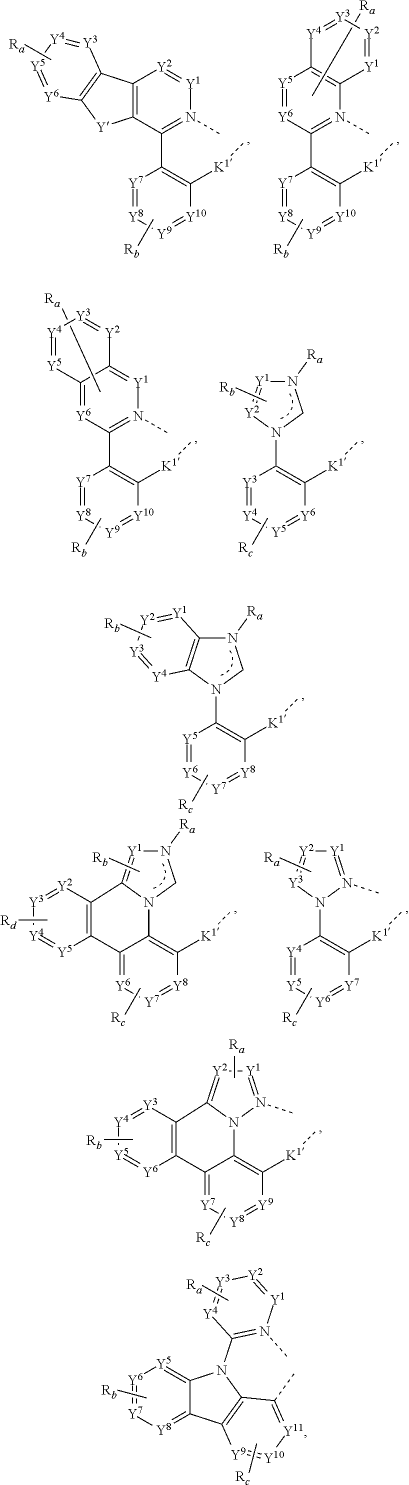

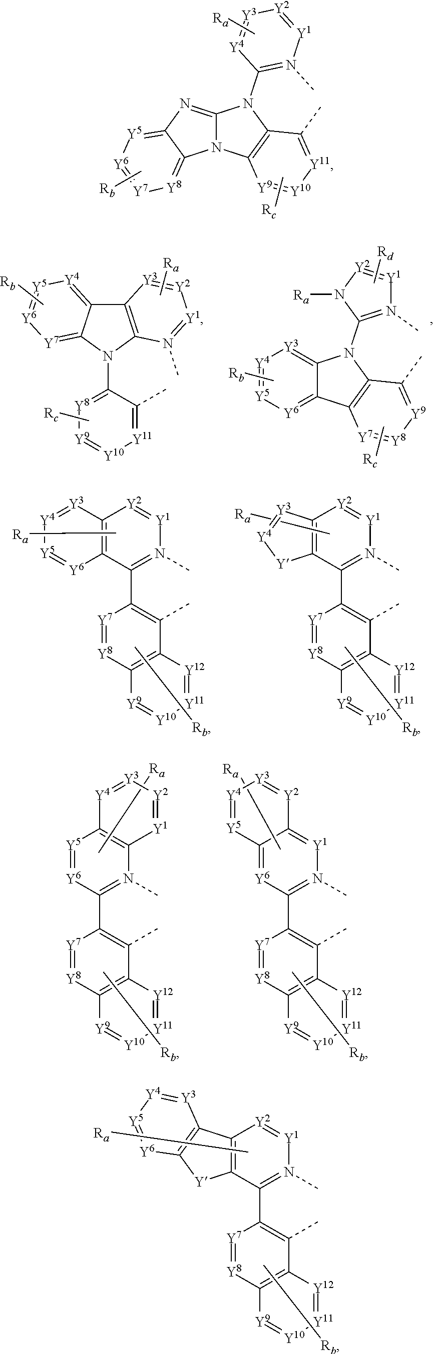

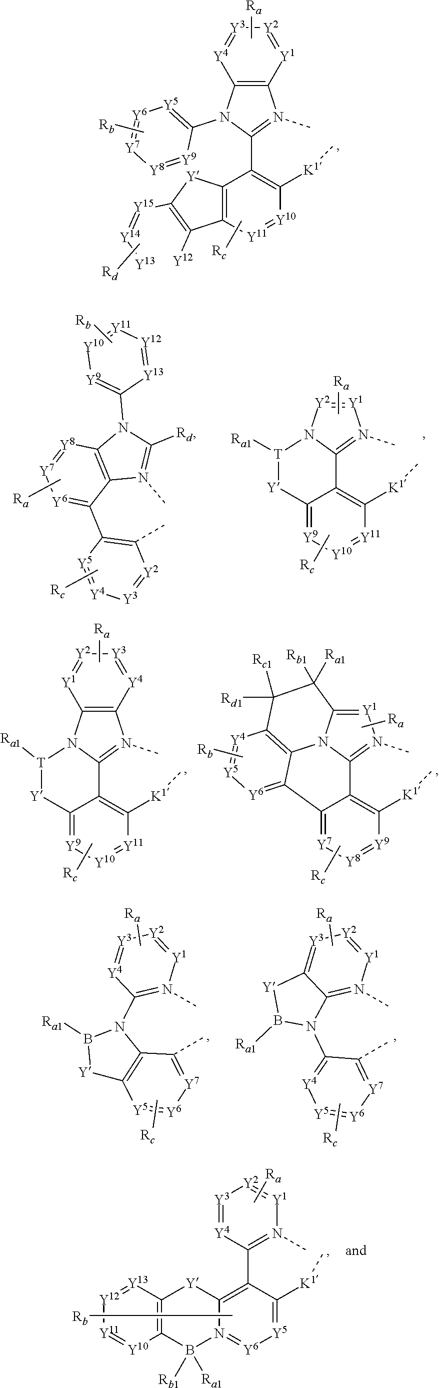

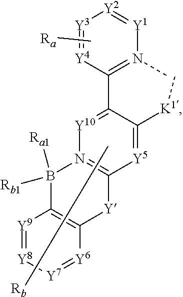

wherein:
T is selected from the group consisting of B, Al, Ga, and In;
K^{1′} is selected from the group consisting of a single bond, O, S, NRₑ, PRₑ, BRₑ, CRₑR_{f}, and SiRₑR_{f};
each of Y¹ to Y¹³ is independently selected from the group consisting of C and N;
Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, R_{d1}, Rₐ, R_{b}, R_{c}, R_{d}, Rₑ, and R_{f} is independently a hydrogen or a subsituent selected from the group consisting of the General Substituents defined herein; and
any two substituents of Rₐ₁, R_{b1}, R_{c1}, R_{d1}, Rₐ, R_{b}, R_{c}, and R_{d} can be fused or joined to form a ring or form a multidentate ligand.

In some embodiments, L_{B} and L_{C} are each independently selected from the group consisting of the structures of the following LIST 5:

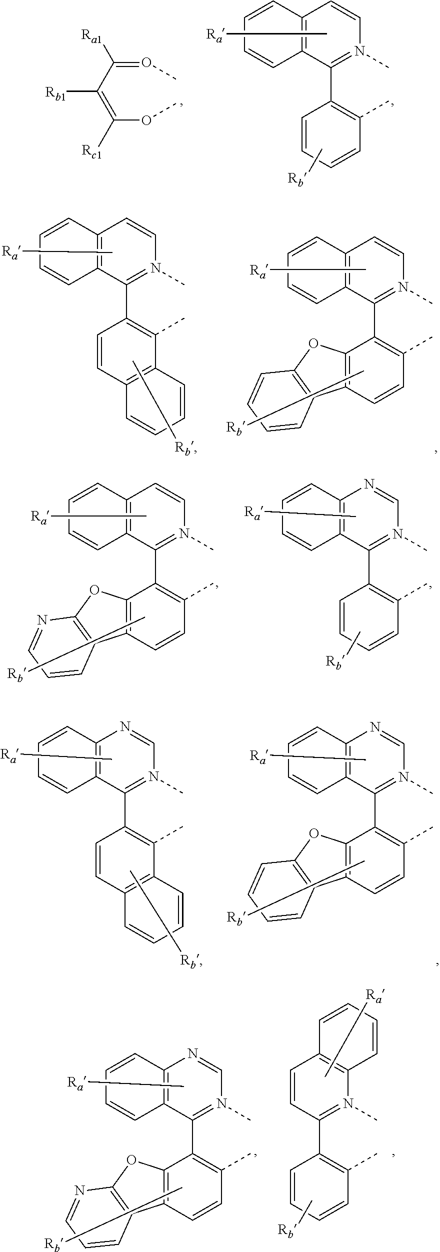

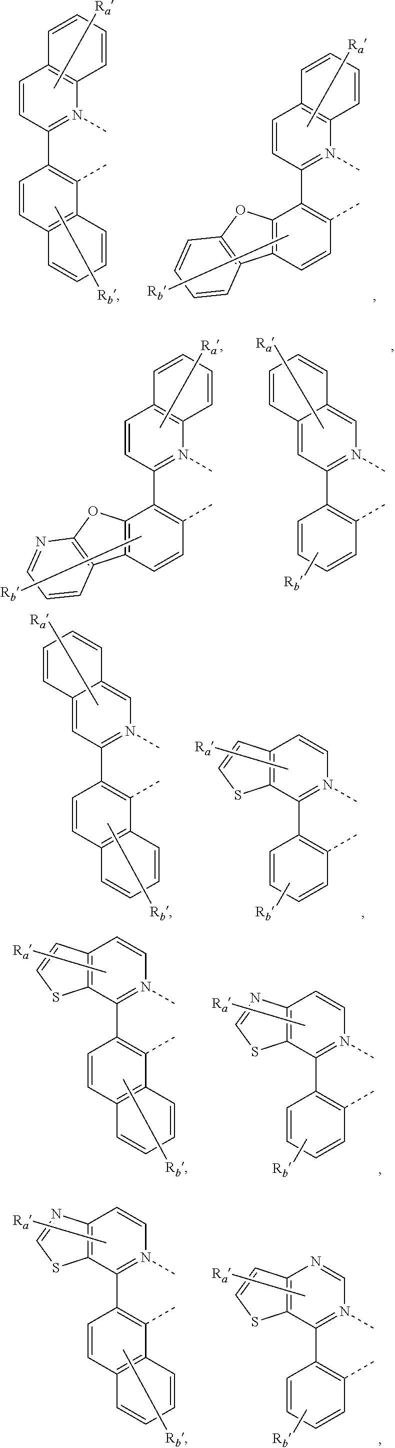

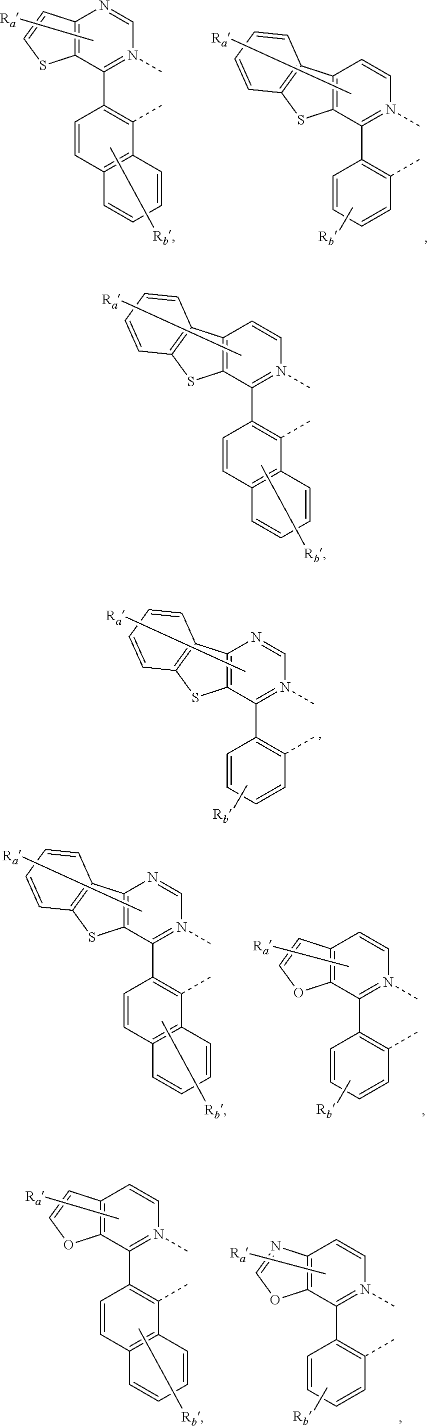

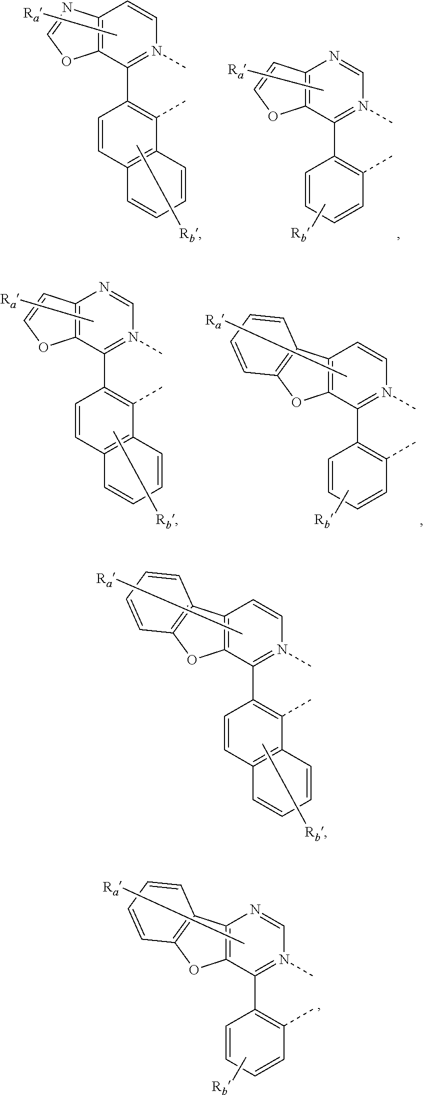

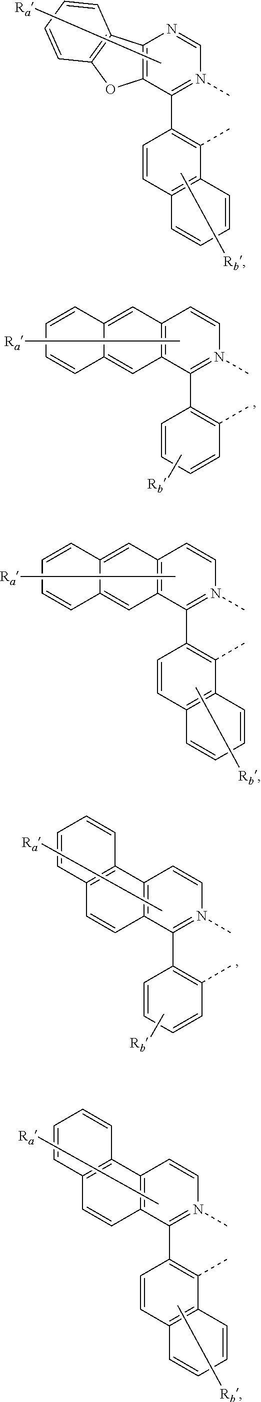

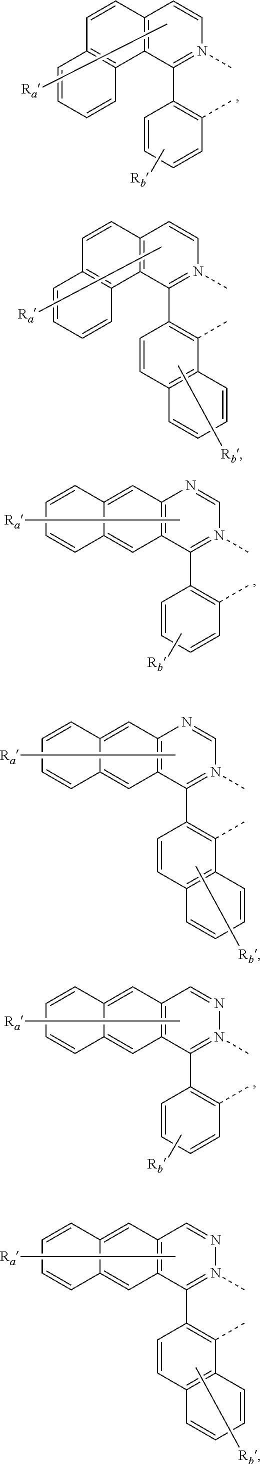

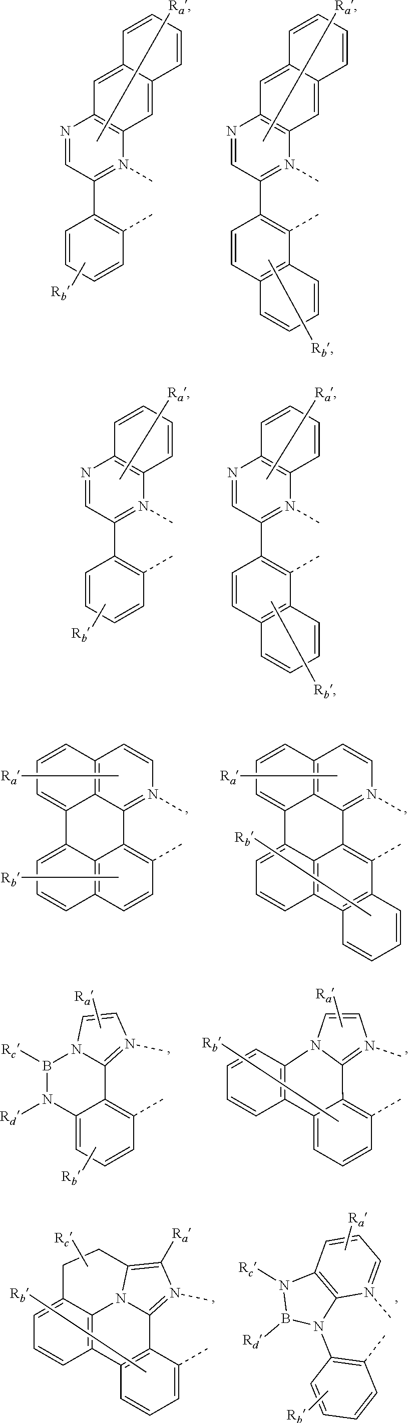

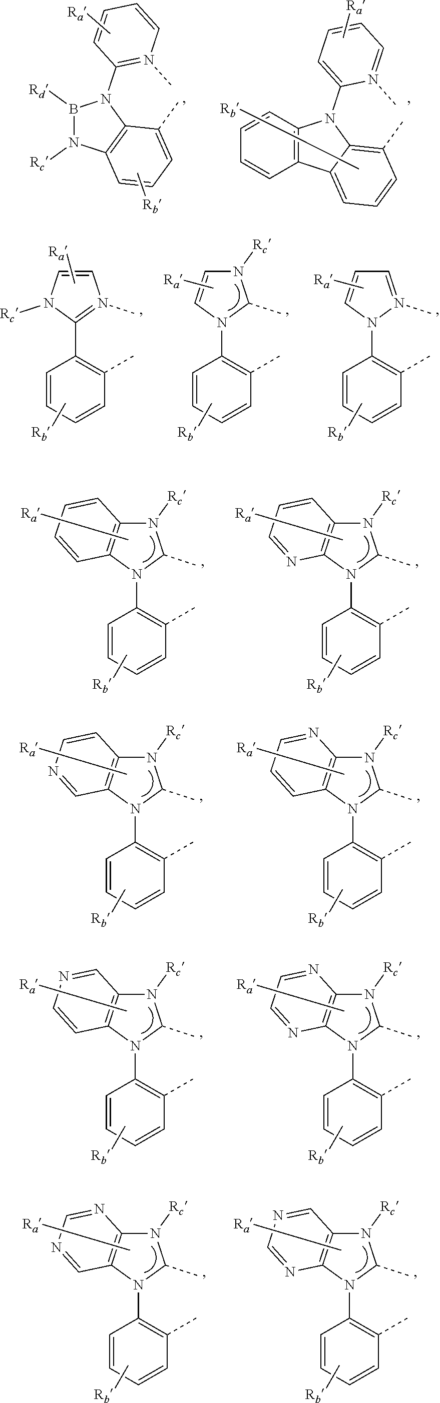

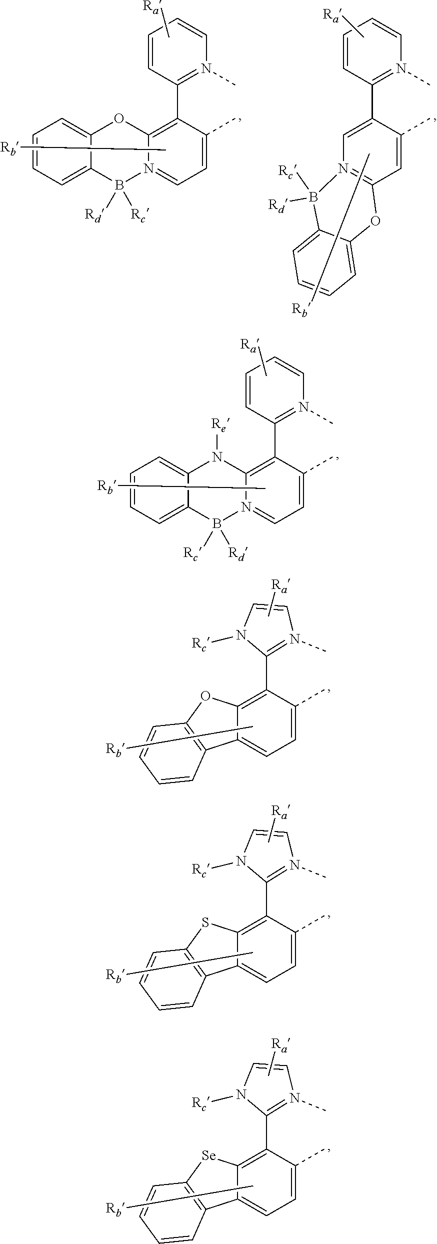

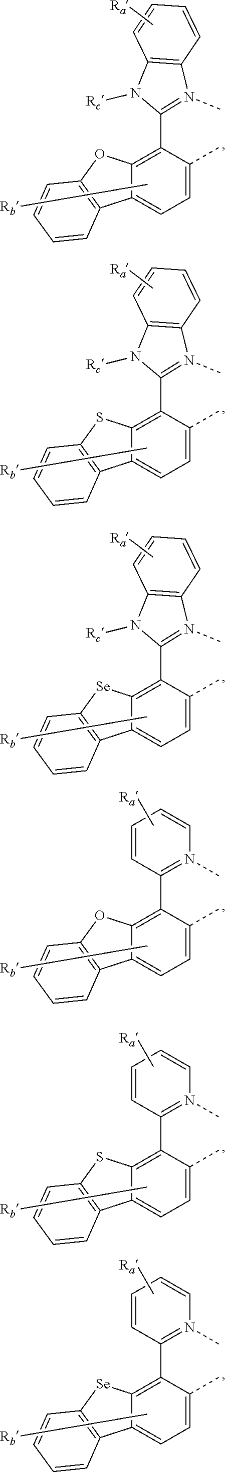

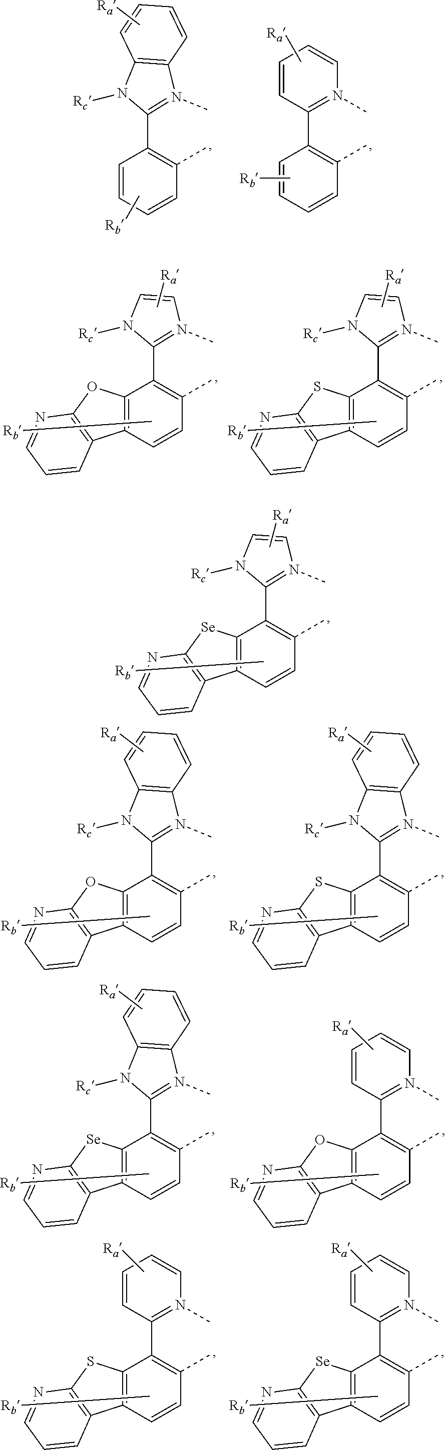

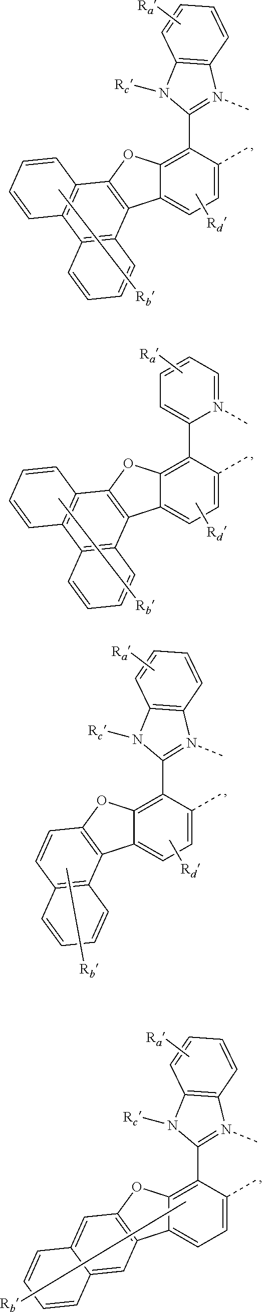

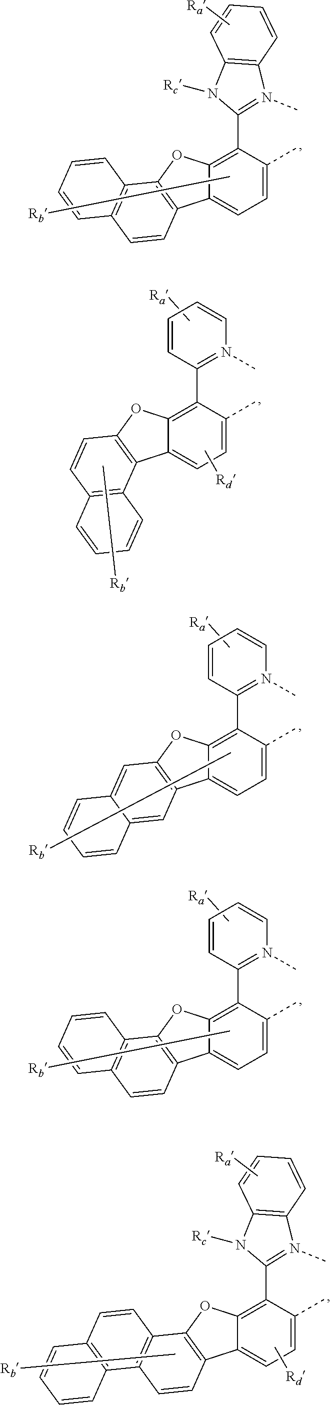

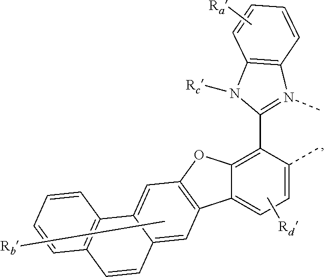

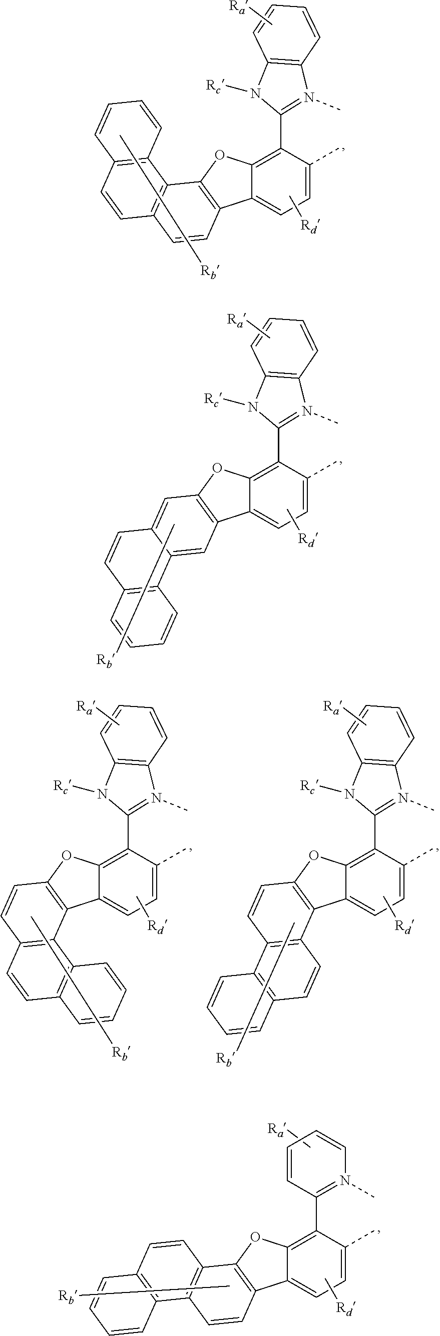

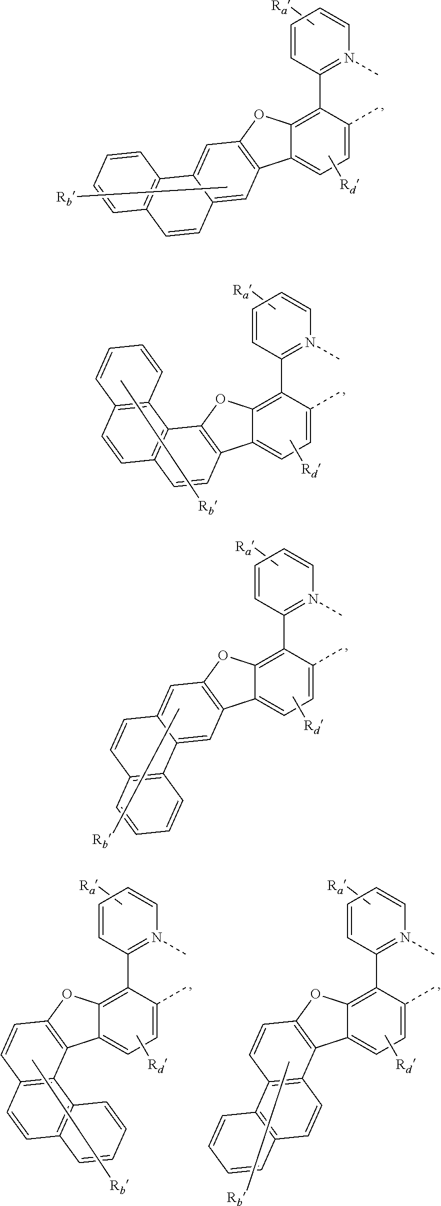

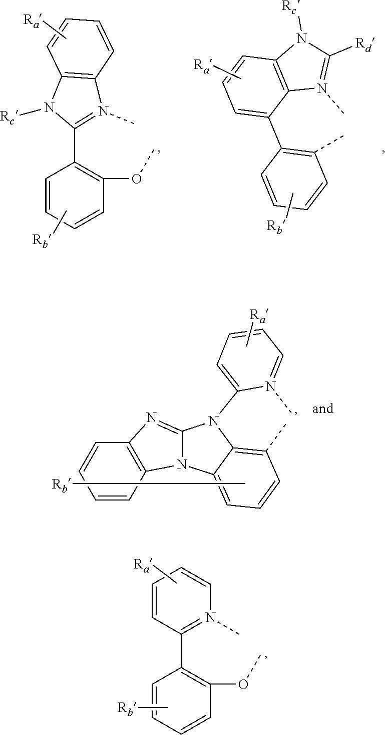

wherein:

Rₐ′, R_{b}′, R_{c}′, R_{d}′, and Rₑ′ each independently represents zero, mono, or up to a maximum allowed number of substitution to its associated ring;

Rₐ₁, R_{b1}, R_{c1}, Rₐ′, R_{b}′, R_{c}′, R_{d}′, and Rₑ′ each independently hydrogen or a substituent selected from the group consisting of the General Substituents defined berein; and

any two substituents of Rₐ₁, R_{b1}, R_{c1}, Rₐ′, R_{b}′, R_{c}′, R_{d}′, and R^{e}′ can be fused or joined to form a ring or form a multidentate ligand.

What is claimed is:

1. A compound comprising a first ligand L_{A} of Formula I, 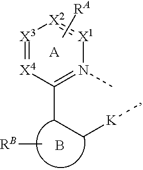
wherein:
moiety B is a fused polycyclic ring system, wherein each ring of the fused polycyclic ring system is a 5-membered or 6-membered carbocyclic or heterocyclic ring;
X¹ to X⁴ are each independently C or N;
K is selected from the group consisting of a direct bond, O, S, N(R^{α}), P(R^{═}), B(R^{α}), C(R^{α})(R^{β}), and Si(R^{α})(R^{β});
L_{A} is coordinated to a metal M;
M may be coordinated to other ligands;
L_{A} may be joined with other ligands to comprise a tridentate, tetradentate, pentadentate, or hexadentate ligand;
one of the following three conditions is true:
(1) at least one of R^{A} or R^{B} comprises a silyl group, and moiety B comprises four or more fused rings,
(2) at least one R^{A} has a structure of Formula II, 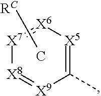
and at least one of R^{A} or R^{B} comprises a silyl group, wherein if the at least one of R^{A} that is Formula II is joined to X³ and K is a direct bond, then at least one R^{C} is not H, and
(3) at least one R^{B} comprises a silyl group and at least one R^{A} comprises a cyclic group or a silyl group;
wherein each of R^{A}, R^{B}, and R^{C} independently represents mono to the maximum allowable substitutions, or no substitutions;
each R^{A}, R^{B}, R^{C}, R^{α}, and R^{β} is independently hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two R^{A}, R^{B}, R^{C}, R^{α}, and R^{β} may be joined or fused to form a ring.

2. The compound of claim 1, wherein each R^{A}, R^{B}, R^{C}, R^{α}, and R^{β} is independently hydrogen or a substituent selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

3. The compound of claim 1, wherein moiety B comprises at least four fused rings; and/or wherein at least one R^{A} comprises a silyl group; and/or wherein at least one R^{B} comprises a silyl group.

4. The compound of claim 1, wherein moiety B is selected from the group consisting of naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, benzimidazole derived carbene, aza-benzimidazole derived carbene, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-antracene, phenanthridine, fluorene, and aza-fluorene.

5. The compound of claim 1, wherein each of X¹ to X⁴ is C or wherein at least one of X¹ to X⁴ is N; and/or wherein K is a direct bond, O or S; and/or wherein the metal M is selected from the group consisting of Ir, Rh, Re, Ru, Os, Pt, Pd, Ag, Au, and Cu; and/or wherein at least one R^{A} comprises a cyclic group or a silyl group; and/or wherein at least one R^{B} comprises a silyl group; and/or wherein L_{A} is partially deuterated.

6. The compound of claim 1, two adjacent ones of X¹ to X⁴ are C and the adjacent R^{A} are joined or fused to form a ring; and/or wherein at least one additional R^{A} comprises a moiety selected from the group consisting of alkyl, cycloalkyl, aryl, heteroaryl, partially or fully deuterated variants thereof, F, and silyl.

7. The compound of claim 1, wherein at least one R^{A} has a structure of Formula II, 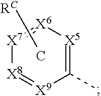
and/or wherein the R^{A} bonded to X³ has a structure of Formula II, K is a direct bond, and at least one R^{C} is not H.

8. The compound of claim 7, wherein the R^{C} bonded to at least one of X⁵ or X⁹ is independently selected from the group consisting of alkyl, cycloalkyl, aryl, heteroaryl, and combinations thereof; and/or wherein the R^{C} bonded to X⁷ is independently selected from the group consisting of alkyl, cycloalkyl, aryl, heteroaryl, and combinations thereof; and/or wherein two adjacent ones of X⁵ to X⁹ are C and the adjacent R^{C} are joined or fused to form a ring.

9. The compound of claim 1, wherein the ligand L_{A} is selected from the group consisting of: 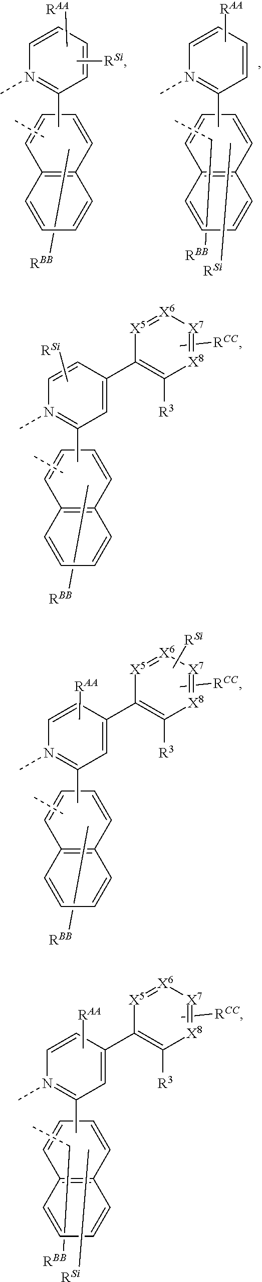 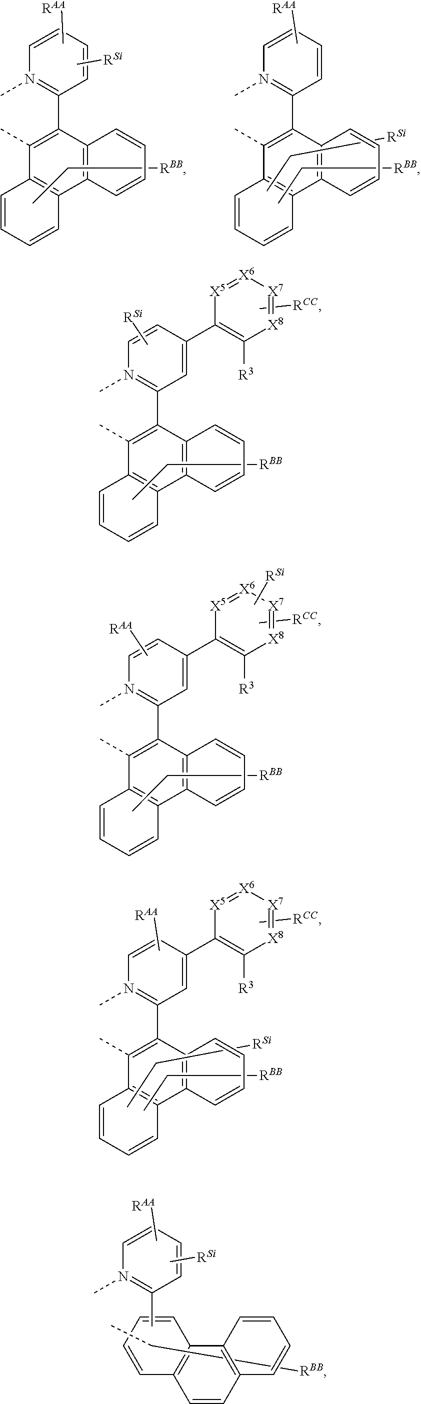 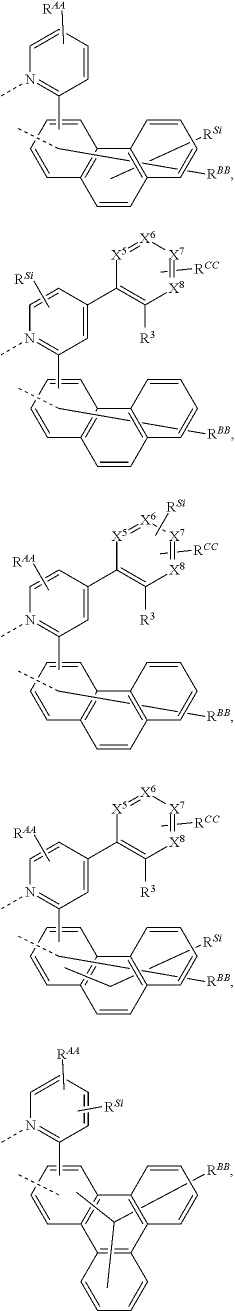 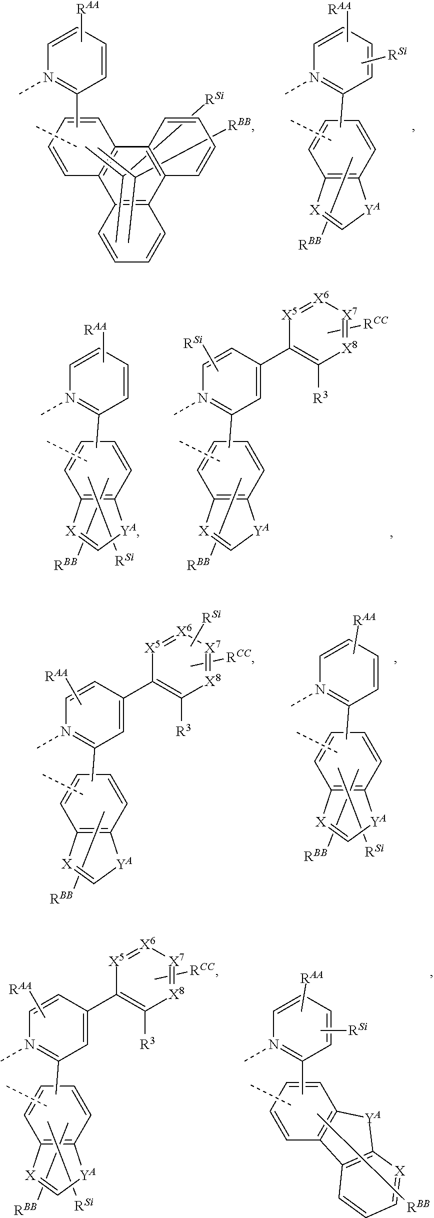 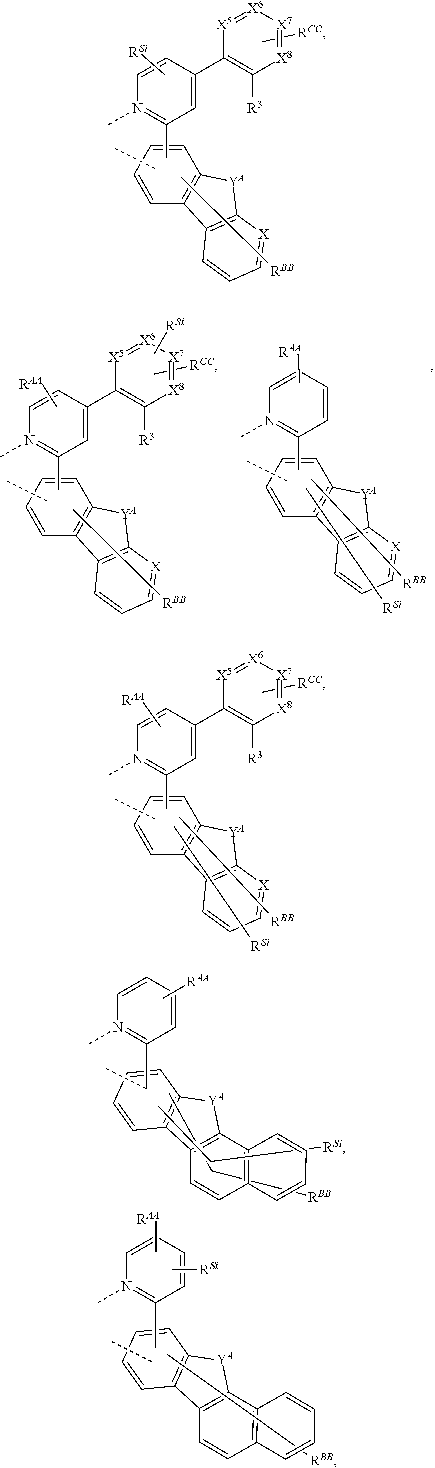 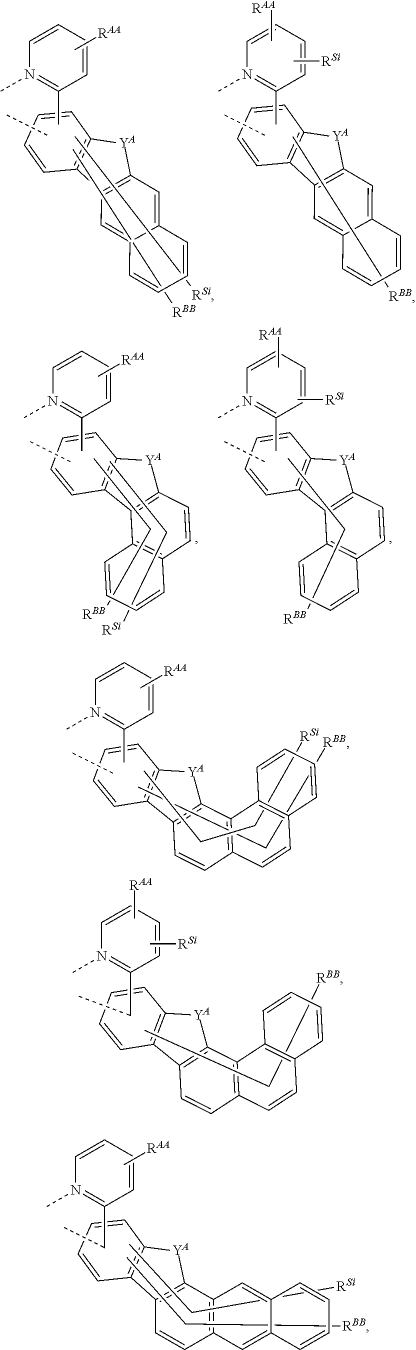 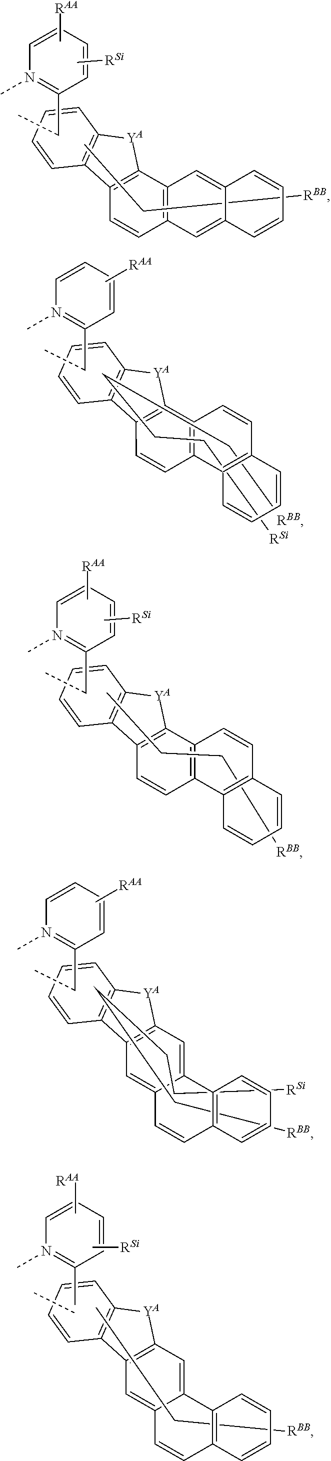 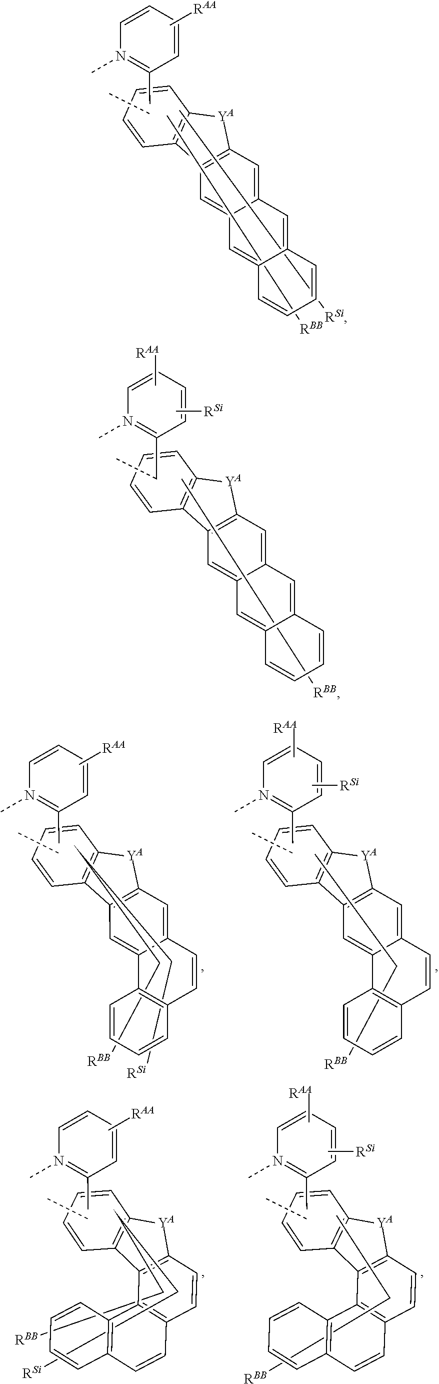 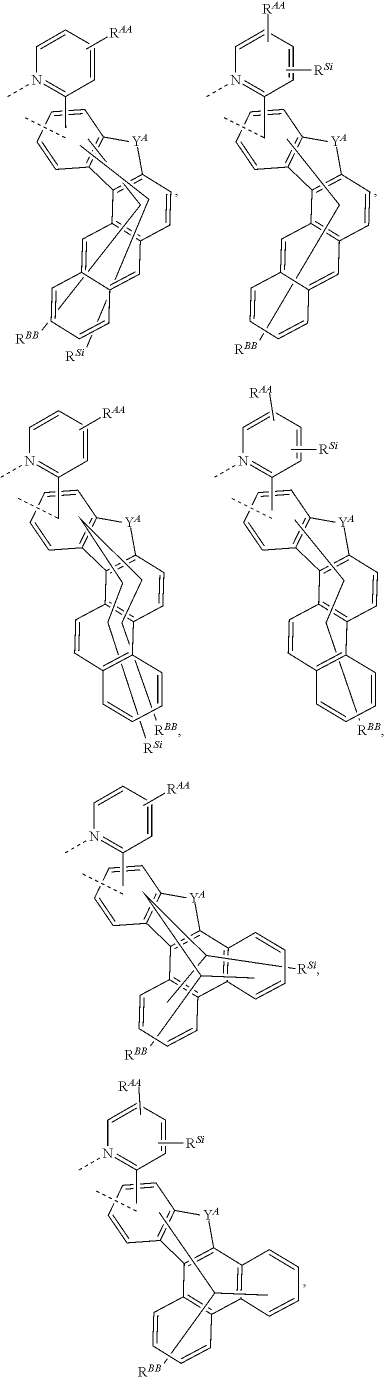 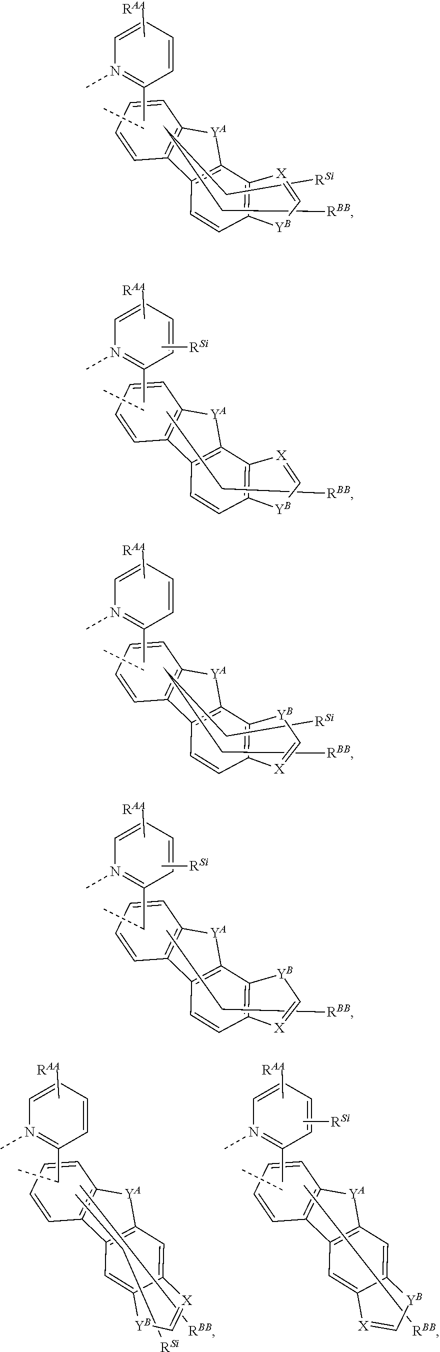 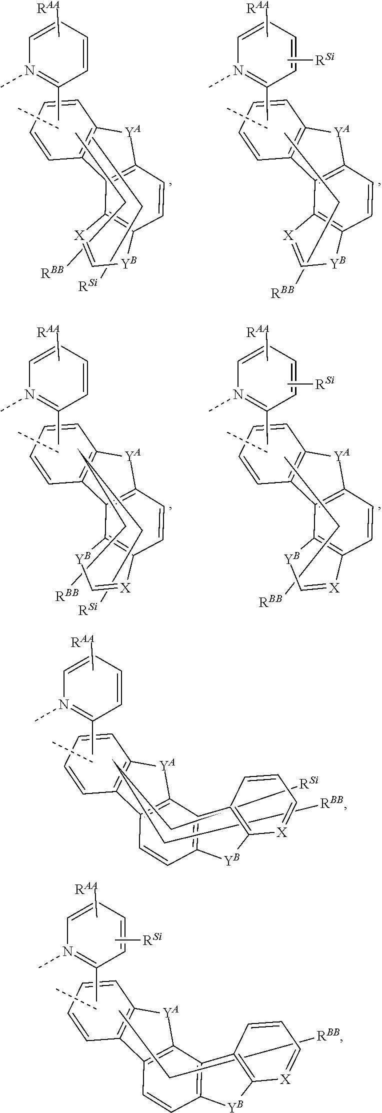 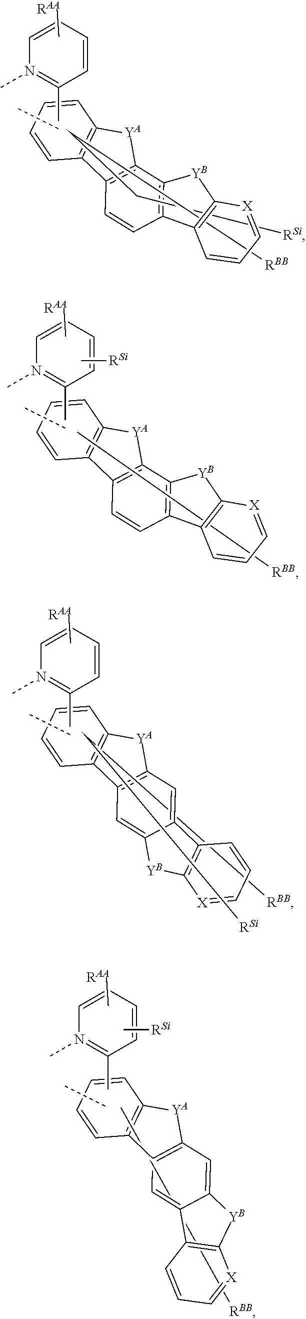 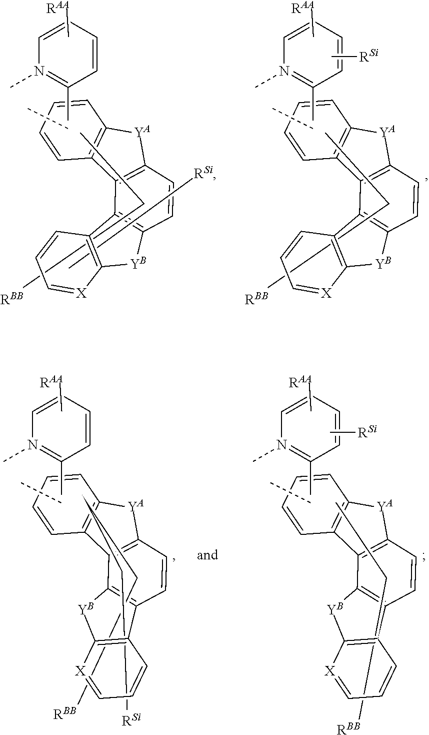
wherein:
X is Cor N;
each of Y^{A} and Y^{B} is independently selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SIRₑR_{f}, and GeRₑR_{f};
each of R^{AA}, R^{BB}, and R^{CC}; independently represents mono to the maximum allowable substitutions, or no substitutions;
each Rₑ, R_{f}, R^{AA}, R^{BB}, R^{CC} and R^{Si} is independently hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
R³ is a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
with the proviso that R^{Si} comprises a silyl moiety; and
any two R^{A}, R^{B}, R^{C}, R^{α}, and R^{β} may be joined or fused to form a ring.

10. The compound of claim 1, wherein the ligand L_{A} is selected from the group consisting of: 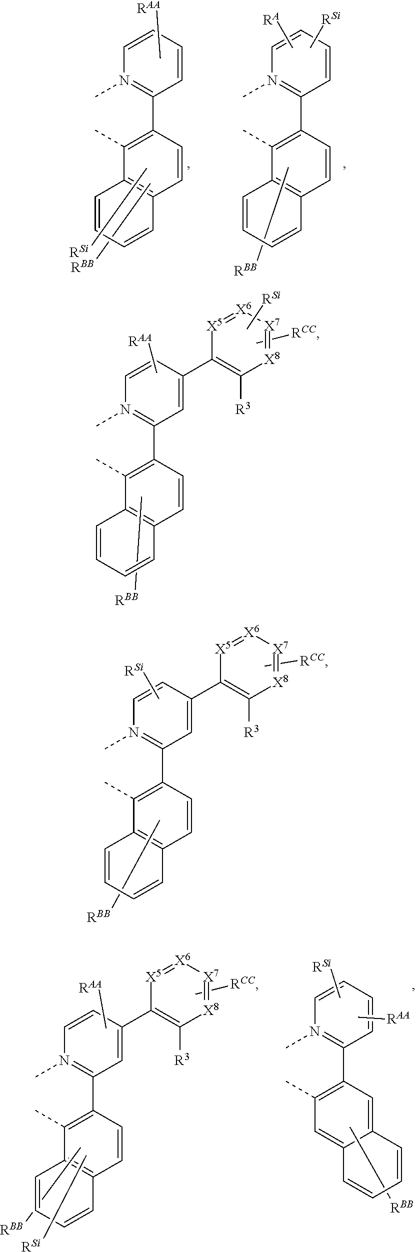 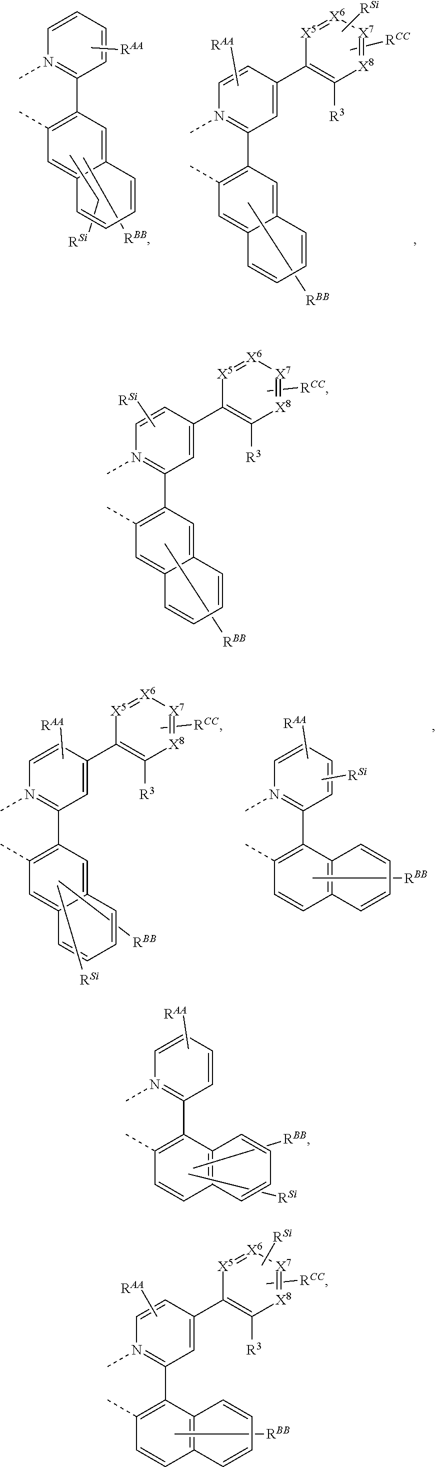 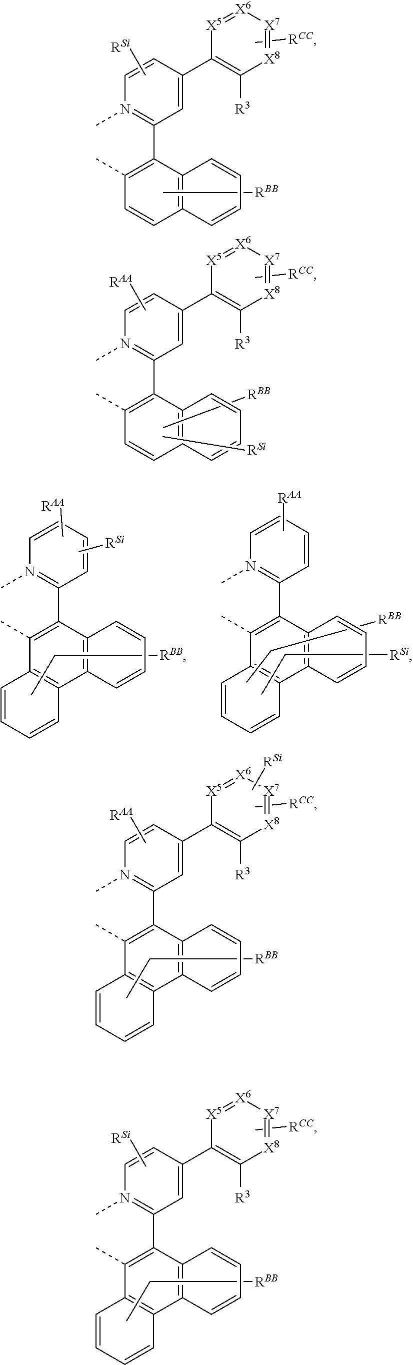 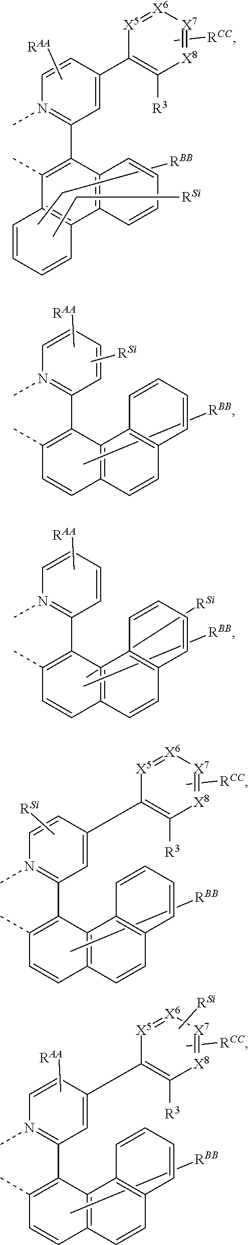 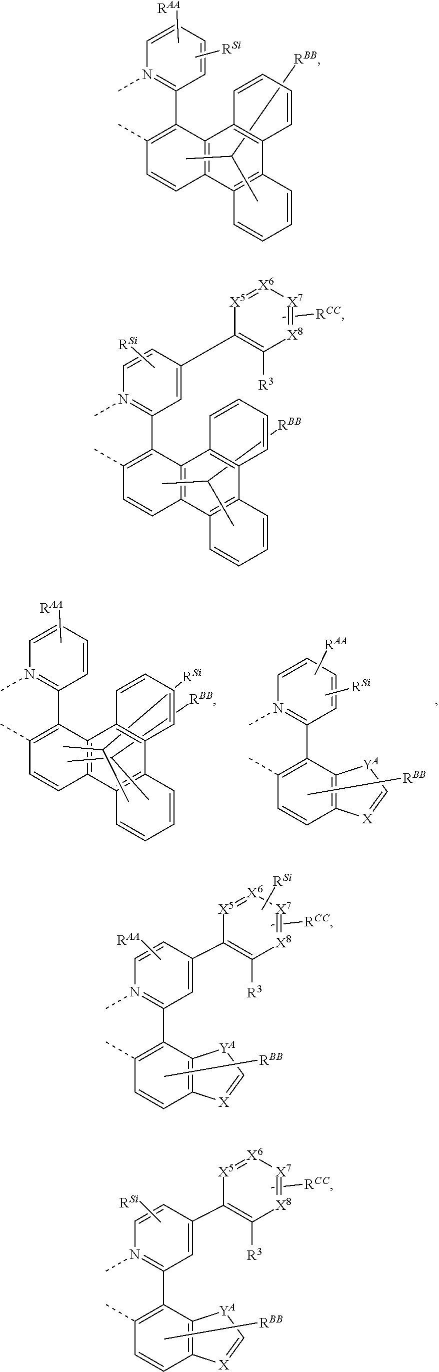 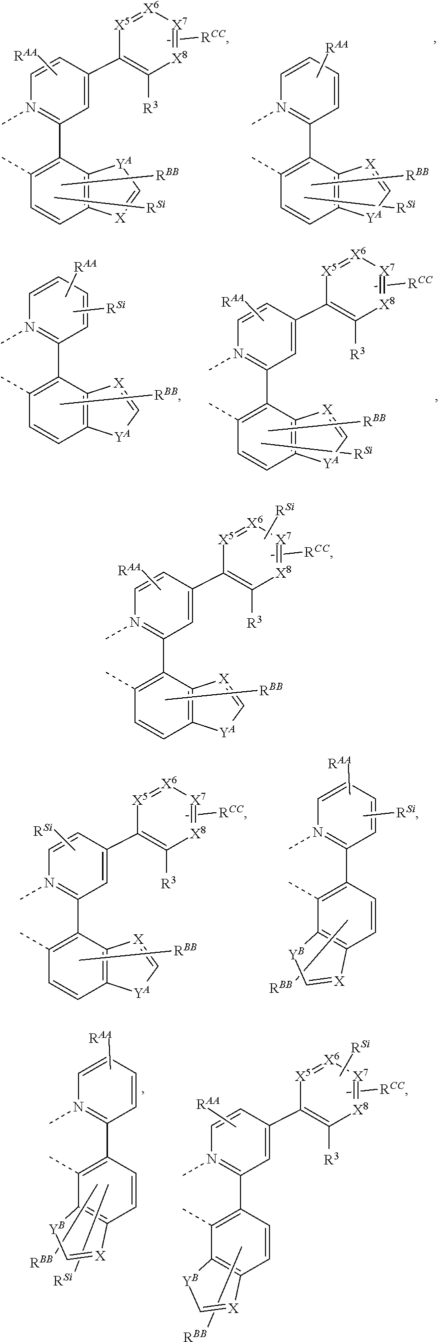 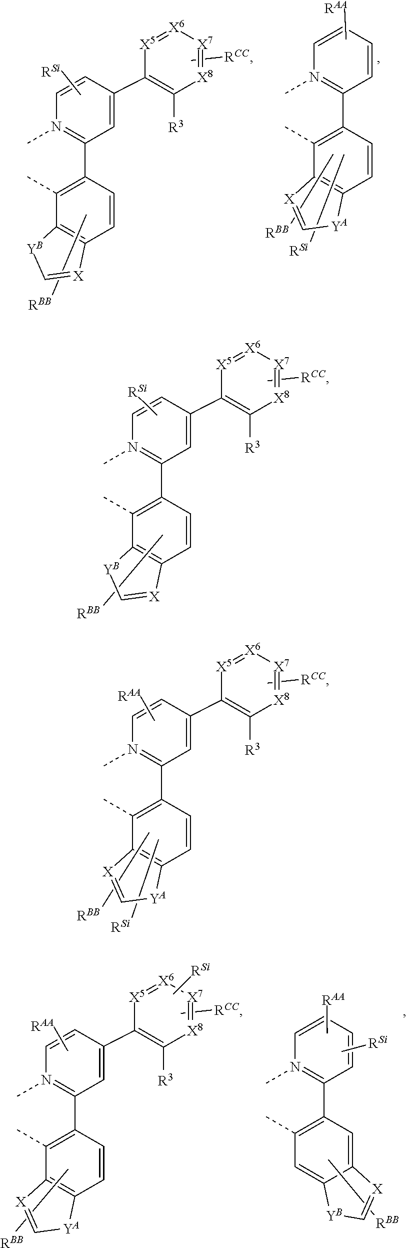 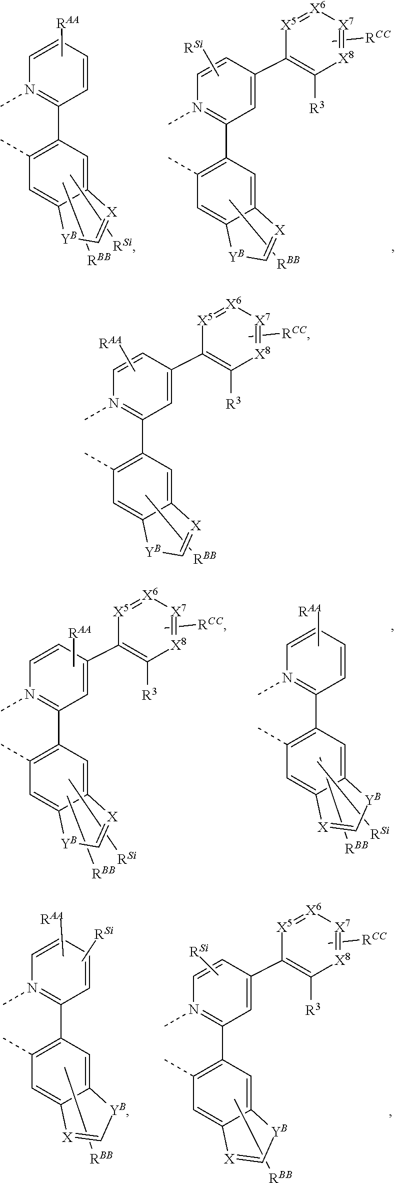 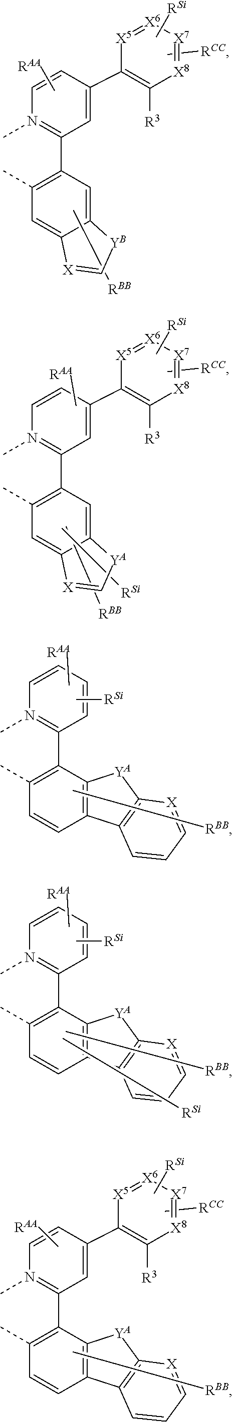 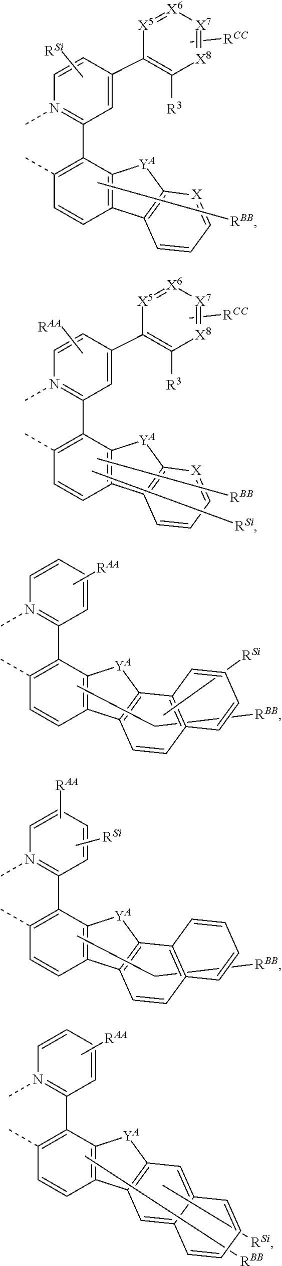 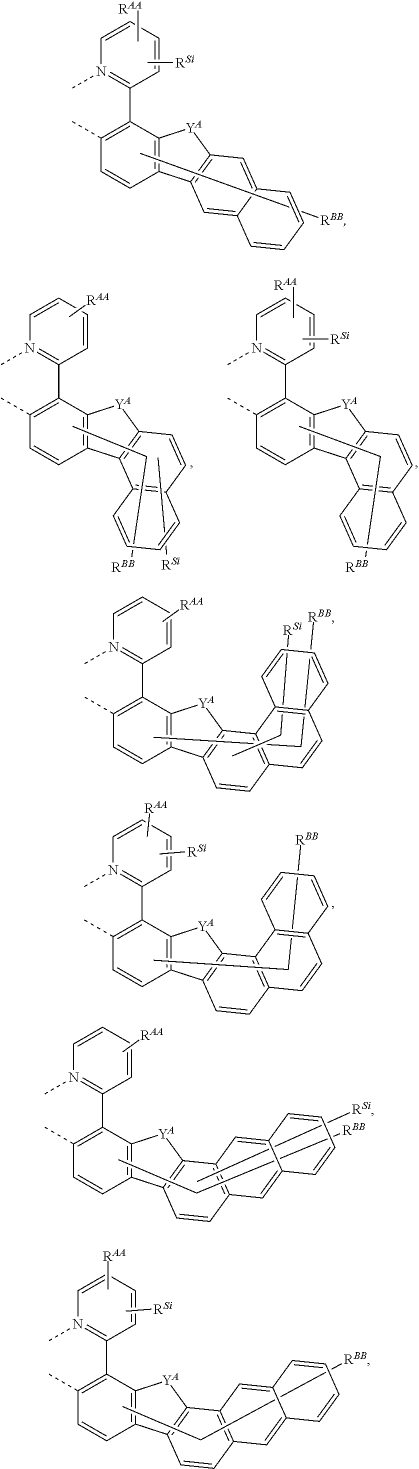 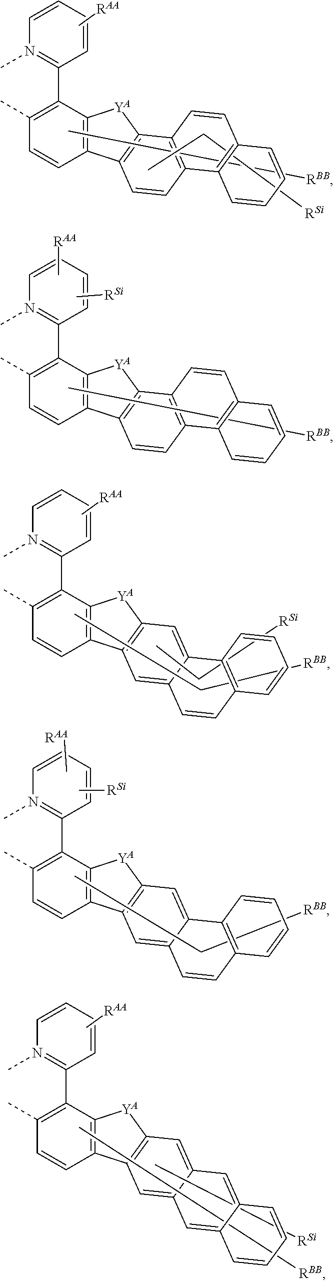 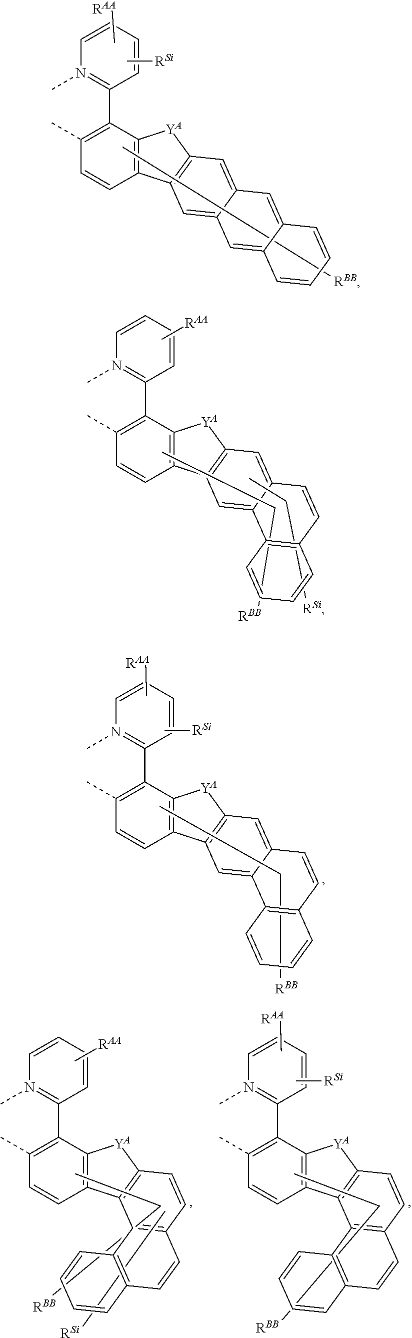 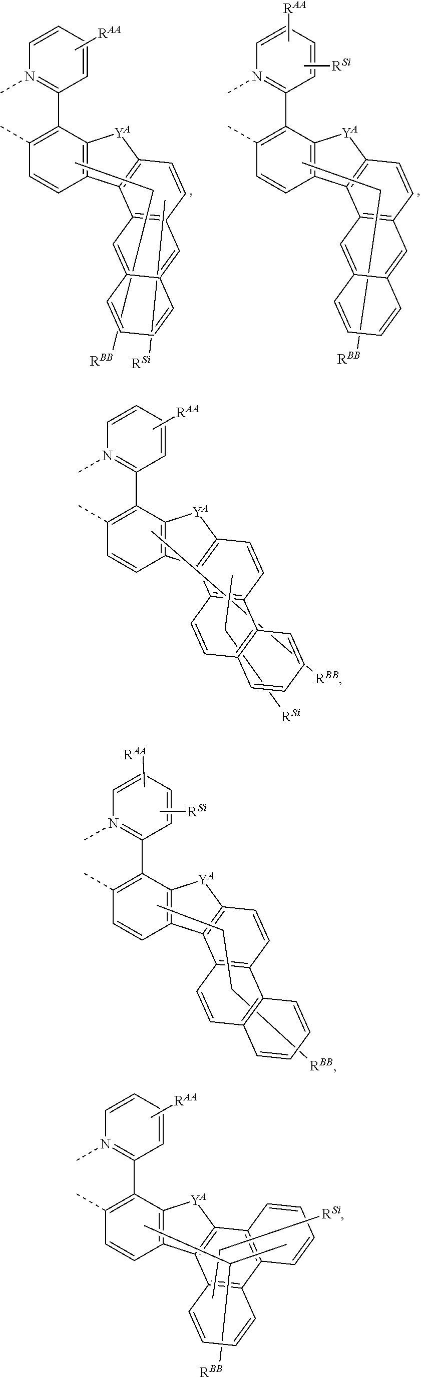 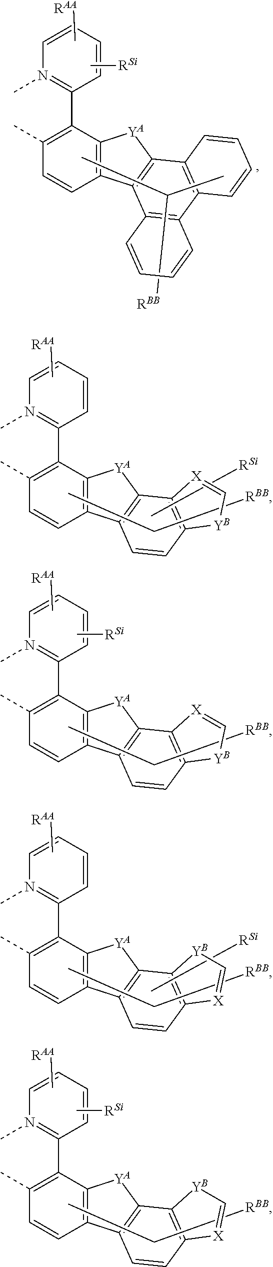 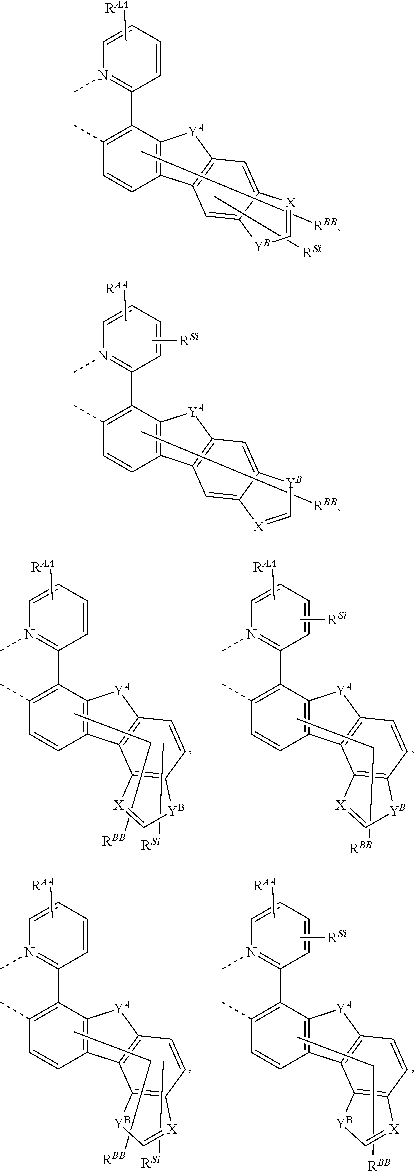 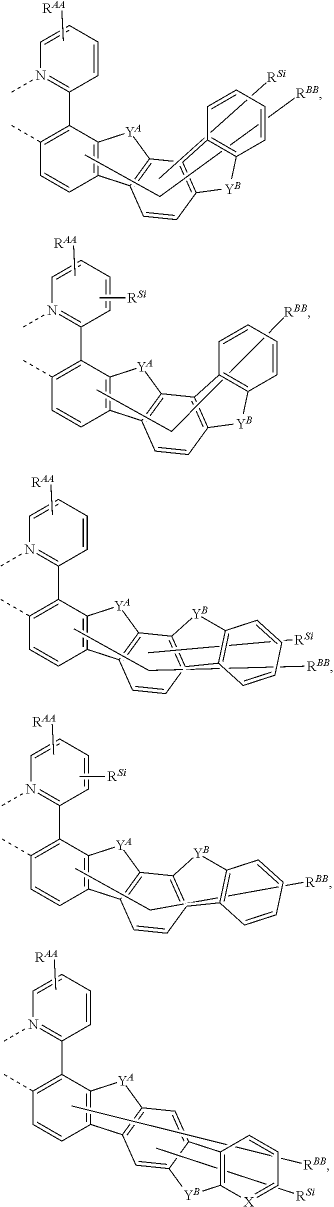 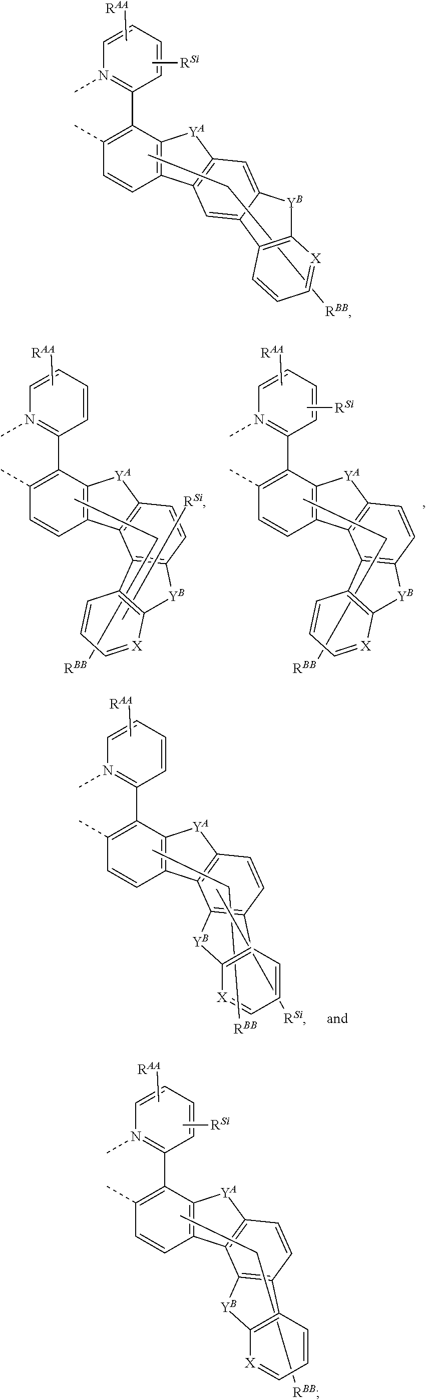
wherein:
X is Cor N;
each of Y^{A} and Y^{B} is independently selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
each of R^{AA}, R^{BB}, and R^{CC} independently represents mono to the maximum allowable substitutions, or no substitutions;
each Rₑ, R_{f}, R^{AA}, R^{BB}, R^{CC}, and R^{Si} is independently hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
R³ is a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
with the proviso that R^{Si} comprises a silyl moiety; and
any two R^{A}, R^{B}, R^{C}, R^{α}, and R^{β} may be joined or fused to form a ring.

11. The compound of claim 1, wherein the ligand L_{A} is selected from the group consisting of L_{Ai}, and L_{Aw}R^{m})(Rⁿ)(R^{o})(R^{p})(T), wherein i is an integer from 1 to 90, w is an integer from 1 to 62, each) L_{Aw}R^{m})(Rⁿ)(R^{o})(R^{p})(T) is defined as follows:

| Compound | Structure of compound | Compound | Structure of compound |
|---|---|---|---|
| L_{A1}(R^{m})(Rⁿ) (R^{o})(R^{p})(T), wherein L_{A1}(R1)(R1) (R1)(R1)(T1) to L_{A1}(R115) (R115)(R115) (R115)T(20), have the structure | 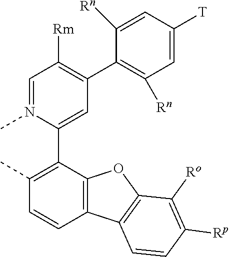 | L_{A2}(R^{m})(Rⁿ) (R^{o})(R^{p})(T), wherein L_{A2}(R1)(R1) (R1)(R1)(T1) to L_{A2}(R115) (R115)(R115) (R115)T(20), have the structure | 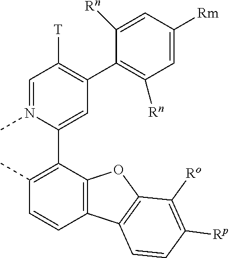 |
| L_{A3}(R^{m})(Rⁿ) (R^{o})(R^{p})(T), wherein L_{A3}(R1)(R1) (R1)(R1)(T1) to L_{A3}(R115) (R115)(R115) (R115)T(20), have the structure | 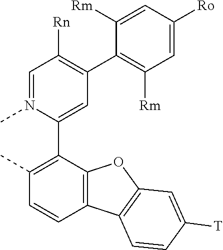 | L_{A4}(R^{m})(Rⁿ) (R^{o})(R^{p})(T), wherein L_{A4}(R1)(R1) (R1)(R1)(T1) to L_{A4}(R115) (R115)(R115) (R115)T(20), have the structure | 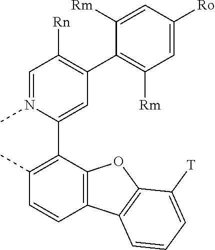 |
| L_{A5}(R^{m})(Rⁿ) (R^{o})(R^{p})(T), wherein L_{A5}(R1)(R1) (R1)(R1)(T1) to L_{A5}(R115) (R115)(R115) (R115)T(20), have the structure | 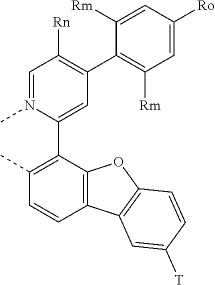 | L_{A6}(R^{m})(Rⁿ) (R^{o})(R^{p})(T), wherein L_{A6}(R1)(R1) (R1)(R1)(T1) to L_{A6}(R115) (R115)(R115) (R115)T(20), have the structure | 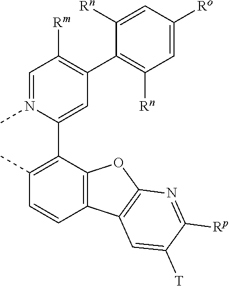 |
| L_{A7}(R^{m})(Rⁿ) (R^{o})(R^{p})(T), wherein L_{A7}(R1)(R1) (R1)(R1)(T1) to L_{A7}(R115) (R115)(R115) (R115)T(20), have the structure | 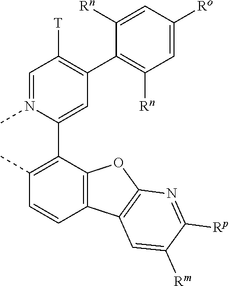 | L_{A8}(R^{m})(Rⁿ) (R^{o})(R^{p})(T), wherein L_{A8}(R1)(R1) (R1)(R1)(T1) to L_{A8}(R115) (R115)(R115) (R115)T(20), have the structure | 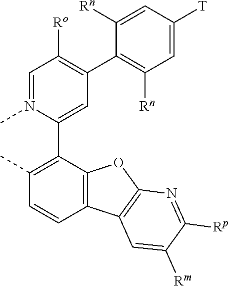 |
| L_{A9}(R^{m})(Rⁿ) (R^{o})(R^{p})(T), wherein L_{A9}(R1)(R1) (R1)(R1)(T1) to L_{A9}(R115) (R115)(R115) (R115)T(20), have the structure | 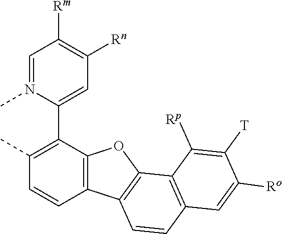 | L_{A10}(R^{m})(Rⁿ) (R^{o})(R^{p})(T), wherein L_{A10}(R1)(R1) (R1)(R1)(T1) to L_{A10}(R115) (R115)(R115) (R115)T(20), have the structure | 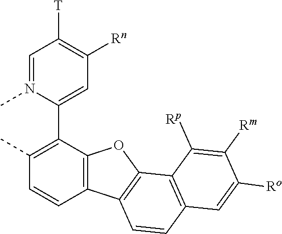 |
| L_{A11}(R^{m})(Rⁿ) (R^{o})(R^{p})(T), wherein L_{A11}(R1)(R1) (R1)(R1)(T1) to L_{A11}(R115) (R115)(R115) (R115)T(20), have the structure | 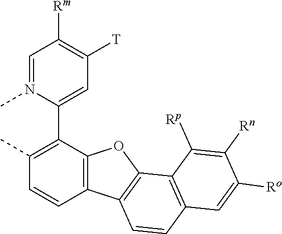 | L_{A12}(R^{m})(Rⁿ) (R^{o})(R^{p})(T), wherein L_{A12}(R1)(R1) (R1)(R1)(T1) to L_{A12}(R115) (R115)(R115) (R115)T(20), have the structure | 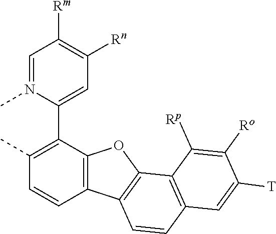 |
| L_{A13}(R^{m})(Rⁿ) (R^{o})(R^{p})(T), wherein L_{A13}(R1)(R1) (R1)(R1)(T1) to L_{A13}(R115) (R115)(R115) (R115)T(20), have the structure | 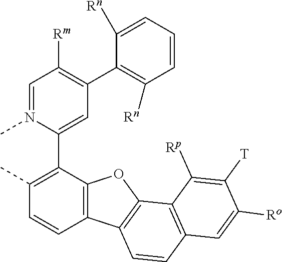 | L_{A14}(R^{m})(Rⁿ) (R^{o})(R^{p})(T), wherein L_{A14}(R1)(R1) (R1)(R1)(T1) to L_{A14}(R115) (R115)(R115) (R115)T(20), have the structure | 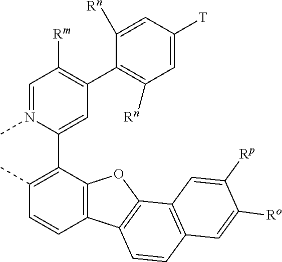 |
| L_{A15}(R^{m})(Rⁿ) (R^{o})(R^{p})(T), wherein L_{A15}(R1)(R1) (R1)(R1)(T1) to L_{A15}(R115) (R115)(R115) (R115)T(20), have the structure | 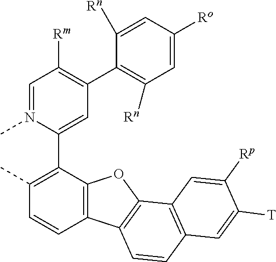 | L_{A16}(R^{m})(Rⁿ) (R^{o})(R^{p})(T), wherein L_{A16}(R1)(R1) (R1)(R1)(T1) to L_{A16}(R115) (R115)(R115) (R115)T(20), have the structure | 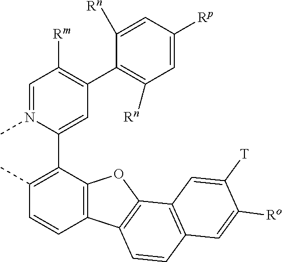 |
| L_{A17}(R^{m})(Rⁿ) (R^{o})(R^{p})(T), wherein L_{A17}(R1)(R1) (R1)(R1)(T1) to L_{A17}(R115) (R115)(R115) (R115)T(20), have the structure | 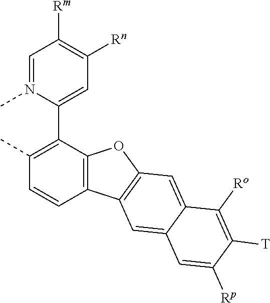 | L_{A18}(R^{m})(Rⁿ) (R^{o})(R^{p})(T), wherein L_{A18}(R1)(R1) (R1)(R1)(T1) to L_{A18}(R115) (R115)(R115) (R115)T(20), have the structure | 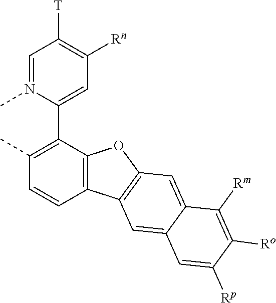 |
| L_{A19}(R^{m})(Rⁿ) (R^{o})(R^{p})(T), wherein L_{A19}(R1)(R1) (R1)(R1)(T1) to L_{A19}(R115) (R115)(R115) (R115)T(20), have the structure | 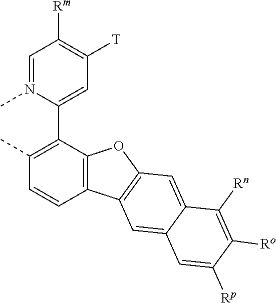 | L_{A20}(R^{m})(Rⁿ) (R^{o})(R^{p})(T), wherein L_{A20}(R1)(R1) (R1)(R1)(T1) to L_{A20}(R115) (R115)(R115) (R115)T(20), have the structure | 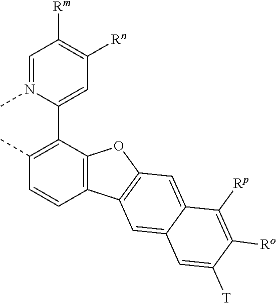 |
| L_{A21}(R^{m})(Rⁿ) (R^{o})(R^{p})(T), wherein L_{A21}(R1)(R1) (R1)(R1)(T1) to L_{A21}(R115) (R115)(R115) (R115)T(20), have the structure | 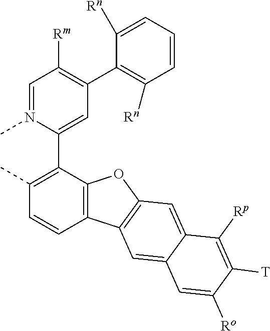 | L_{A22}(R^{m})(Rⁿ) (R^{o})(R^{p})(T), wherein L_{A22}(R1)(R1) (R1)(R1)(T1) to L_{A22}(R115) (R115)(R115) (R115)T(20), have the structure | 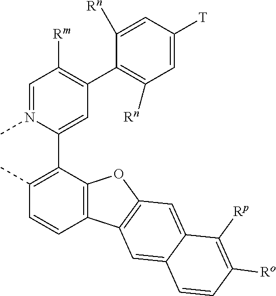 |
| L_{A23}(R^{m})(Rⁿ) (R^{o})(R^{p})(T), wherein L_{A23}(R1)(R1) (R1)(R1)(T1) to L_{A23}(R115) (R115)(R115) (R115)T(20), have the structure | 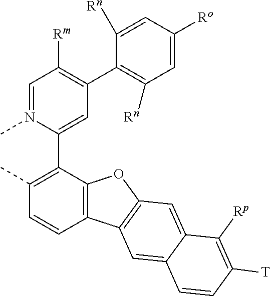 | L_{A24}(R^{m})(Rⁿ) (R^{o})(R^{p})(T), wherein L_{A24}(R1)(R1) (R1)(R1)(T1) to L_{A24}(R115) (R115)(R115) (R115)T(20), have the structure | 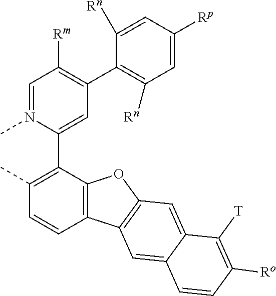 |
| L_{A25}(R^{m})(Rⁿ) (R^{o})(R^{p})(T), wherein L_{A25}(R1)(R1) (R1)(R1)(T1) to L_{A25}(R115) (R115)(R115) (R115)T(20), have the structure | 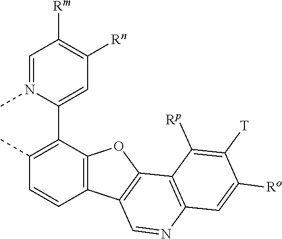 | L_{A26}(R^{m})(Rⁿ) (R^{o})(R^{p})(T), wherein L_{A26}(R1)(R1) (R1)(R1)(T1) to L_{A26}(R115) (R115)(R115) (R115)T(20), have the structure | 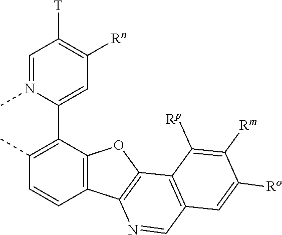 |
| L_{A27}(R^{m})(Rⁿ) (R^{o})(R^{p})(T), wherein L_{A27}(R1)(R1) (R1)(R1)(T1) to L_{A27}(R115) (R115)(R115) (R115)T(20), have the structure | 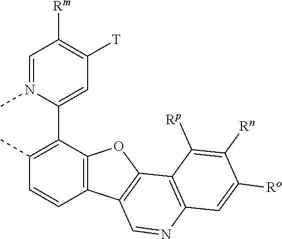 | L_{A28}(R^{m})(Rⁿ) (R^{o})(R^{p})(T), wherein L_{A28}(R1)(R1) (R1)(R1)(T1) to L_{A28}(R115) (R115)(R115) (R115)T(20), have the structure | 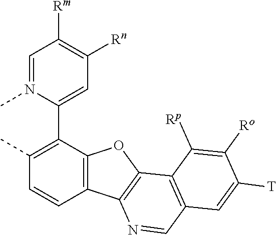 |
| L_{A29}(R^{m})(Rⁿ) (R^{o})(R^{p})(T), wherein L_{A29}(R1)(R1) (R1)(R1)(T1) to L_{A29}(R115) (R115)(R115) (R115)T(20), have the structure | 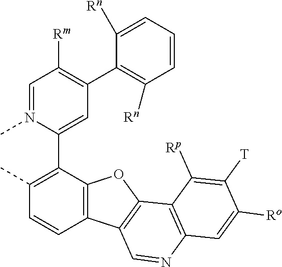 | L_{A30}(R^{m})(Rⁿ) (R^{o})(R^{p})(T), wherein L_{A30}(R1)(R1) (R1)(R1)(T1) to L_{A30}(R115) (R115)(R115) (R115)T(20), have the structure | 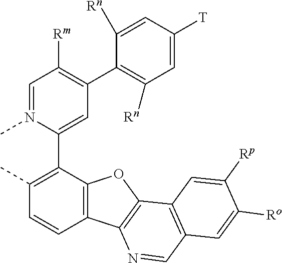 |
| L_{A31}(R^{m})(Rⁿ) (R^{o})(R^{p})(T), wherein L_{A31}(R1)(R1) (R1)(R1)(T1) to L_{A31}(R115) (R115)(R115) (R115)T(20), have the structure | 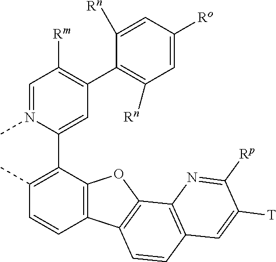 | L_{A32}(R^{m})(Rⁿ) (R^{o})(R^{p})(T), wherein L_{A32}(R1)(R1) (R1)(R1)(T1) to L_{A32}(R115) (R115)(R115) (R115)T(20), have the structure | 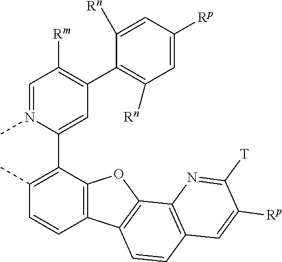 |
| L_{A33}(R^{m})(Rⁿ) (R^{o})(R^{p})(T), wherein L_{A33}(R1)(R1) (R1)(R1)(T1) to L_{A33}(R115) (R115)(R115) (R115)T(20), have the structure | 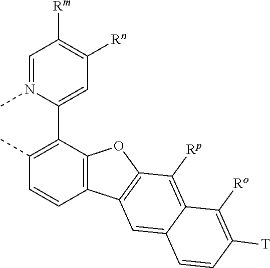 | L_{A34}(R^{m})(Rⁿ) (R^{o})(R^{p})(T), wherein L_{A34}(R1)(R1) (R1)(R1)(T1) to L_{A34}(R115) (R115)(R115) (R115)T(20), have the structure | 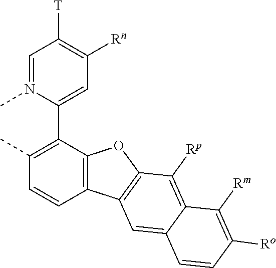 |
| L_{A35}(R^{m})(Rⁿ) (R^{o})(R^{p})(T), wherein L_{A35}(R1)(R1) (R1)(R1)(T1) to L_{A35}(R115) (R115)(R115) (R115)T(20), have the structure | 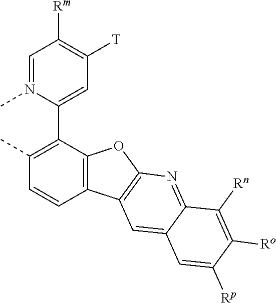 | L_{A36}(R^{m})(Rⁿ) (R^{o})(R^{p})(T), wherein L_{A36}(R1)(R1) (R1)(R1)(T1) to L_{A36}(R115) (R115)(R115) (R115)T(20), have the structure | 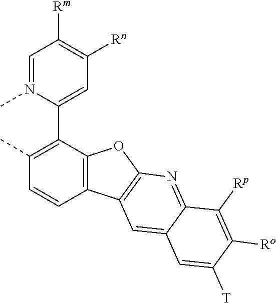 |
| L_{A37}(R^{m})(Rⁿ) (R^{o})(R^{p})(T), wherein L_{A37}(R1)(R1) (R1)(R1)(T1) to L_{A37}(R115) (R115)(R115) (R115)T(20), have the structure | 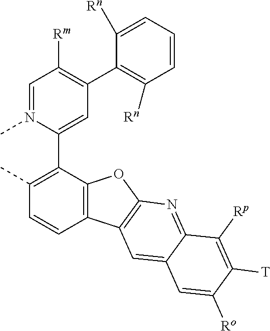 | L_{A38}(R^{m})(Rⁿ) (R^{o})(R^{p})(T), wherein L_{A38}(R1)(R1) (R1)(R1)(T1) to L_{A38}(R115) (R115)(R115) (R115)T(20), have the structure | 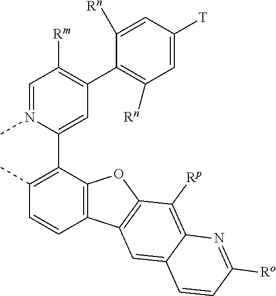 |
| L_{A39}(R^{m})(Rⁿ) (R^{o})(R^{p})(T), wherein L_{A39}(R1)(R1) (R1)(R1)(T1) to L_{A39}(R115) (R115)(R115) (R115)T(20), have the structure | 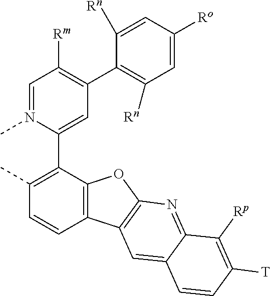 | L_{A40}(R^{m})(Rⁿ) (R^{o})(R^{p})(T), wherein L_{A40}(R1)(R1) (R1)(R1)(T1) to L_{A40}(R115) (R115)(R115) (R115)T(20), have the structure | 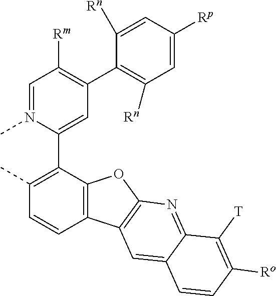 |
| L_{A41}(R^{m})(Rⁿ) (R^{o})(R^{p})(T), wherein L_{A41}(R1)(R1) (R1)(R1)(T1) to L_{A41}(R115) (R115)(R115) (R115)T(20), have the structure | 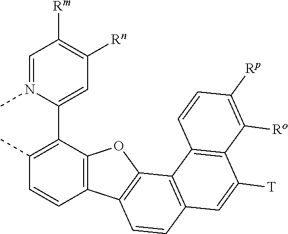 | L_{A42}(R^{m})(Rⁿ) (R^{o})(R^{p})(T), wherein L_{A42}(R1)(R1) (R1)(R1)(T1) to L_{A42}(R115) (R115)(R115) (R115)T(20), have the structure | 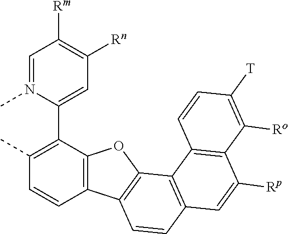 |
| L_{A43}(R^{m})(Rⁿ) (R^{o})(R^{p})(T), wherein L_{A43}(R1)(R1) (R1)(R1)(T1) to L_{A43}(R115) (R115)(R115) (R115)T(20), have the structure | 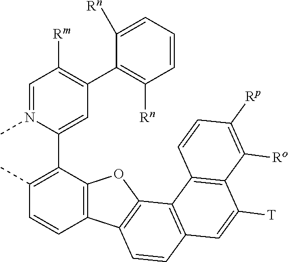 | L_{A44}(R^{m})(Rⁿ) (R^{o})(R^{p})(T), wherein L_{A44}(R1)(R1) (R1)(R1)(T1) to L_{A44}(R115) (R115)(R115) (R115)T(20), have the structure | 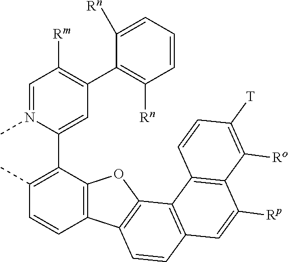 |
| L_{A45}(R^{m})(Rⁿ) (R^{o})(R^{p})(T), wherein L_{A45}(R1)(R1) (R1)(R1)(T1) to L_{A45}(R115) (R115)(R115) (R115)T(20), have the structure | 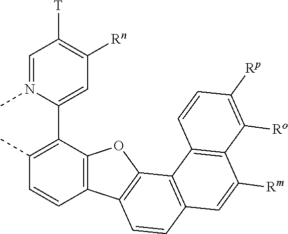 | L_{A46}(R^{m})(Rⁿ) (R^{o})(R^{p})(T), wherein L_{A46}(R1)(R1) (R1)(R1)(T1) to L_{A46}(R115) (R115)(R115) (R115)T(20), have the structure | 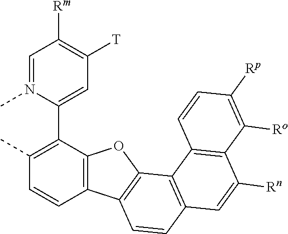 |
| L_{A47}(R^{m})(Rⁿ) (R^{o})(R^{p})(T), wherein L_{A47}(R1)(R1) (R1)(R1)(T1) to L_{A47}(R115) (R115)(R115) (R115)T(20), have the structure | 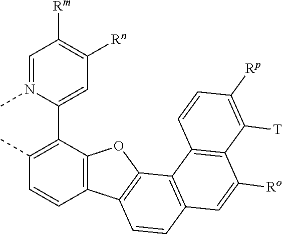 | L_{A48}(R^{m})(Rⁿ) (R^{o})(R^{p})(T), wherein L_{A48}(R1)(R1) (R1)(R1)(T1) to L_{A48}(R115) (R115)(R115) (R115)T(20), have the structure | 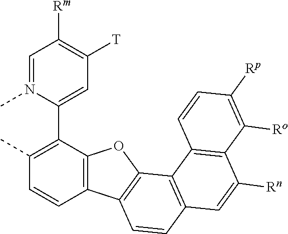 |
| L_{A49}(R^{m})(Rⁿ) (R^{o})(R^{p})(T), wherein L_{A49}(R1)(R1) (R1)(R1)(T1) to L_{A49}(R115) (R115)(R115) (R115)T(20), have the structure | 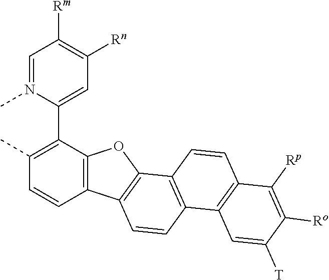 | L_{A50}(R^{m})(Rⁿ) (R^{o})(R^{p})(T), wherein L_{A50}(R1)(R1) (R1)(R1)(T1) to L_{A50}(R115) (R115)(R115) (R115)T(20), have the structure | 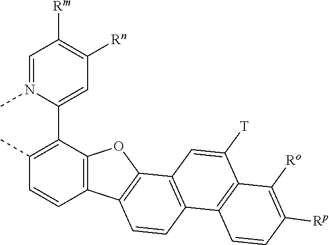 |
| L_{A51}(R^{m})(Rⁿ) (R^{o})(R^{p})(T), wherein L_{A51}(R1)(R1) (R1)(R1)(T1) to L_{A51}(R115) (R115)(R115) (R115)T(20), have the structure | 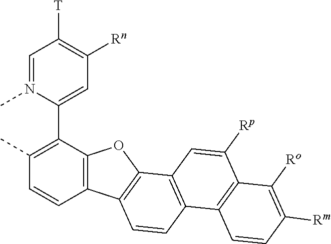 | L_{A52}(R^{m})(Rⁿ) (R^{o})(R^{p})(T), wherein L_{A52}(R1)(R1) (R1)(R1)(T1) to L_{A52}(R115) (R115)(R115) (R115)T(20), have the structure | 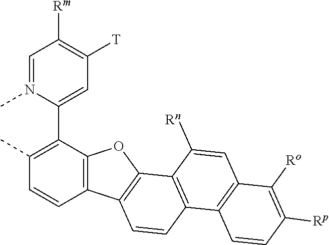 |
| L_{A53}(R^{m})(Rⁿ) (R^{o})(R^{p})(T), wherein L_{A53}(R1)(R1) (R1)(R1)(T1) to L_{A53}(R115) (R115)(R115) (R115)T(20), have the structure | 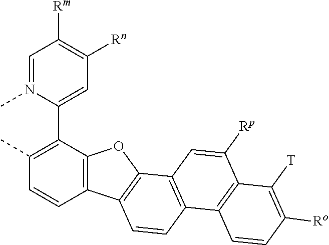 | L_{A54}(R^{m})(Rⁿ) (R^{o})(R^{p})(T), wherein L_{A54}(R1)(R1) (R1)(R1)(T1) to L_{A54}(R115) (R115)(R115) (R115)T(20), have the structure | 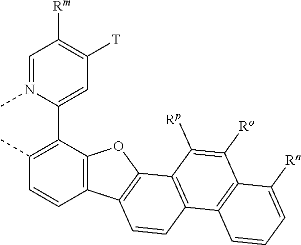 |
| L_{A55}(R^{m})(Rⁿ) (R^{o})(R^{p})(T), wherein L_{A55}(R1)(R1) (R1)(R1)(T1) to L_{A55}(R115) (R115)(R115) (R115)T(20), have the structure | 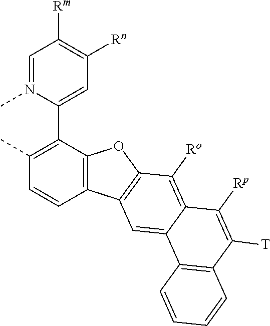 | L_{A56}(R^{m})(Rⁿ) (R^{o})(R^{p})(T), wherein L_{A56}(R1)(R1) (R1)(R1)(T1) to L_{A56}(R115) (R115)(R115) (R115)T(20), have the structure | 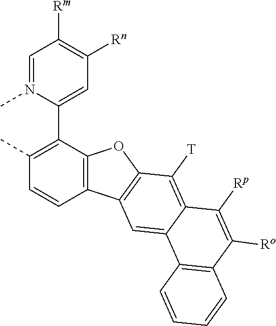 |
| L_{A57}(R^{m})(Rⁿ) (R^{o})(R^{p})(T), wherein L_{A57}(R1)(R1) (R1)(R1)(T1) to L_{A57}(R115) (R115)(R115) (R115)T(20), have the structure | 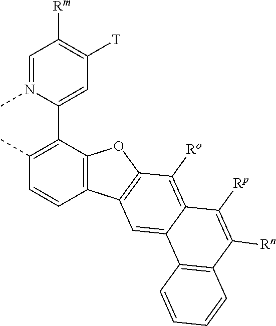 | L_{A58}(R^{m})(Rⁿ) (R^{o})(R^{p})(T), wherein L_{A58}(R1)(R1) (R1)(R1)(T1) to L_{A58}(R115) (R115)(R115) (R115)T(20), have the structure | 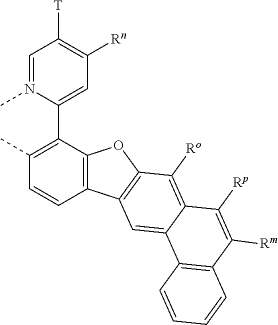 |
| L_{A59}(R^{m})(Rⁿ) (R^{o})(R^{p})(T), wherein L_{A59}(R1)(R1) (R1)(R1)(T1) to L_{A59}(R115) (R115)(R115) (R115)T(20), have the structure | 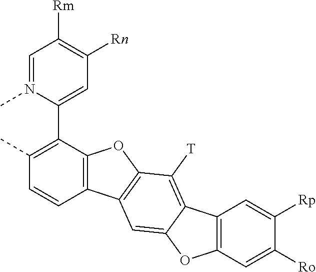 | L_{A60}(R^{m})(Rⁿ) (R^{o})(R^{p})(T), wherein L_{A60}(R1)(R1) (R1)(R1)(T1) to L_{A60}(R115) (R115)(R115) (R115)T(20), have the structure | 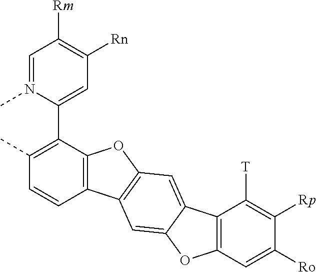 |
| L_{A61}(R^{m})(Rⁿ) (R^{o})(R^{p})(T), wherein L_{A61}(R1)(R1) (R1)(R1)(T1) to L_{A61}(R115) (R115)(R115) (R115)T(20), have the structure | 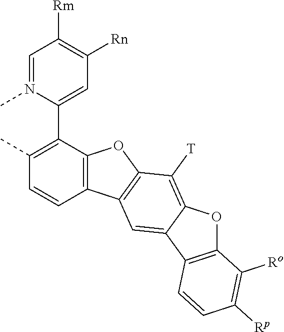 | L_{A62}R^{m})(Rⁿ) (R^{o})(R^{p})(T), wherein L_{A62}(R1)(R1) (R1)(R1)(T1) to L_{A62}(R115) (R115)(R115) (R115)T(20), have the structure | 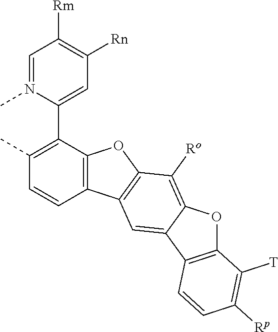 |

wherein R1 to R140 have the following structures: 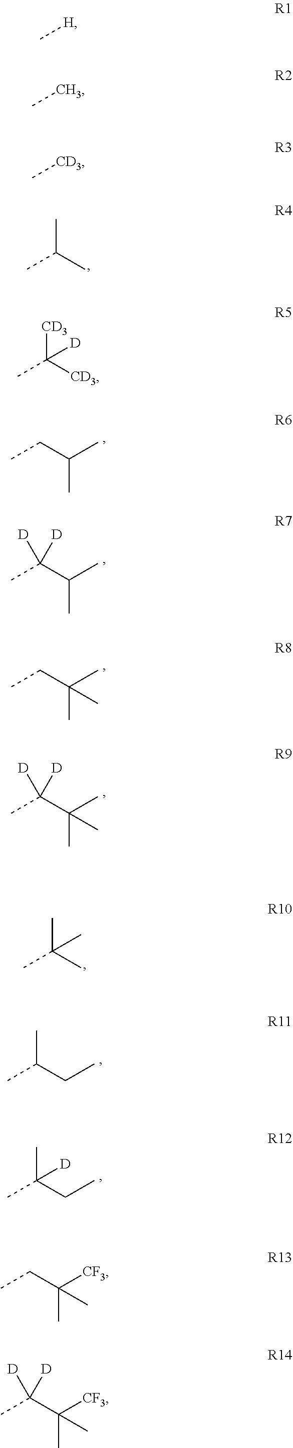 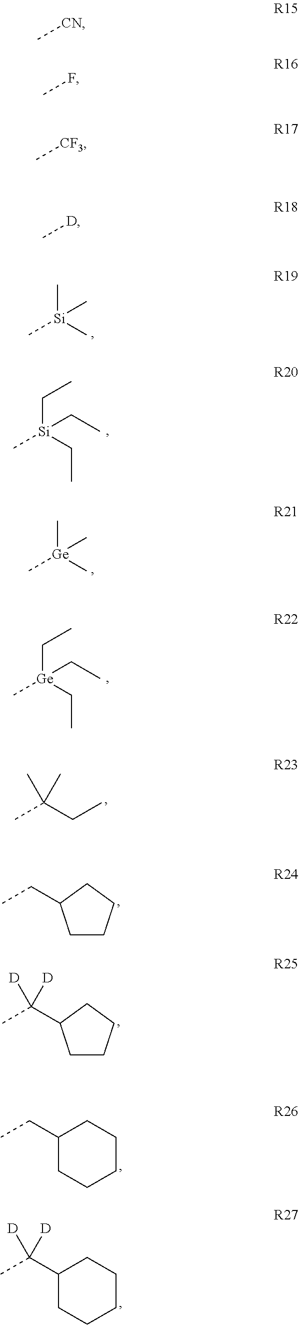 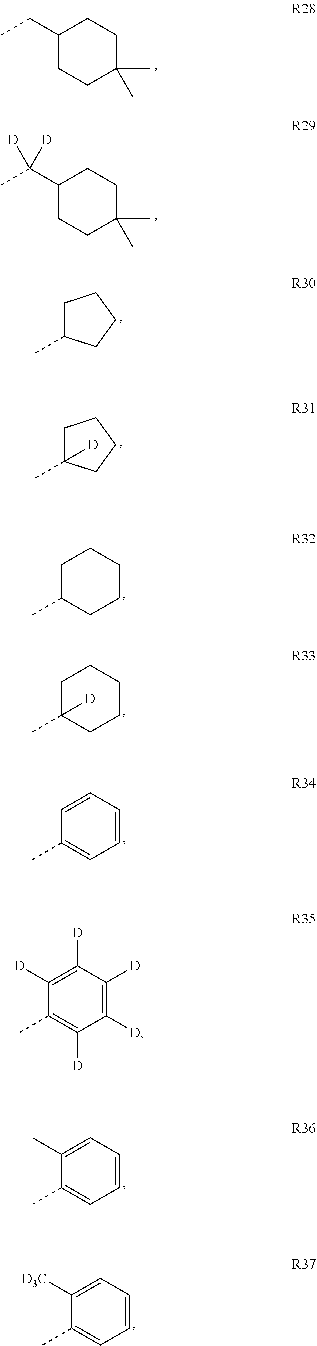 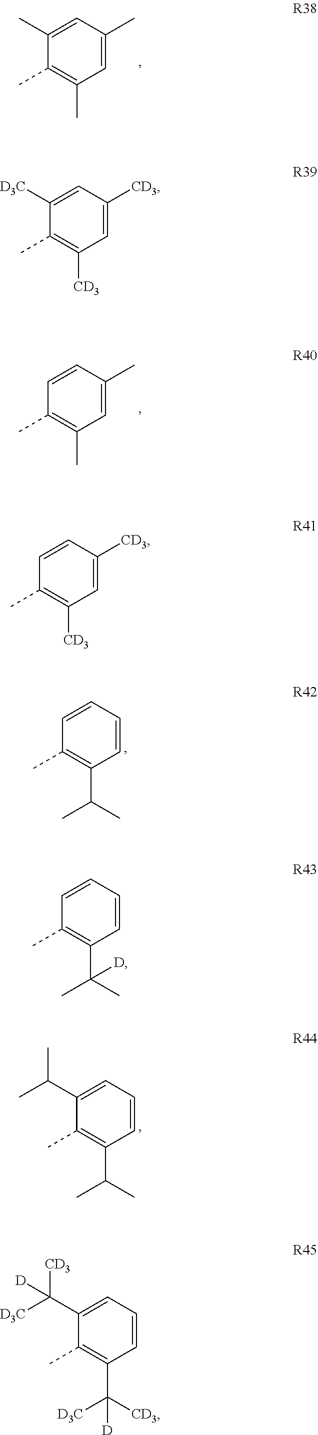 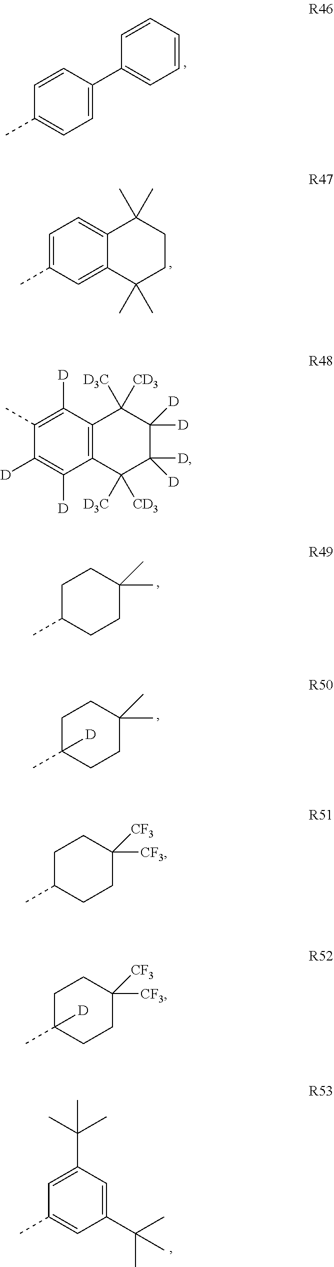 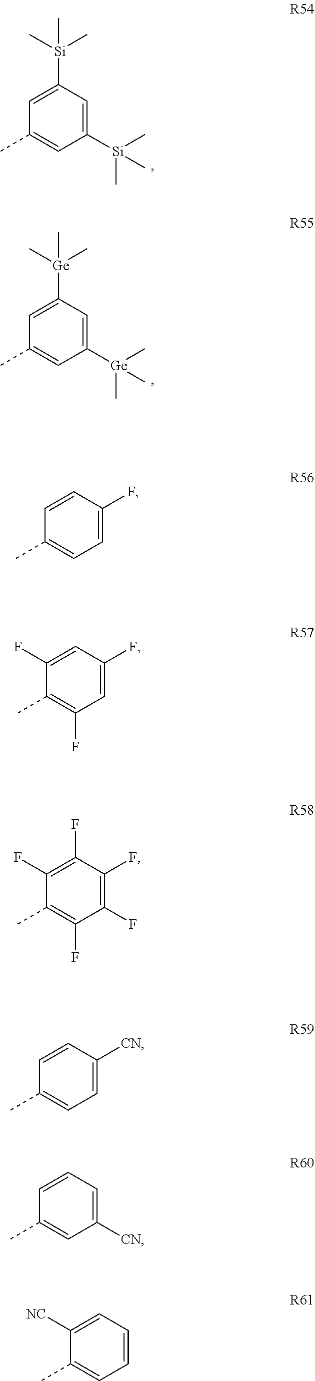 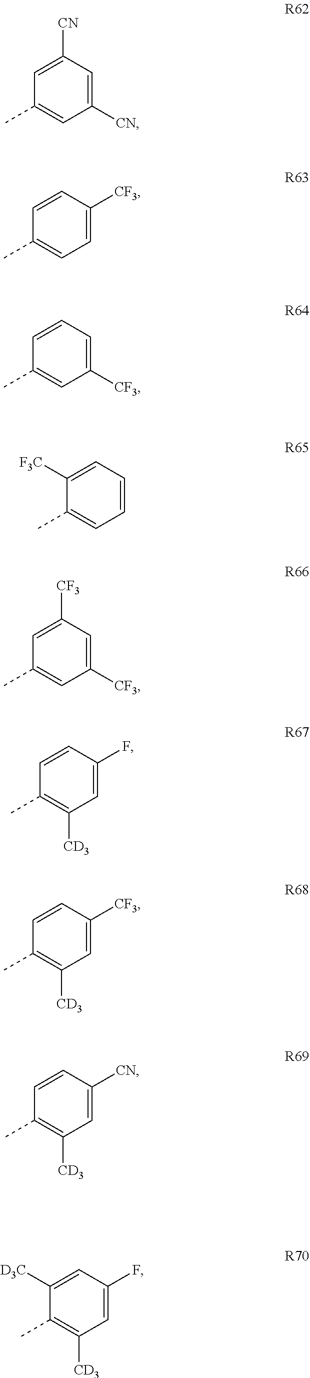 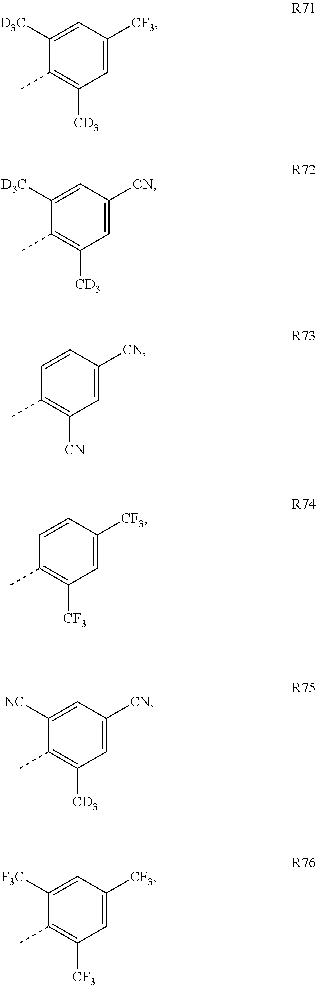 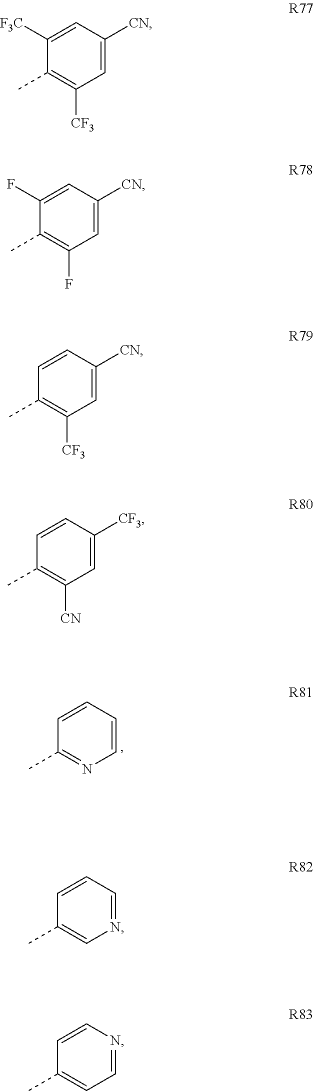 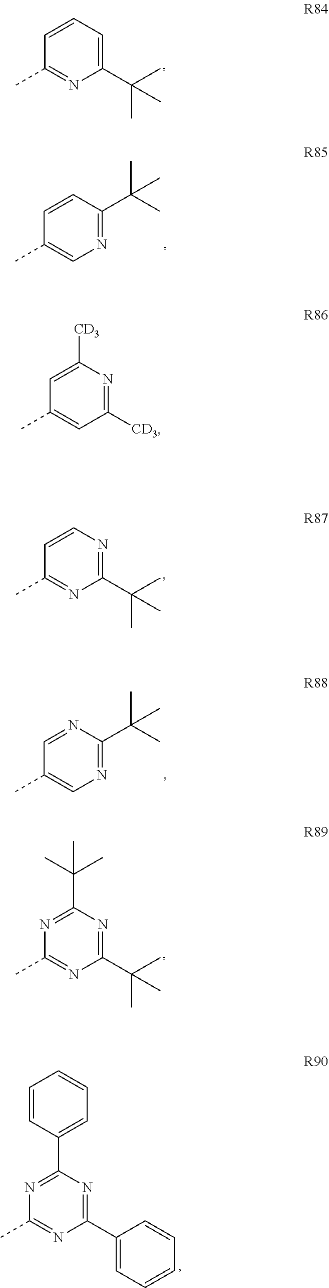 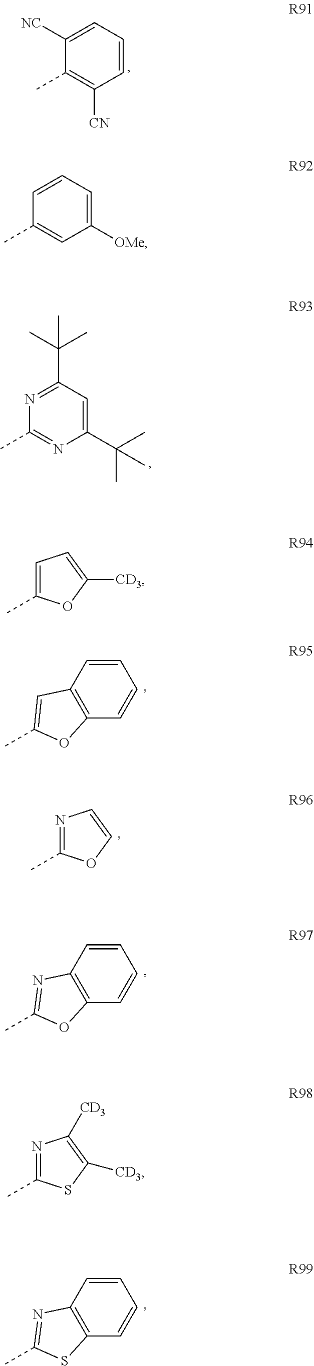 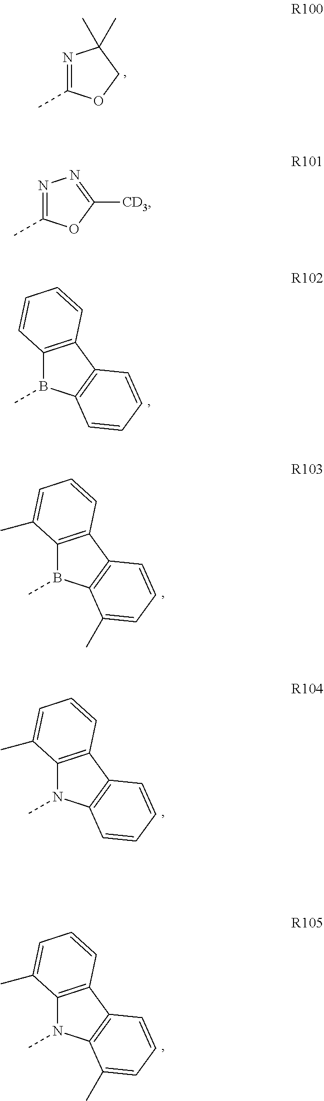 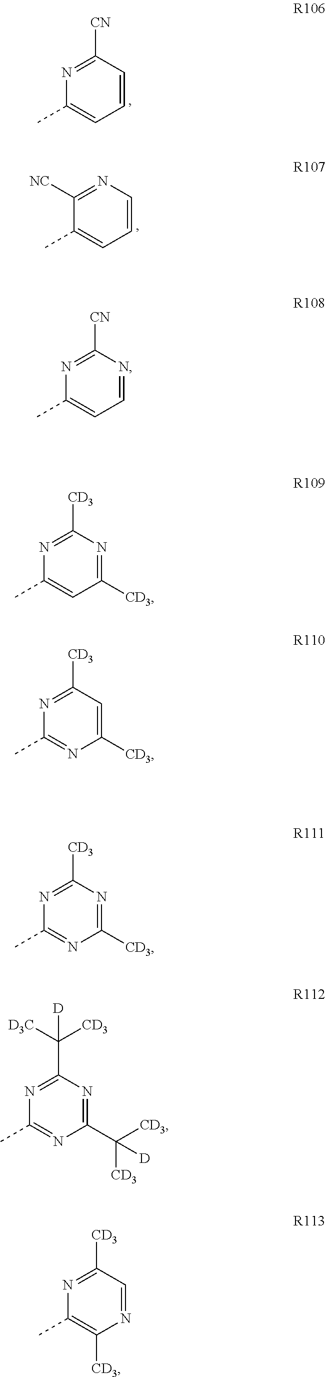 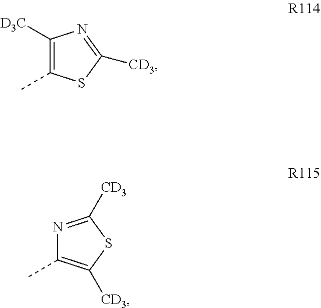
wherein T1 to T20 have the following structures: 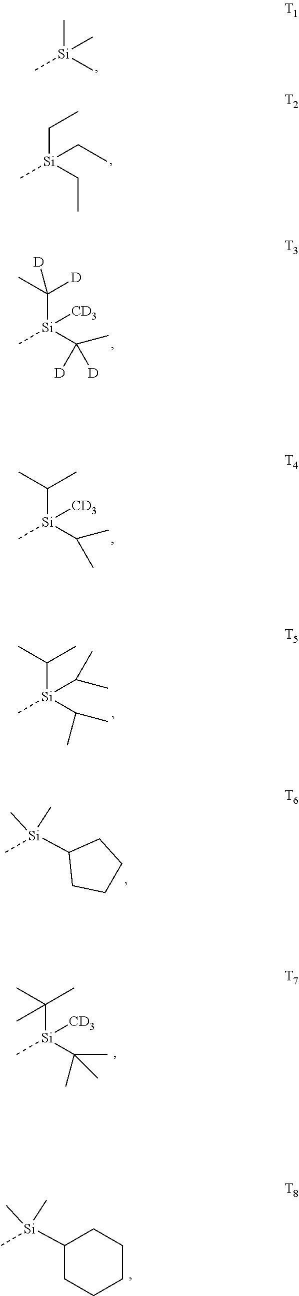 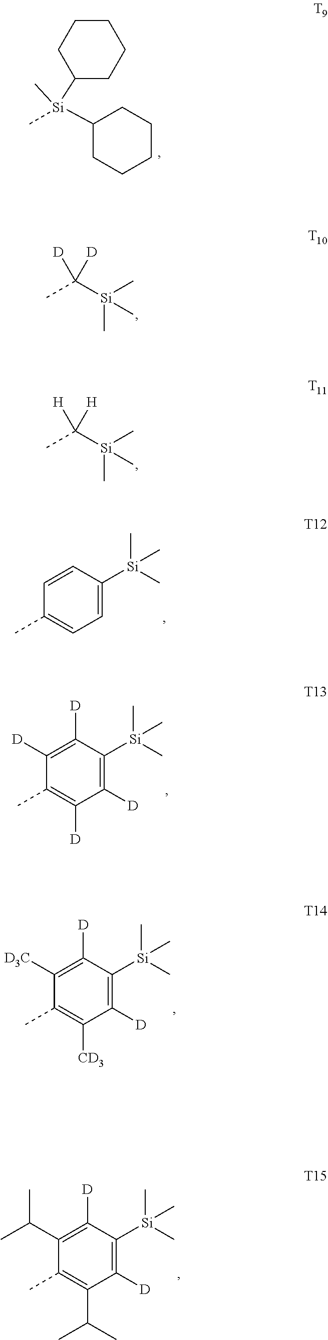 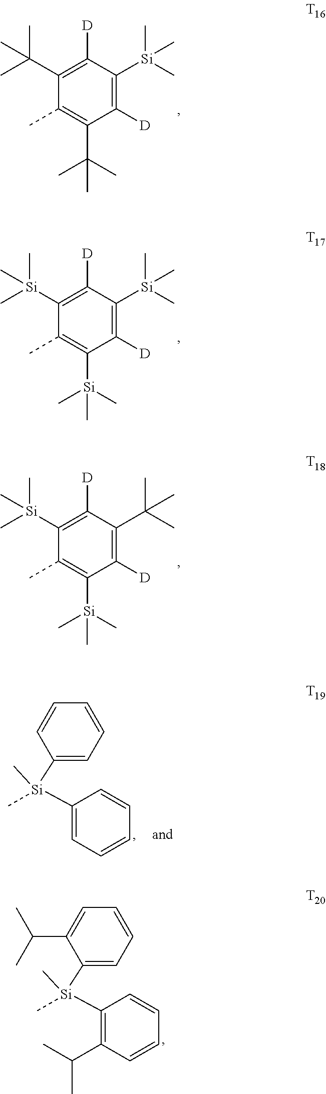
and each L_{Ai} is defined as follows:

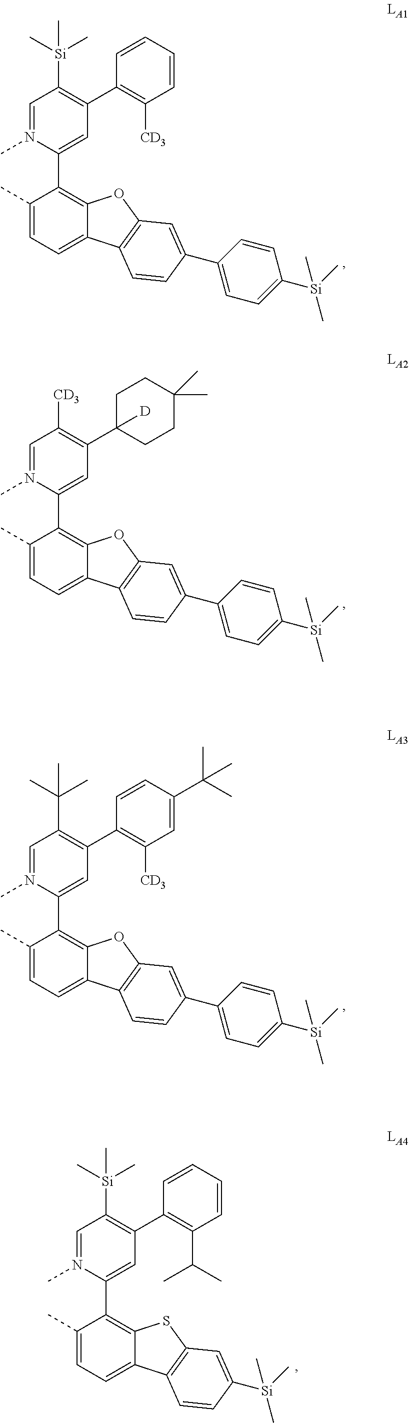

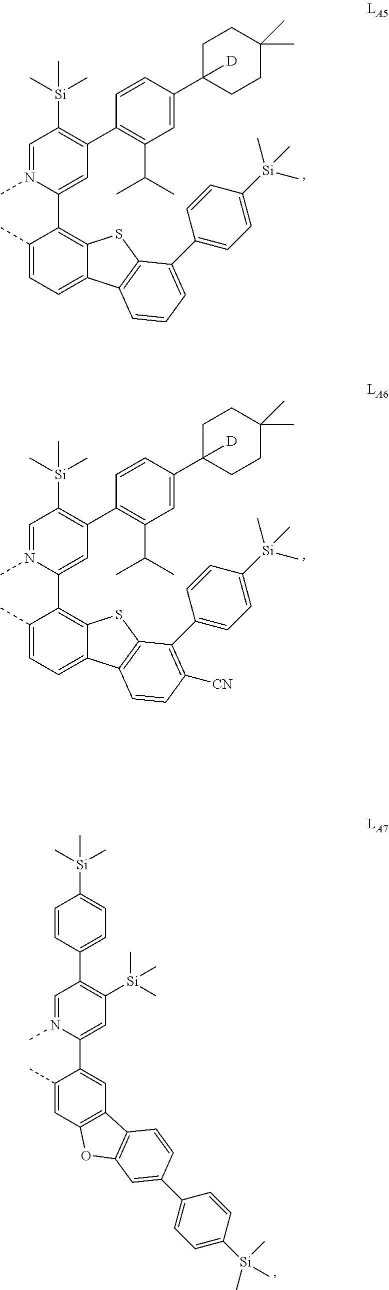

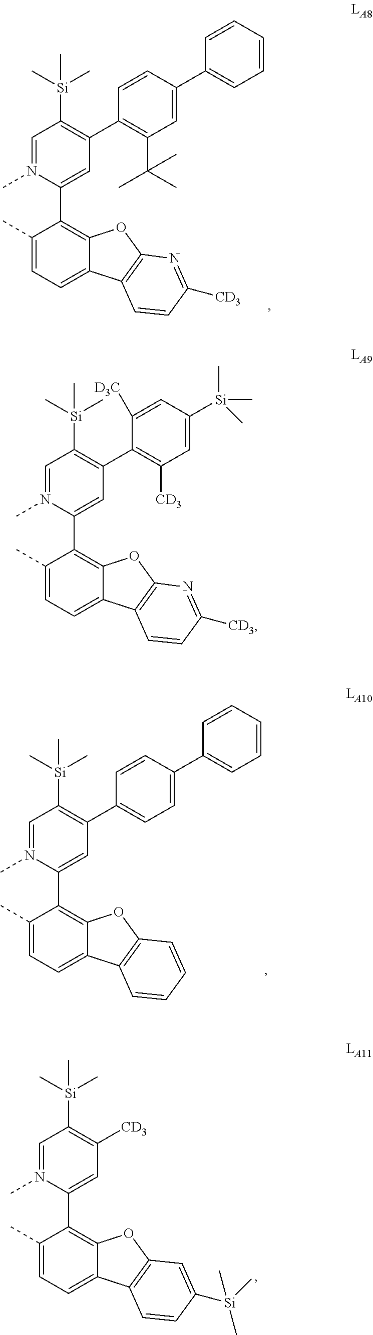

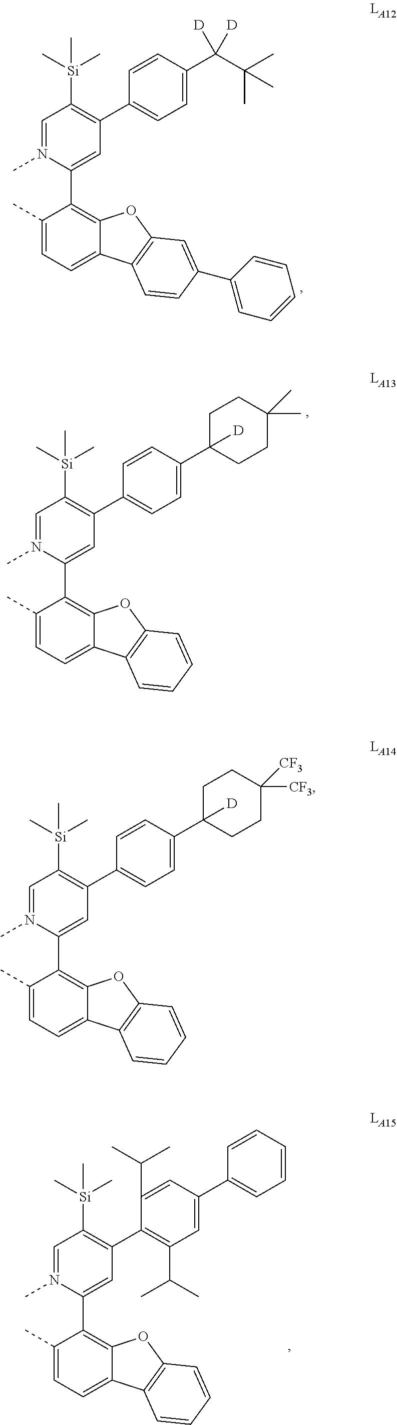

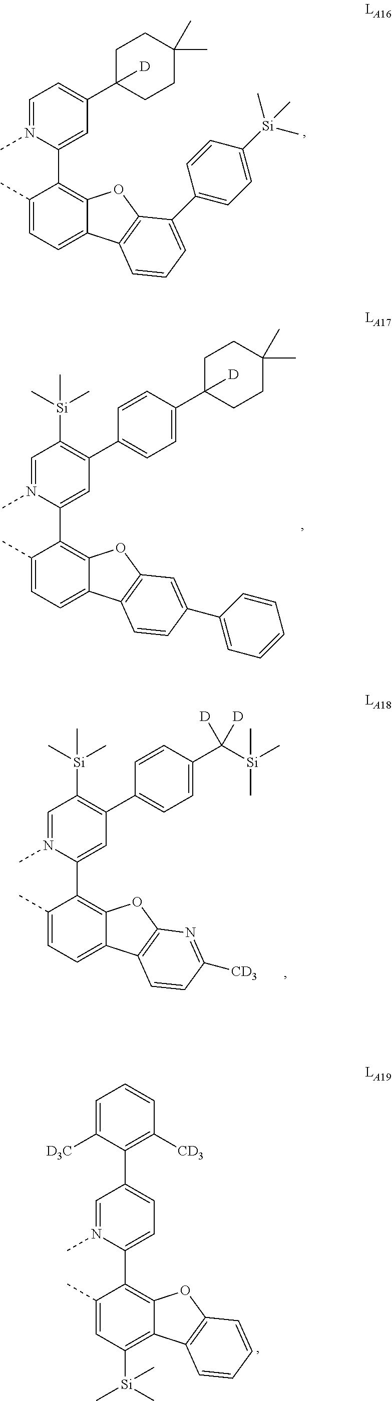

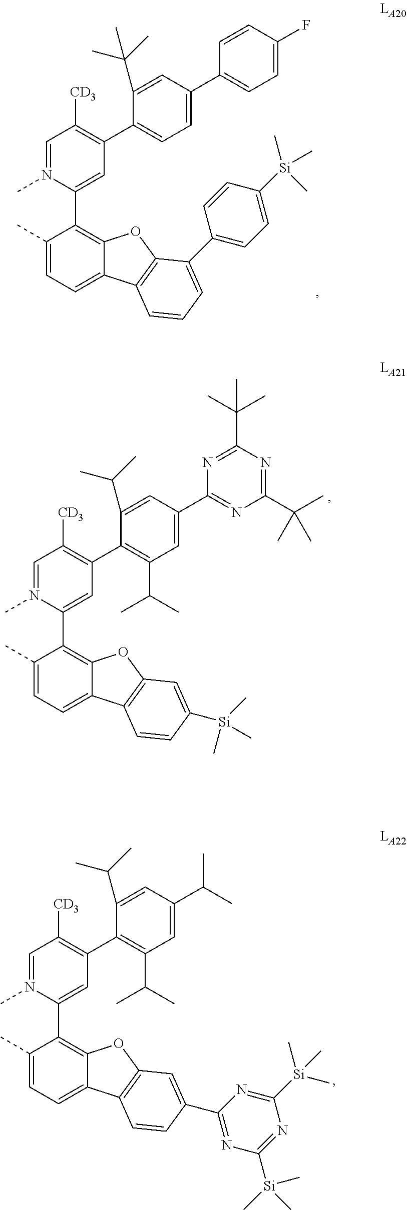

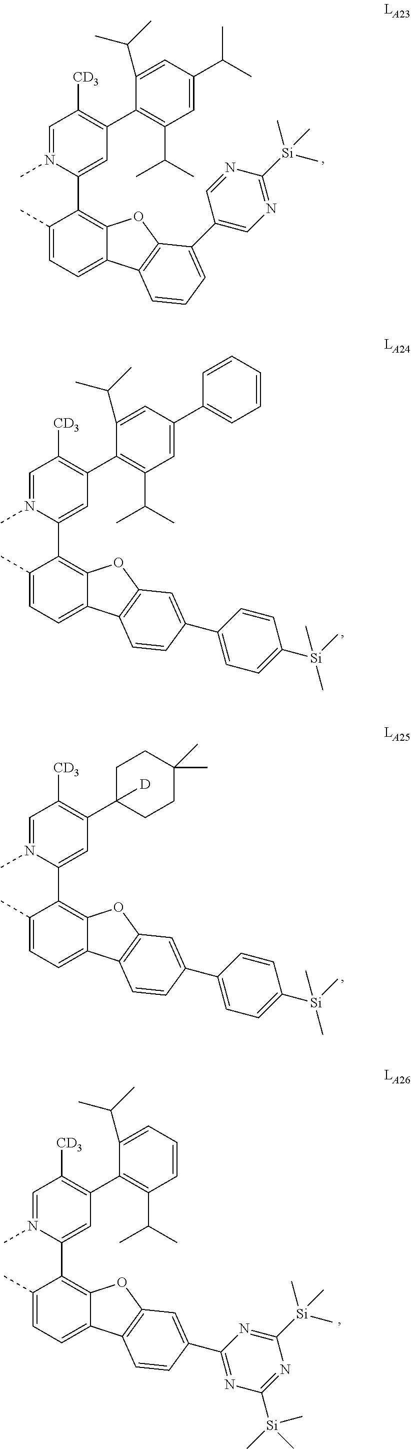

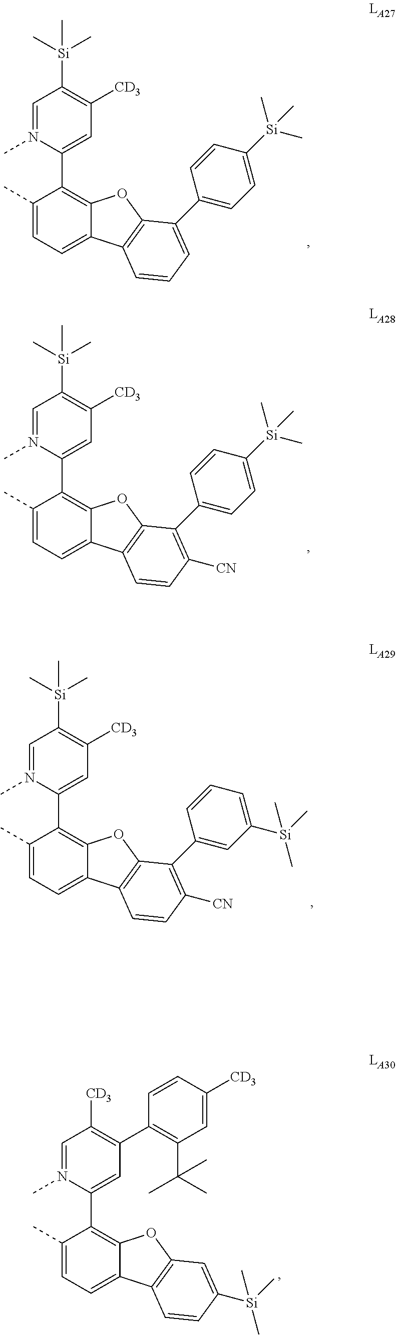

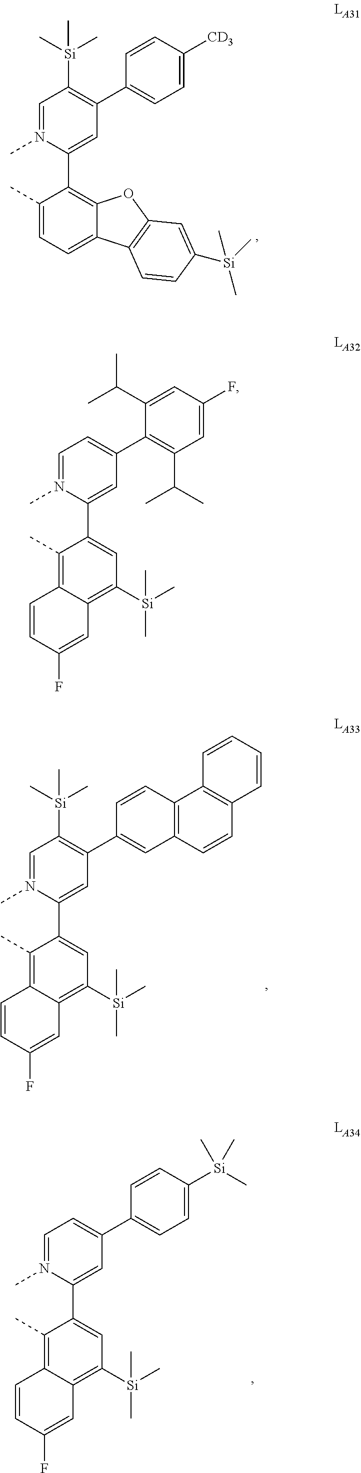

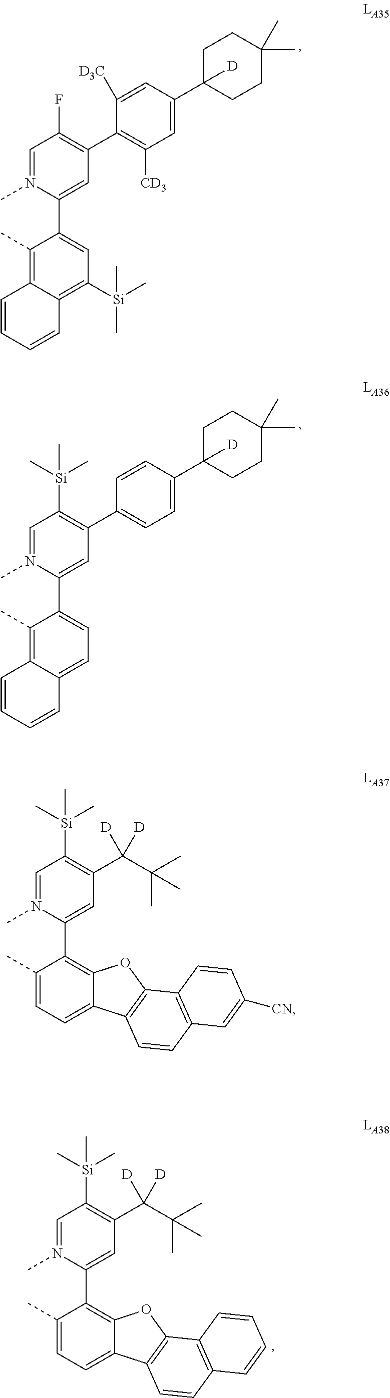

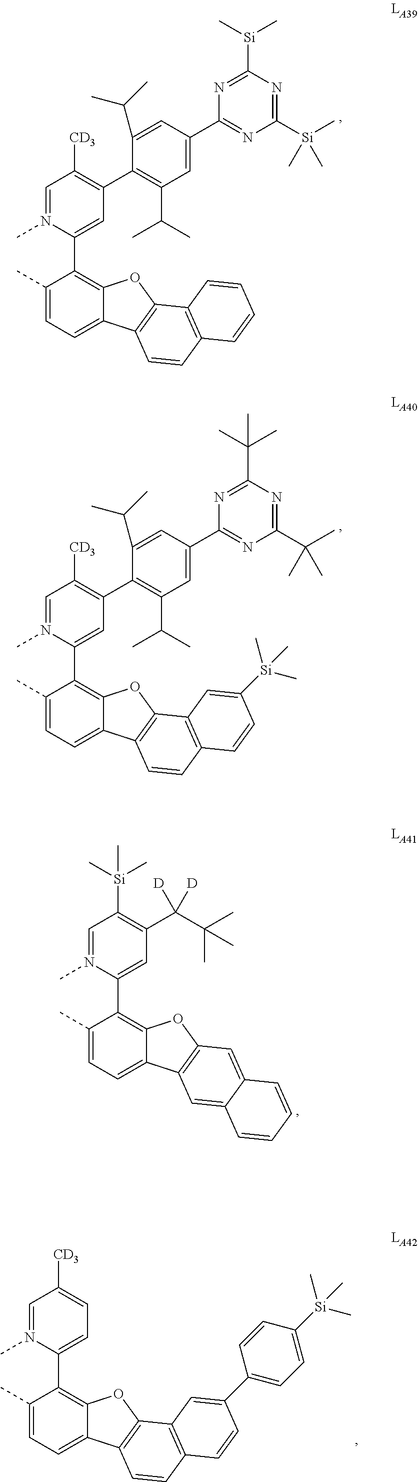

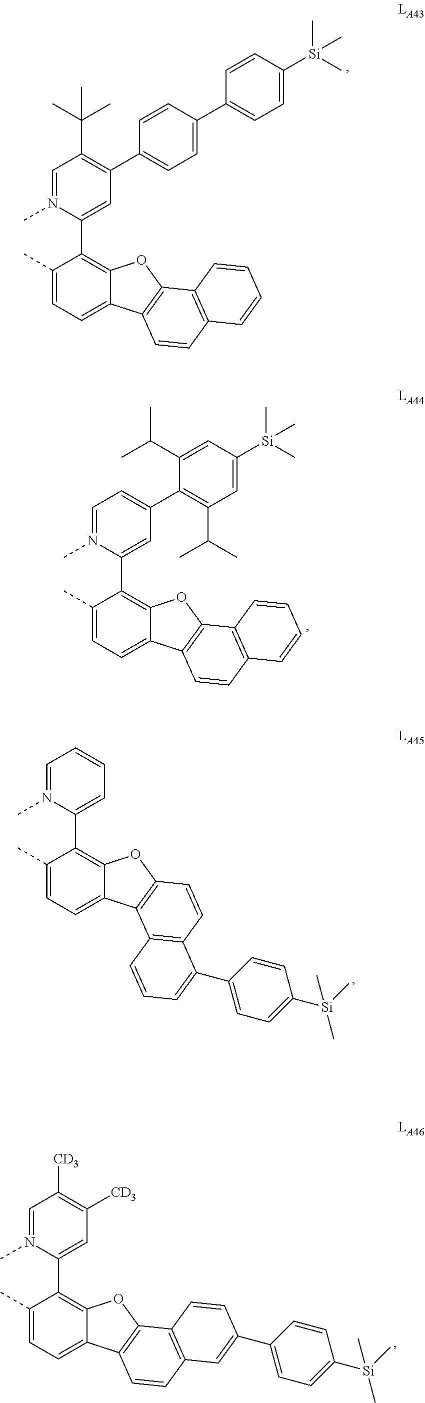

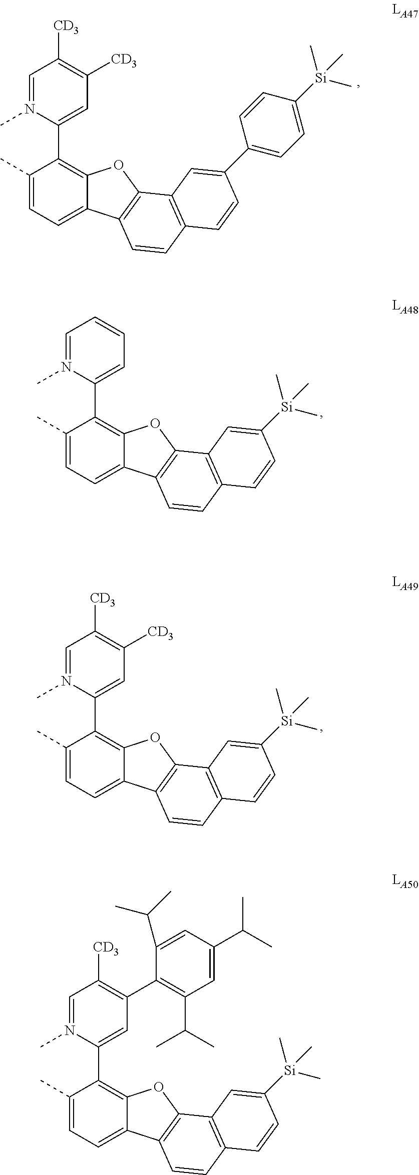

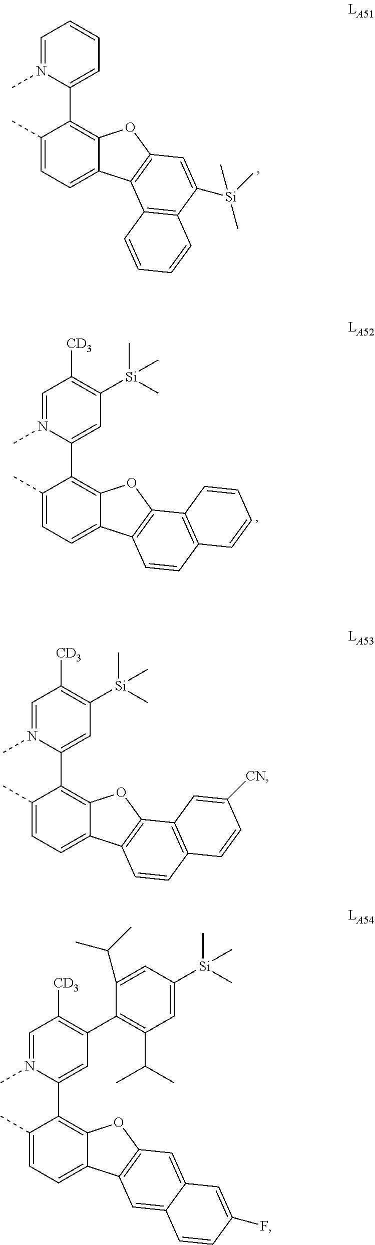

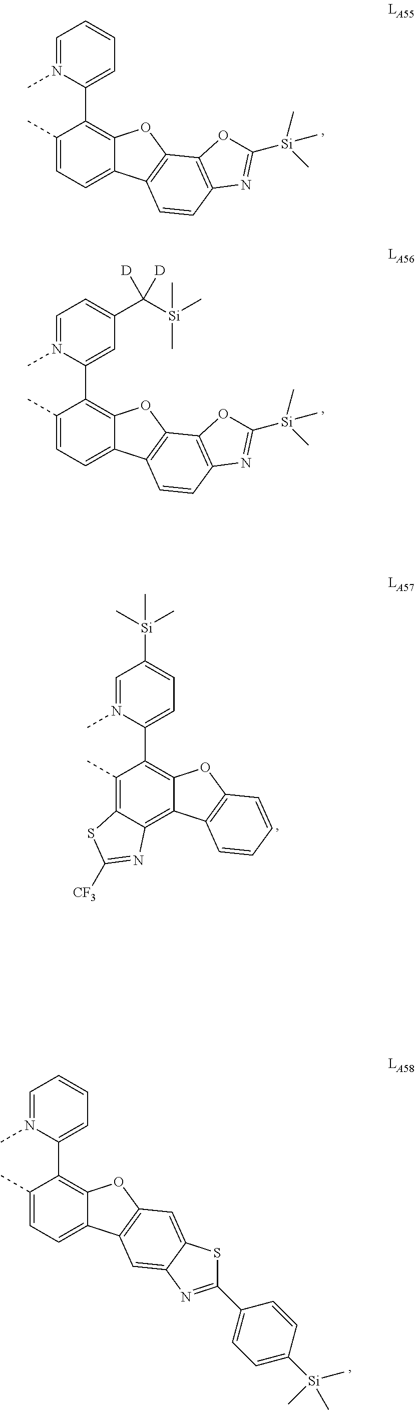

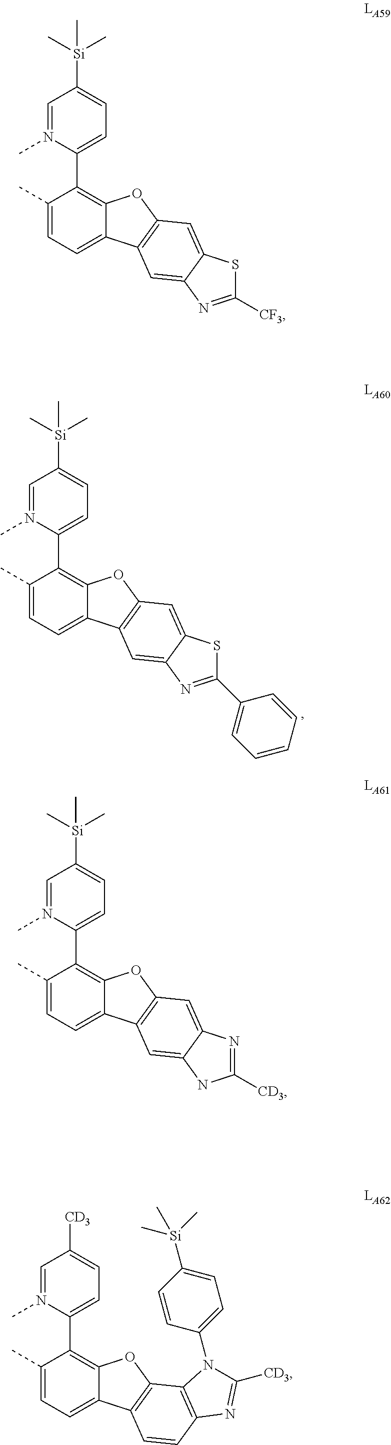

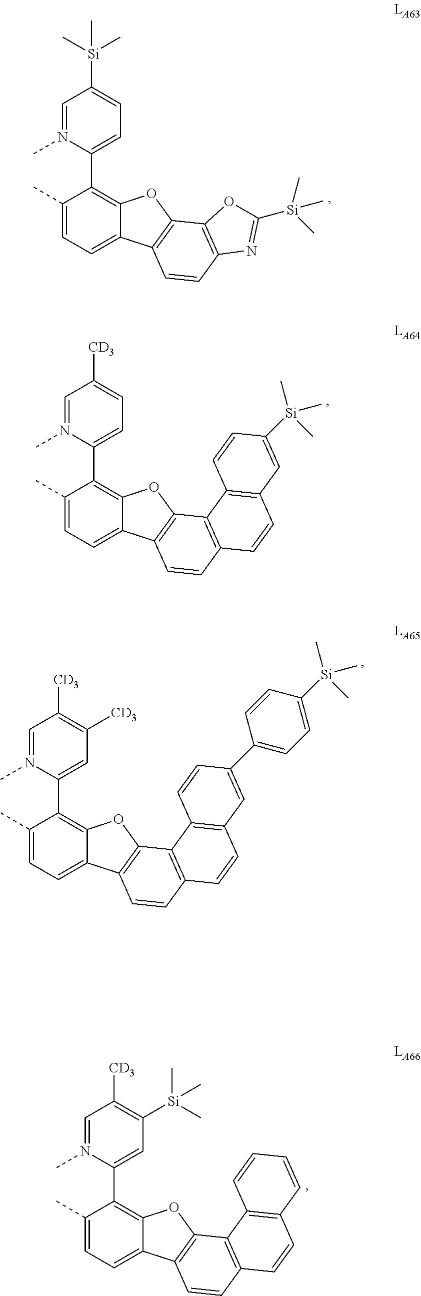

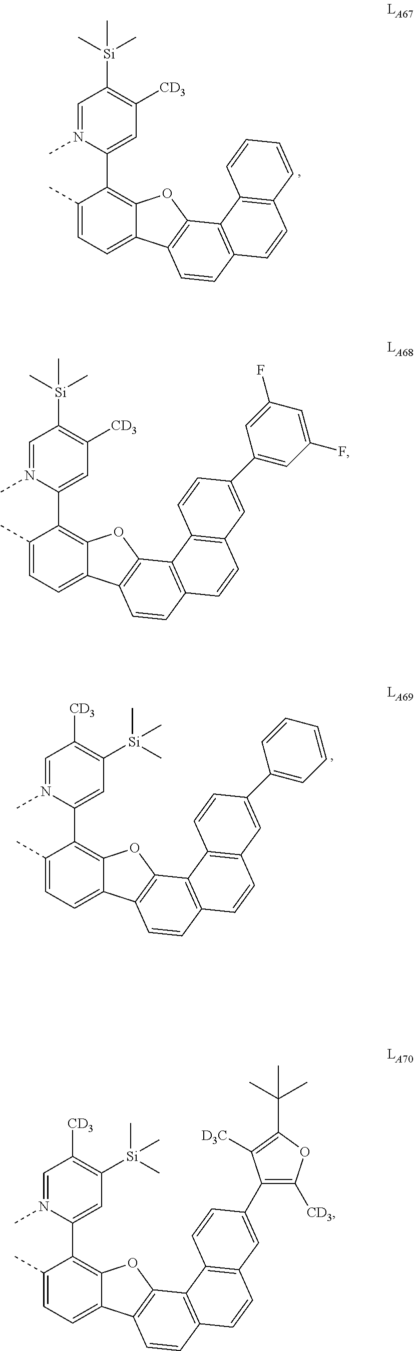

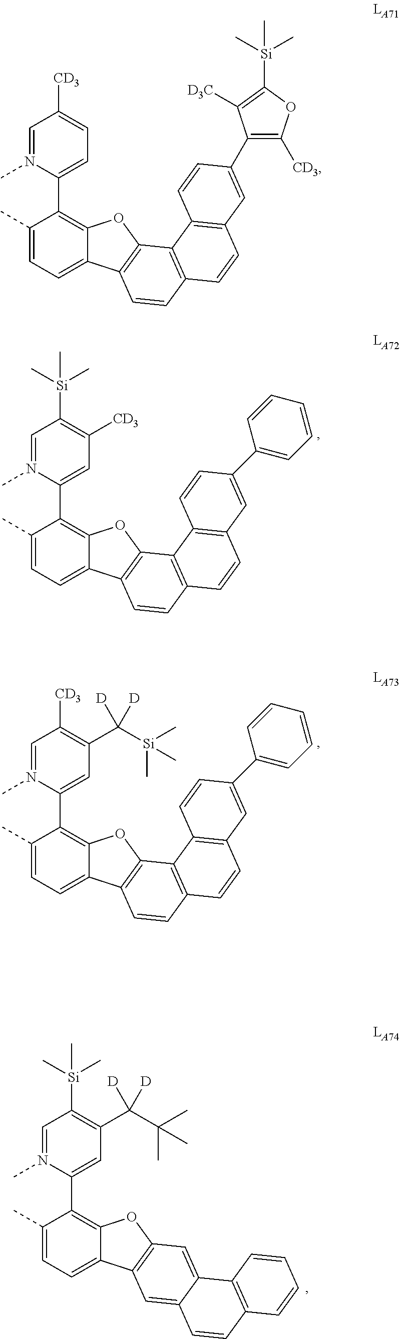

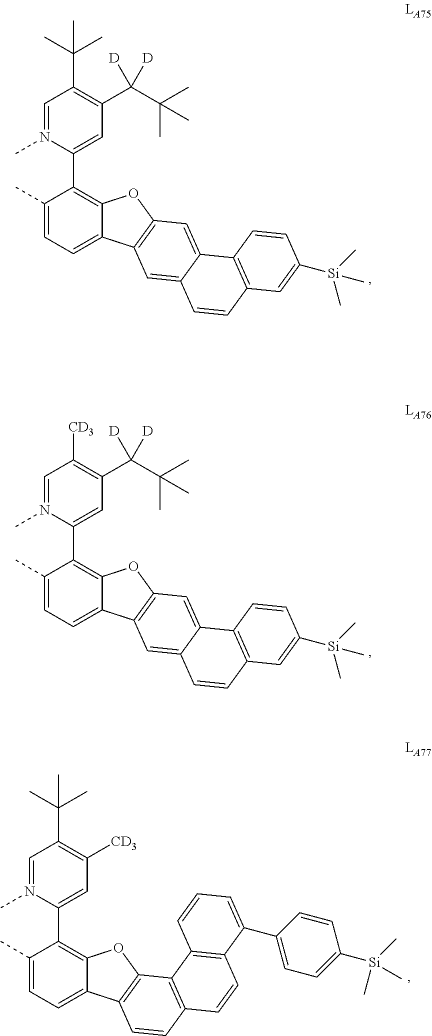

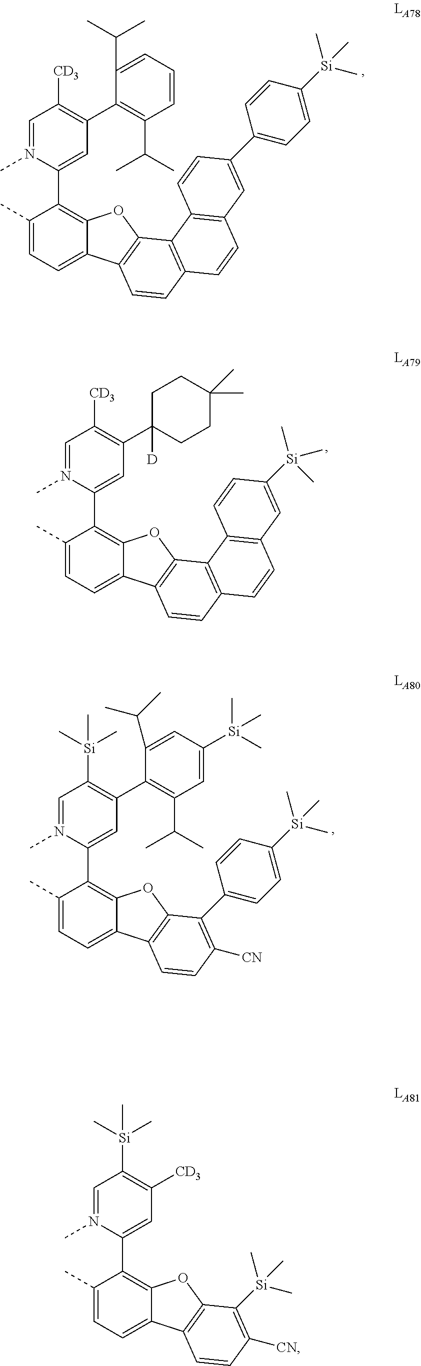

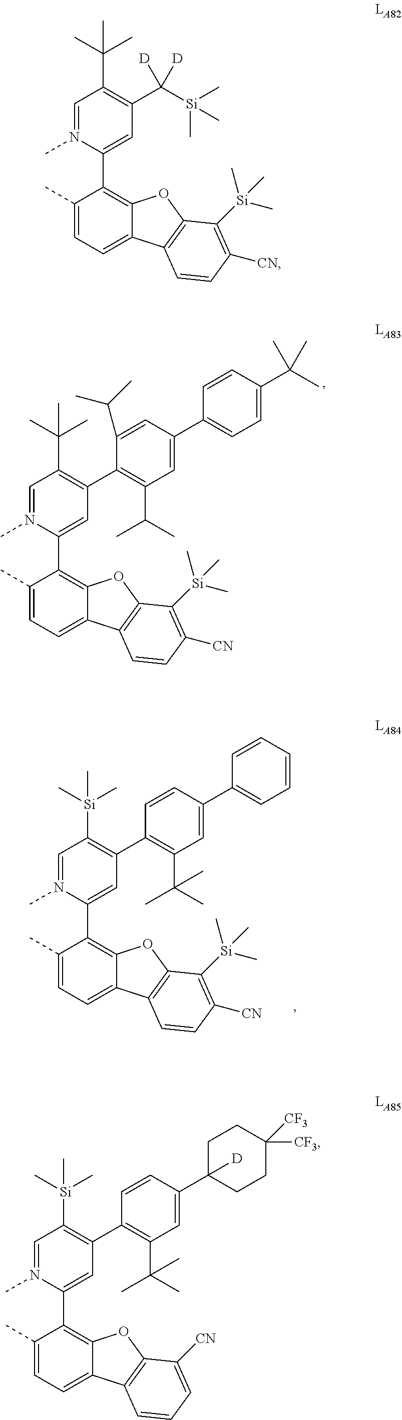

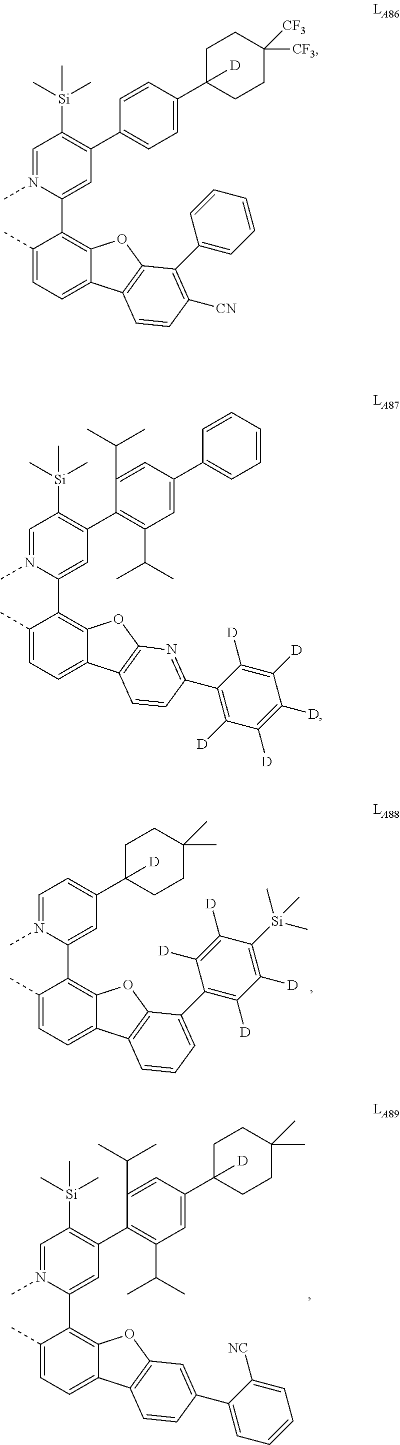

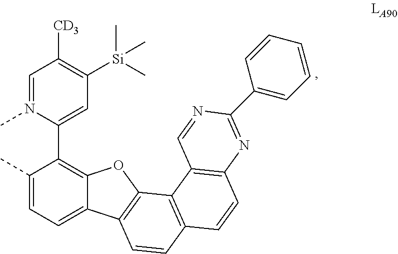

12. The compound of claim 1, wherein the compound has a formula of M(L_{A})ₚ(L_{B})_{q}(L_{C})ᵣ wherein L_{B} and L_{C} are each a bidentate ligand; and wherein p is 1, 2, or 3; q is 0, 1, or 2; r is 0, 1, or 2; and p+q+r is the oxidation state of the metal M.

13. The compound of claim 12, wherein the compound has a formula selected from the group consisting of Ir(L_{A})₃, Ir(L_{A})(L_{B})₂, Ir(L_{A})₂(L_{B}), Ir(L_{A})(L_{C}), and Ir(L_{A})(L_{B})(L_{C}); and wherein L_{A}, L_{B}, and L_{C} are different from each other; or a formula of Pt(L_{A})(L_{B}); and wherein L_{A} and L_{B} can be same or different.

14. The compound of claim 12, wherein L_{B} and L_{C} are each independently selected from the group consisting of: 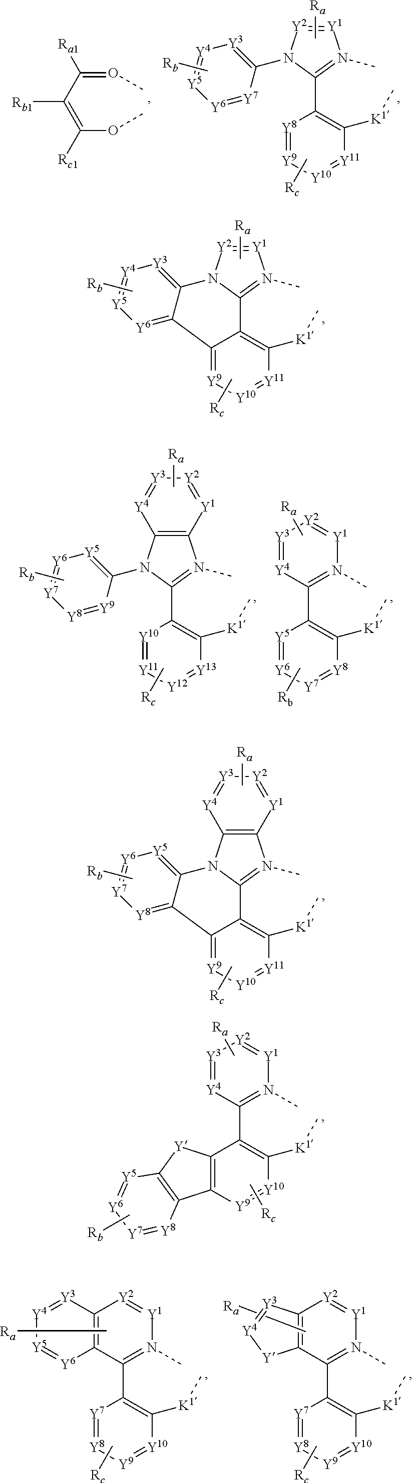 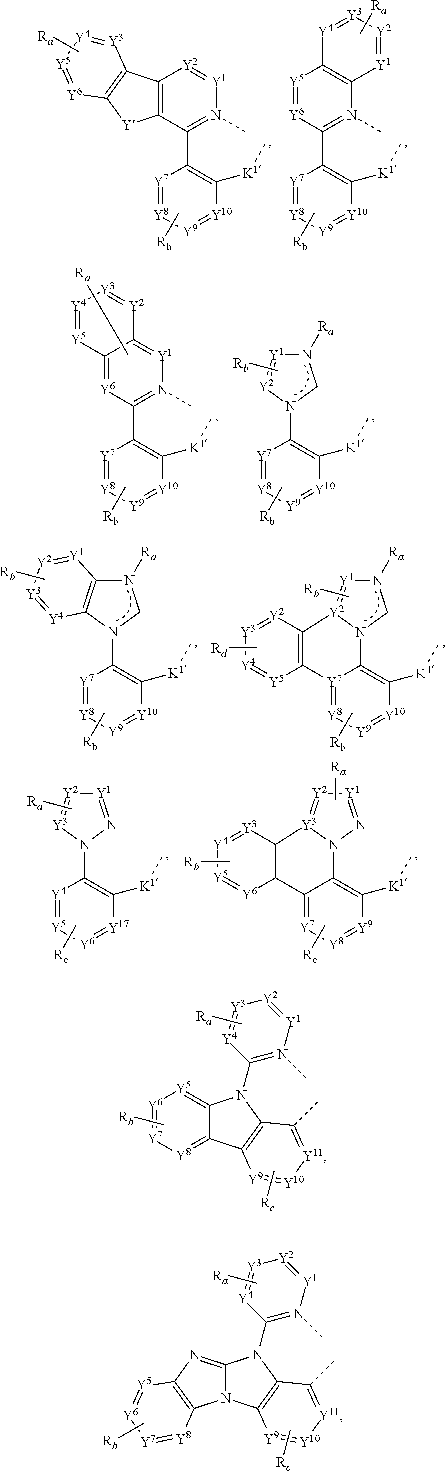 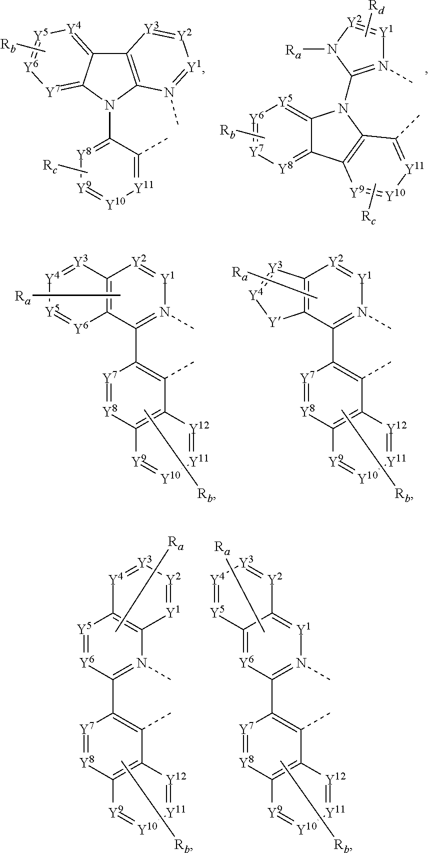 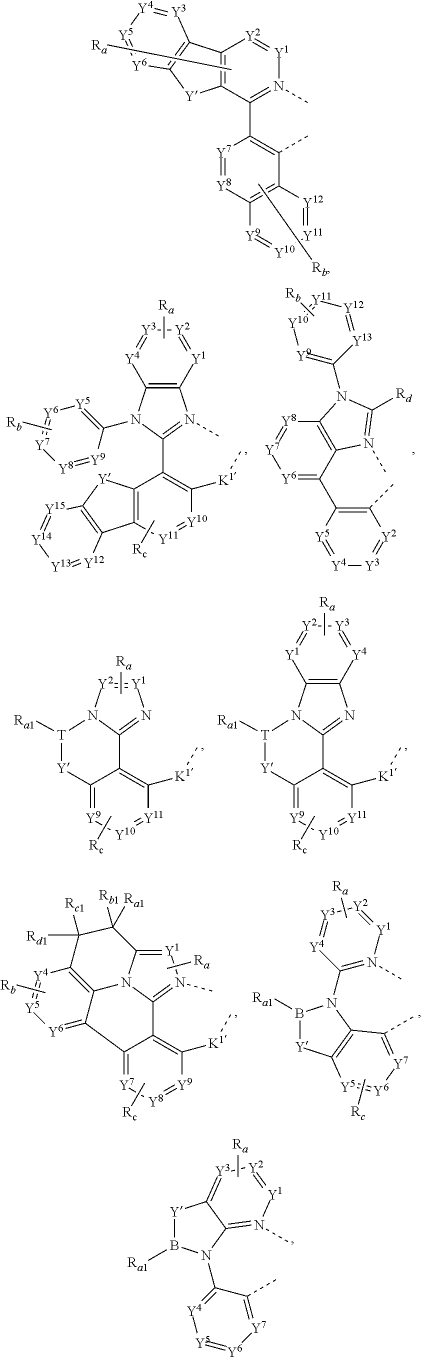 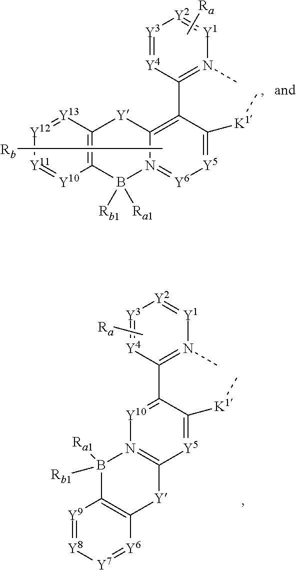
wherein:
T is selected from the group consisting of B, Al, Ga, and In;
K^{1′} is selected from the group consisting of a single bond, O, S, NRₑ, PRₑ, BRₑ, CRₑR_{f}, and SiRₑR_{f};
each of Y¹ to Y¹³ is independently selected from the group consisting of C and N;
Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, R_{d1}, Rₐ, R_{b}, R_{c}, R_{d}, Rₑ, and R_{f} is independently a hydrogen or a subsituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thercof; and
any two substituents of Rₐ₁, R_{b1}, R_{c1}, R_{d1}, R₁, R_{b}, R_{c}, and R_{d} can be fused or joined to form a ring or form a multidentate ligand.
